(19) United States
(12) Patent Application Publication
(10) Pub. No.: US 2025/0156613 A1
(43) Pub. Date: May 15, 2025

(54) RESERVOIR DEVICE AND PROCESS STATE PREDICTION SYSTEM

(71) Applicants: Tokyo Electron Limited, Tokyo (JP); NATIONAL UNIVERSITY CORPORATION HOKKAIDO UNIVERSITY, Hokkaido (JP)

(72) Inventors: Yukiya SAITOU, Hokkaido (JP); Takuro Tsutsui, Hokkaido (JP); Yuanchieh Ling, Hokkaido (JP); Tetsuya Asai, Hokkaido (JP); Yuki Abe, Hokkaido (JP); Kose Yoshida, Hokkaido (JP)

(21) Appl. No.: 19/024,483

(22) Filed: Jan. 16, 2025

Related U.S. Application Data
(63) Continuation of application No. PCT/JP2023/013903, filed on Apr. 4, 2023.

(30) Foreign Application Priority Data
Jul. 20, 2022 (JP) 2022-115663

(51) Int. Cl. G06F 30/28

(52) U.S. Cl. CPC G06F 30/28

(57) ABSTRACT

A reservoir device receives input of time series sensor data measured in a predetermined process and outputs a reservoir feature value based on a result of processing using an input weight multiplier and a connection weight multiplier, in which the input weight multiplier weights the input sensor data, using a value determined by a periodic function as an input weight, and the connection weight multiplier performs weighted addition of data indicating states of nodes, using a value determined by a periodic function as a connection weight between two nodes among the nodes.

### CROSS-REFERENCE TO RELATED APPLICATIONS

This application is a continuation application of international application No. PCT/JP2023/013903 filed on Apr. 4, 2023 and designating the United States, which is based upon and claims priority to Japanese Patent Application No. 2022-115663 filed on Jul. 20, 2022, the entire contents of which are incorporated herein by reference.

### TECHNICAL FIELD

The present disclosure relates to a reservoir device and a process state prediction system.

### BACKGROUND

In the related art, in the field of manufacturing processes, a process state (a state of a device during execution of a manufacturing process (for example, presence or absence of an abnormality in the device)) is predicted using time series sensor data measured by various sensors, and the process state is monitored by providing notification of a prediction result. In recent years, use of a machine learning model has also been proposed in order to improve prediction accuracy in predicting the process state.

### CITATION LIST

### Patent Documents

Patent Documents 1 JP2018-77779A

### Non Patent Documents

Non-patent Document 1: Tanaka H., Akai-Kasaya M., Termeh A. Y., Hong L., Fu L., Tamukoh H., Tanaka D., Asai T., and Ogawa T., A molecular neuromorphic network device consisting of single-walled carbon nanotubes complexed with polyoxometalate Nature Communications, vol. 9, p. 2693 (2018)
Non-patent Document 2: Shaohua Kan, Kohei Nakajima, Yuki Takeshima, Tetsuya Asai, Yuji Kuwahara, and Megumi Akai-Kasaya Simple reservoir computing capitalizing on the nonlinear response of materials: Theory and physical implementations Phys. Rev. Applied, Accepted, 13 Jan. (2021)
Non-patent Document 3: Kose Yoshida, Megumi Akai-Kasaya and Tetsuya Asai, “A 1-Msps 500-Node FORCE Learning Accelerator for Reservoir Computing,” Journal of Signal Processing, Vol. 26, No. 4, pp. 103-106, July 2022
Non-patent Document 4: Jaeger, Herbert, The “echo state” approach to analyzing and training recurrent neural networks—with an erratum note’. Bonn, Germany: German National Research Center for Information Technology GMD Technical Report. 148 (2001)

### SUMMARY

For example, a reservoir device according to an aspect of the present disclosure has the following configuration. That is, a reservoir device is configured to receive input of time series sensor data measured in a predetermined process and output a reservoir feature value based on a result of processing using an input weight multiplier and a connection weight multiplier, in which the input weight multiplier weights the input sensor data, using a value determined by a periodic function as an input weight, and the connection weight multiplier performs weighted addition of data indicating states of nodes, using a value determined by a periodic function as a connection weight between two nodes among the nodes.

For example, a reservoir device according to another aspect of the present disclosure has the following configuration. That is, a reservoir device is configured to receive input of time series sensor data measured in a predetermined process and output a reservoir feature value based on a result of processing using an input weight multiplier and a connection weight multiplier. The reservoir device includes an adder configured to add the sensor data weighted in the input weight multiplier to data indicating states of nodes subjected to weighted addition in the connection weight multiplier, and an operation circuit configured to output the reservoir feature value by performing fixed-point or floating-point polynomial calculation of a result of addition performed by the adder.

For example, a reservoir device according to another aspect of the present disclosure has the following configuration. That is, a reservoir device is configured to receive input of time series sensor data measured in a predetermined process and output a reservoir feature value based on a result of processing using an input weight multiplier and a connection weight multiplier, in which the input weight multiplier weights the input sensor data, using a value determined by a periodic function as an input weight, the connection weight multiplier includes multipliers configured to weight data indicating states of nodes, using a value determined by a periodic function as a connection weight between two nodes among the nodes and correspond in number to a processing speed or prediction accuracy of the reservoir device, and the multipliers of the connection weight multiplier parallelly weight common data between the multipliers in weighting the data indicating the states of the nodes, using the value determined by the periodic function as the connection weight.

For example, a reservoir device according to another aspect of the present disclosure has the following configuration. That is, a reservoir device is configured to receive input of time series sensor data measured in a predetermined process and output a reservoir feature value based on a result of processing using an input weight multiplier and a connection weight multiplier, in which the input weight multiplier weights the input sensor data, using a value determined by a periodic function as an input weight, the connection weight multiplier includes a spectral radius multiplier configured to weight data indicating states of nodes, using a connection weight between two nodes among the nodes by adjusting a reservoir feature value obtained one timing ago using a spectral radius and output a spectral radius weighting result, and multipliers that correspond in number to a processing speed or prediction accuracy of the reservoir device, the spectral radius weighting result being input into the multipliers, the multipliers are connected in series in a stage subsequent to the input weight multiplier, a first multiplier among the multipliers includes an adder configured to add an input weighting result output by the input weight multiplier to a connection weighting result obtained by weighting data indicating a state of a corresponding node, and a multiplier that is a second multiplier or later among the multipliers includes an adder configured to add an addition result output by a multiplier in a previous stage to the connection weighting result obtained by weighting data indicating a state of a corresponding node.

### BRIEF DESCRIPTION OF DRAWINGS

FIG. 1A is a diagram illustrating an application example of a process state prediction system.

FIG. 1B is a diagram illustrating an example of an effective prediction time.

FIG. 2 is a diagram illustrating an example of a system configuration of the process state prediction system.

FIG. 3 is a first diagram illustrating an example of a hardware configuration of a reservoir device.

FIG. 4 is a second diagram illustrating an example of the hardware configuration of the reservoir device.

FIG. 5 is a diagram illustrating an example of an LFSR.

FIG. 6 is a diagram illustrating an example of a chaotic circuit.

FIG. 7A is a diagram illustrating a method of calculating parameters used for scaling.

FIG. 7B is a diagram illustrating an example of an nb-bit right shifter.

FIG. 8 is a diagram illustrating an example of a detailed configuration of an M-bit accumulation circuit.

FIG. 9 is a diagram illustrating an example of a detailed configuration of an activation function circuit.

FIG. 10 is a diagram illustrating an example of a limiter circuit.

FIG. 11 is a diagram illustrating a specific example of processing of an adjustment device configured to adjust a coefficient of a polynomial of an activation function.

FIG. 12 is an example of a transition diagram of each period to which a process state predictor transitions.

FIG. 13 is a diagram illustrating an example of a functional configuration of the process state predictor in a learning period.

FIG. 14 is a diagram illustrating an example of a functional configuration of the process state predictor in a prediction period.

FIG. 15A is a first diagram illustrating an example of a functional configuration of the process state predictor in a relearning period.

FIG. 15B is a second diagram illustrating an example of the functional configuration of the process state predictor in the relearning period.

FIG. 16 is a diagram illustrating an example of a hardware configuration of a FORCE learner based on the recursive least squares.

FIG. 17 is a first diagram illustrating parallel processing and serial processing implemented in the FORCE learner based on the recursive least squares.

FIG. 18 is a second diagram illustrating the parallel processing and the serial processing implemented in the FORCE learner based on the recursive least squares.

FIG. 19 is a first diagram illustrating transmission processing implemented in the FORCE learner based on the recursive least squares.

FIG. 20 is a diagram illustrating substitution processing implemented in the FORCE learner based on the recursive least squares,

FIG. 21 is a second diagram illustrating the transmission processing implemented in the FORCE learner based on the recursive least squares.

FIG. 22 is a diagram illustrating distribution processing implemented in the FORCE learner based on the recursive least squares.

FIG. 23 is a diagram illustrating weight parameter update processing implemented in the FORCE learner based on the recursive least squares.

FIG. 24 is an example of a timing chart of FORCE learning processing performed by the FORCE learner based on the recursive least squares.

FIG. 25 is a diagram illustrating an example of a hardware configuration of a management device.

FIG. 26 is a diagram illustrating an example of a functional configuration of a manager.

FIG. 27 is an example of a flowchart illustrating an overall flow of process state prediction processing performed by the manager and the process state prediction system.

FIG. 28 is an example of a flowchart illustrating a flow of learning processing.

FIG. 29 is an example of a flowchart illustrating a flow of prediction processing.

FIG. 30 is an example of a flowchart illustrating a flow of relearning determination processing.

FIG. 31 is a diagram illustrating another example of the effective prediction time.

FIG. 32 is an example of a flowchart illustrating a flow of relearning processing.

FIG. 33 is a diagram illustrating an example of a weight bit shift multiplier in a second embodiment.

FIG. 34 is a diagram illustrating a configuration example of each weight bit shift multiplier.

FIG. 35 is a third diagram illustrating an example of the hardware configuration of the reservoir device.

FIG. 36 is a fourth diagram illustrating an example of the hardware configuration of the reservoir device.

FIG. 37 is a fifth diagram illustrating an example of the hardware configuration of the reservoir device.

FIG. 38 is a sixth diagram illustrating an example of the hardware configuration of the reservoir device.

FIG. 39 is a diagram illustrating an example of reducing the number of operations in the reservoir device.

FIG. 40 is a diagram illustrating a specific example of processing based on a variable vector length dot product operation architecture in the reservoir device,

FIG. 41 is a diagram illustrating an overview of parallel processing in the reservoir device.

FIG. 42 is an example of a timing chart of multiplication processing in the reservoir device.

FIG. 43 is an example of a timing chart of processing of each unit of the reservoir device.

FIG. 44 is a seventh diagram illustrating an example of the hardware configuration of the reservoir device.

FIG. 45 is an eighth diagram illustrating an example of the hardware configuration of the reservoir device.

FIG. 46A is a first diagram illustrating details of a calculation unit constituting the reservoir device.

FIG. 46B is a second diagram illustrating details of the calculation unit constituting the reservoir device.

FIG. 47 is an example of an overall timing chart of the reservoir device.

FIG. 48 is a diagram illustrating an example of a verification result of prediction accuracy of the reservoir device.

FIG. 49 is a ninth diagram illustrating an example of the hardware configuration of the reservoir device.

FIG. 50 is a tenth diagram illustrating an example of the hardware configuration of the reservoir device.

FIG. 51 is a third diagram illustrating details of the calculation unit constituting the reservoir device.

FIG. 52 is a diagram illustrating an example of the weight bit shift multiplier in a seventh embodiment.

### DETAILED DESCRIPTION

A device equipped with a machine learning model generally has a processing cycle longer than a measurement cycle of time series sensor data and cannot execute the machine learning model by detecting short-cycle behavior occurring in the time series sensor data.

Prediction accuracy in predicting a process state based on time series sensor data can be improved.

In the following, embodiments of the present invention will be described with reference to the accompanying drawings. In the specification and drawings, elements having substantially the same functions or configurations are referred to by the same numerals, and a duplicate description thereof will be omitted.

### First Embodiment

### <Application Example of Process State Prediction System>

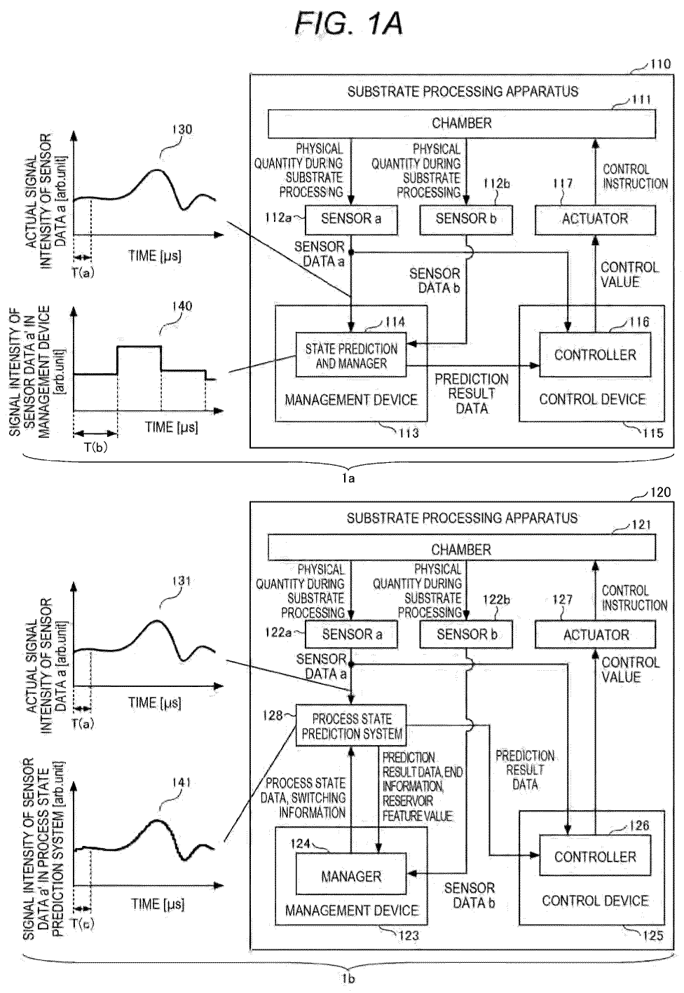

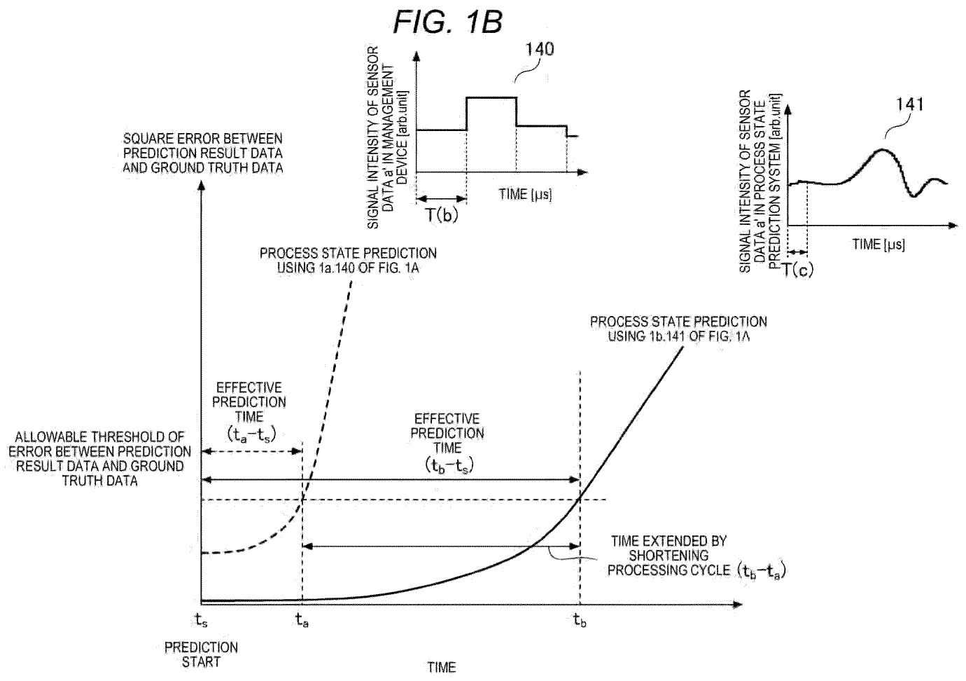

First, an application example of a process state prediction system according to a first embodiment will be described. FIG. 1A is a diagram illustrating the application example of the process state prediction system.

While the example of FIG. 1A describes application of the process state prediction system to a substrate processing apparatus, an apparatus to which the process state prediction system is applied is not limited to the substrate processing apparatus and may be an apparatus that executes another manufacturing process.

FIG. 1A illustrates not only the substrate processing apparatus (1b) to which the process state prediction system is applied but also a substrate processing apparatus (1a) to which the process state prediction system is not applied as a comparative example, and differences between both will be described by comparison with each other, as appropriate.

As illustrated in 1a and 1b in FIG. 1A, substrate processing apparatuses 110 and 120 have chambers 111 and 121 for processing substrates, a sensor a 112a and a sensor a 122a, and a sensor b 112b and a sensor b 122b. The substrate processing apparatuses 110 and 120 have management devices 113 and 123, control devices 115 and 125, and actuators 117 and 127.

As illustrated in 1a of FIG. 1A, which is a comparative example, in the substrate processing apparatus 110, the sensor a 112a and the sensor b 112b measure physical quantities during processing of the substrate in the chamber 111 and output the measured data as time series sensor data a and time series sensor data b. A process state is predicted by processing the time series sensor data a and the time series sensor data b output from the sensor a 112a and the sensor b 112b in a state prediction and manager 114 of the management device 113. The predicted process state is output to the control device 115 as prediction result data (an example of prediction data).

A control value is calculated by processing the time series sensor data a output from the sensor a 112a in a controller 116 of the control device 115. The controller 116 may correct the control value based on the prediction result data. The control value calculated by the controller 116 is output to the actuator 117, and the actuator 117 notifies the chamber 111 of a control instruction based on the control value.

In 1a of FIG. 1A, a graph 130 is an example of the time series sensor data a output from the sensor a 112a, in which the horizontal axis denotes time and the vertical axis denotes signal intensity. In 1a of FIG. 1A, a graph 140 indicates time series sensor data a′ being processed in the state prediction and manager 114 of the management device 113, in which a horizontal axis denotes time and a vertical axis denotes signal intensity.

Generally, a processing cycle T(b) in which the management device 113 predicts the process state is longer than a measurement cycle T(a) in which the sensor a 112a measures the time series sensor data a. Thus, the state prediction and manager 114 cannot detect short behavior occurring in the time series sensor data a as indicated in the graph 130 (refer to the graph 140), and as a result, sufficient prediction accuracy is unlikely to be obtained when the process state is predicted.

As illustrated in 1b of FIG. 1A, in the substrate processing apparatus 120, the sensor a 122a and the sensor b 122b measure physical quantities during processing of the substrate in the chamber 121 and output the measured data as the time series sensor data a and the time series sensor data b. At that time, the process state is predicted by processing the time series sensor data a output from the sensor a 122a in a process state prediction system 128. Prediction result data (an example of prediction data) predicted in the process state prediction system 128 is output to a manager 124 and a controller 126.

A control value is calculated by processing the time series sensor data a output from the sensor 122a in the controller 126 of the control device 125. The controller 126 may correct the control value based on the prediction result data. The control value calculated by the controller 126 is output to the actuator 127, and the actuator 127 notifies the chamber 121 of a control instruction based on the control value.

In 1b of FIG. 1A, a graph 131 is an example of the time series sensor data a output from the sensor a 122a, in which the horizontal axis denotes time and the vertical axis denotes signal intensity. In 1b of FIG. 1A, a graph 141 indicates the time series sensor data a′ being processed in the process state prediction system 128, in which the horizontal axis denotes time and the vertical axis denotes signal intensity.

The process state prediction system 128 according to the first embodiment predicts the process state by processing the time series sensor data a′ through reservoir computing. Thus, a processing cycle T(c) in predicting the process state is significantly shorter than the processing cycle T(b) in which the management device 113 predicts the process state in 1a of FIG. 1A. Consequently, the process state prediction system 128 according to the first embodiment can detect short behavior occurring in the time series sensor data a indicated in the graph 131 and can improve the prediction accuracy.

Improvement in the prediction accuracy through prediction of the process state by processing the time series sensor data a′ of the graph 141 in which the short behavior is detected can be expressed as an “effective prediction time” until square error between the prediction result data and ground truth data exceeds an allowable threshold. The effective prediction time is a time indicating how far ahead in time the process state prediction system 128 (or the state prediction and manager 114) can appropriately predict the process state.

FIG. 1B is a diagram illustrating an example of the effective prediction time. As illustrated in FIG. 1B,
an effective prediction time (t_{b}−tₛ) when the process state is predicted using the time series sensor data a′ of the graph 141
   is longer than
an effective prediction time (tₐ−tₛ) when the process state is predicted using the time series sensor data a′ of the comparative example as in the graph 140. This indicates that the process state prediction system 128 is less susceptible to a decrease in the prediction accuracy caused by a change over time than the comparative example. The substrate processing apparatus 120 may accumulate operation logs (for example, histories of a temperature, a humidity, a voltage signal, and the like during operation) and perform analysis for further extending the effective prediction time (t_{b}−tₐ) using the accumulated logs.

Even when the prediction accuracy is decreased because of a change over time in the chamber 121 or the like, the process state prediction system 128 according to the first embodiment can improve the prediction accuracy by performing relearning processing. Specifically, the manager 124 can manage the relearning processing performed by the process state prediction system 128 using the prediction result data, a reservoir feature value, and the sensor data b output by the process state prediction system 128.

Process state data (the ground truth data) used for performing learning processing or the relearning processing of the process state prediction system 128 may include, for example, presence or absence of an abnormality in the substrate processing apparatus 120 during execution of a substrate processing process. Alternatively, the process state data (the ground truth data) may include the sensor data b output from the sensor b 122b (in the present embodiment, the process state data (the ground truth data) will be described as the sensor data b output from the sensor b 122b). The ground truth data is generally referred to as a “dependent variable” or “labeled training data”.

When the process state prediction system 128 performs the relearning processing, the manager 124 transmits and receives various information (switching information, end information, and the like) to and from the process state prediction system 128 in order to manage periods (to be described in detail later) of the process state prediction system 128.

Consequently, the process state prediction system 128 according to the first embodiment can suppress a decrease in the prediction accuracy caused by a change over time in a manufacturing process.

According to the first embodiment, the prediction accuracy in predicting the process state based on time series sensor data can be improved.

### <System Configuration of Process State Prediction System>

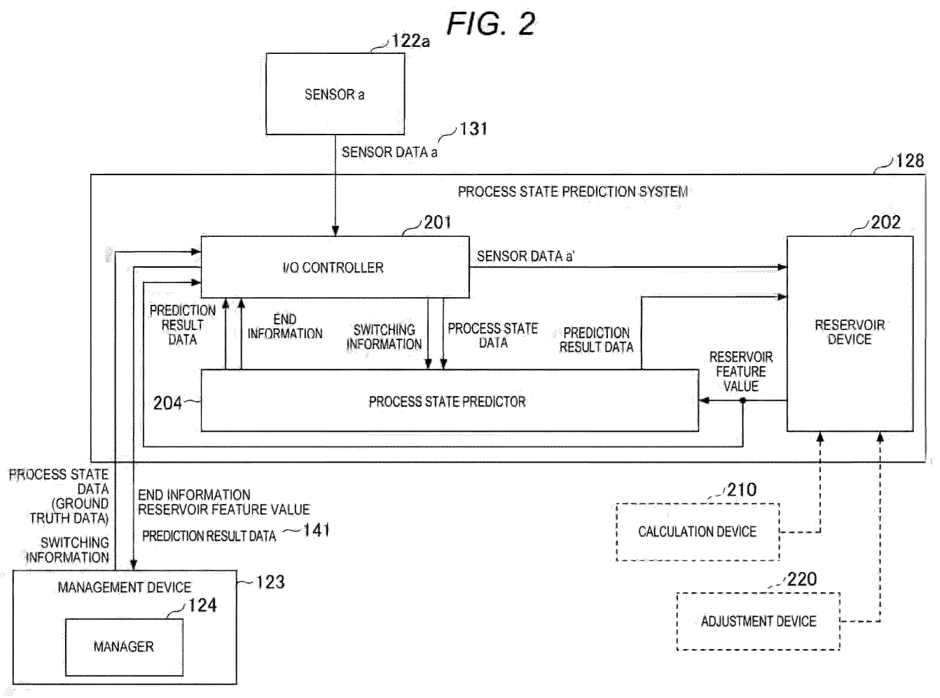

Next, a system configuration of the process state prediction system 128 will be described. FIG. 2 is a diagram illustrating an example of the system configuration of the process state prediction system. For example, the process state prediction system 128 is implemented by a field-programmable gate array (FPGA) board.

As illustrated in FIG. 2, the process state prediction system 128 includes an I/O controller 201, a reservoir device 202, and a process state predictor 204.

The I/O controller 201 controls input and output of digital signals. Specifically, the I/O controller 201 receives input of the time series sensor data a output from the sensor a 122a and notifies the reservoir device 202 of the sensor data a′.

The time series sensor data a input into the I/O controller 201 may be one type of time series sensor data or may be a sensor data set including a plurality of types of time series sensor data. For simplification of description, one type of time series sensor data is input in the following description.

The I/O controller 201 acquires the prediction result data (the predicted process state) output from the process state predictor 204 and the reservoir feature value output from the reservoir device 202 and transmits the prediction result data and the reservoir feature value to the management device 123. The I/O controller 201 receives input of the process state data (the ground truth data) used for performing the learning processing (or the relearning processing) in the process state prediction system 128 from the management device 123 and notifies the process state predictor 204 of the process state data.

The I/O controller 201 transmits and receives the switching information for switching a period of the process state predictor 204 and the end information indicating the end of processing of the process state predictor 204 in the period after switching, to and from the management device 123.

The reservoir device 202 is a chip that outputs the reservoir feature value. The reservoir device 202 implements a function corresponding to a nanomolecular reservoir capable of high-speed learning and prediction by using a digital circuit (for example, an FPGA or an application specific integrated circuit (ASIC)). The reservoir feature value is a numerical value that quantitatively indicates a characteristic of the time series sensor data a′ and that is output by the reservoir device 202 based on each value from the past to the present when each value of the time series sensor data a′ is input into the reservoir device 202.

While the example of FIG. 2 indicates that the prediction result data calculated by the process state predictor 204 is fed back and input into the reservoir device 202, the prediction result data does not need to be fed back.

For example, parameters and coefficients used for processing in the reservoir device 202 are calculated in advance in a calculation device 210 and an adjustment device 220 and set in the reservoir device 202.

The process state predictor 204 is an example of a prediction device and operates in a plurality of periods (in the present embodiment, a learning period, a prediction period, and a relearning period) that switch in accordance with the switching information. The learning period refers to a period of learning a weight parameter. The relearning period refers to a period of relearning the learned weight parameter.

When the process state predictor 204 transitions to the learning period or the relearning period, the process state predictor 204 calculates the weight parameter so that the prediction result data and the process state data (the ground truth data) input by the I/O controller 201 correlate with each other. When calculation of the weight parameter ends, the process state predictor 204 outputs the end information.

Meanwhile, the prediction period refers to a period of outputting the prediction result data based on the reservoir feature value using the weight parameter learned in the learning period or the relearning period.

When the switching information is input into the process state predictor 204 in response to the output of the end information, the process state predictor 204 transitions to the prediction period and predicts the process state based on the reservoir feature value output from the reservoir device 202. The process state predictor 204 outputs the prediction result data to the I/O controller 201 and the reservoir device 202.

For example, art output cycle in which the process state predictor 204 outputs the prediction result data to the I/O controller 201 may be shorter than or equal to a processing cycle of the management device 123 (that is, shorter than or equal to a transmission cycle of a fieldbus).

### <Details of Process State Prediction System>

Next, details of each unit (the reservoir device 202 and the process state predictor 204) of the process state prediction system 128 of FIG. 2 will be described.

### (1) Overview of Reservoir Device 202

First, an overview of the reservoir device 202 will be described. As described above, in the present embodiment, the reservoir device 202 is implemented by a digital circuit. Generally, for example, mathematical equations defined in an echo state network (ESN), which is a base model, are used (refer to Equations (1) and (2)) in order to operate the digital circuit as the reservoir device 202.

$$\begin{matrix}[ Equation 1 ] & \\ {u}_{i} ( t + 1 ) = tanh ( {\sum }_{j}^{N} {w}_{ij} {u}_{j} ( t ) + \text{?} \cdot \text{?} ( t ) ) & ( 1 )\end{matrix}$$

$$\begin{matrix}[ Equation 2 ] & \\ \text{?} ( t + 1 ) = tanh ( {\sum }_{j}^{N} {w}_{ij} {u}_{j} ( t ) + \text{?} \cdot \text{?} ( t ) + {w}_{i}^{F} \cdot Z ( t ) ) & ( 2 )\end{matrix}$$

$$\text{?} \text{indicates text missing or illegible when filed}$$

Equation (1) or (2) indicates
N: the number of reservoir nodes in the reservoir device,
uᵢ(t+1): an internal state of the reservoir device at time t+1 (an i-th reservoir node state),
uⱼ(t): an internal state of the reservoir device at time t (a j-th reservoir node state),
wᵢⱼ: a connection weight between nodes of an i-th reservoir node and a j-th reservoir node at time t,
wᵢ^{I}: an input weight of the i-th reservoir node,
wᵢ^{F}: a feedback weight of the i-th reservoir node,
I(t): a value of the sensor data a′ at time t,
Z(t): the prediction result data at time t,
tan h: a hyperbolic tangent function (in the ESN, tan h is used as an activation function), and
dot symbol “·”: a matrix product.

Equation (1) indicates a mathematical equation executed in the reservoir device without feedback of the prediction result data, and Equation (2) indicates a mathematical equation executed in the reservoir device with feedback of the prediction result data.

However, in Equation (1) or (2), as the number (N) of reservoir nodes is increased, necessary resources are increased, and a processing time is also increased. Therefore, in the present embodiment, the reservoir device 202 is implemented by a digital circuit that changes Equations (1) and (2) to be qualitatively the same as the mathematical equations defined in the ESN and that executes the changed mathematical equations. Thus, according to the present embodiment, the reservoir device 202 can be implemented by a digital circuit having reduced resources and a shortened processing time.

Specifically, the reservoir device 202 according to the present embodiment is implemented by a digital circuit that executes Equation (3) or (4).

$$\begin{matrix}[ Equation 3 ] & \\ {u}_{i} ( t + 1 ) = f ( \text{?} {\sum }_{j}^{N} {w}_{ij}^{raw} {u}_{j} ( t ) + \text{?} \cdot \text{?} ( t ) ) & ( 3 )\end{matrix}$$

$$\begin{matrix}[ Equation 4 ] & \\ {u}_{i} ( t + 1 ) = f ( \text{?} {\sum }_{j}^{N} {w}_{ij}^{raw} {u}_{j} ( t ) + \text{?} \cdot \text{?} ( t ) + \text{?} \cdot Z ( t ) ) & ( 4 )\end{matrix}$$

$$\text{?} \text{indicates text missing or illegible when filed}$$

Equation (3) or Equation (4) indicates
wᵢⱼ^{raw}: an output (an element in an i-th row and a j-th column of a connection weight matrix represented by a matrix of N rows and N columns) of a connection weight generator (to be described in detail later) used for calculating the connection weight between the i-th reservoir node and the i-th reservoir node,
wᵢ^{Iraw}: an output (an i-th element of an input weight vector represented by N elements) of an input weight generator (to be described in detail later) used for calculating an input weight of the i-th reservoir node, and
wᵢ^{Fraw}: an output (an i-th element, of a feedback weight vector represented by N elements) of a feedback weight generator (to be described in detail later) used for calculating a feedback weight of the i-th reservoir node.

That is, the reservoir device 202 according to the present embodiment calculates the reservoir feature value by
calculating (2^{-nb})×(the output wᵢⱼ^{raw} of the connection weight gernerator) instead of the connection weight wᵢⱼ,
calculating (2^{-nI})×(the output wᵢ^{Iraw} of the input weight generator) instead of the input weight wᵢ^{I},
calculating (2^{-nF})×(the output wᵢ^{Fraw} of the feedback weight generator) instead of the feedback weight wᵢ^{F}, and
using an activation function f instead of tan h.

Here, nb, nI, and nF denote a right shift amount of the connection weight, a right shift amount of the input weight, and a right shift amount of the feedback weight, respectively.

### (2) Details of Hardware Configuration of Reservoir Device 202

Next, details of a hardware configuration of the reservoir device 202 implemented by the digital circuit that executes Equation (3) or (4) will be described. In the following description, “M” is a predetermined integer.

(2-1) Details of Reservoir Device 202 (without Feedback)

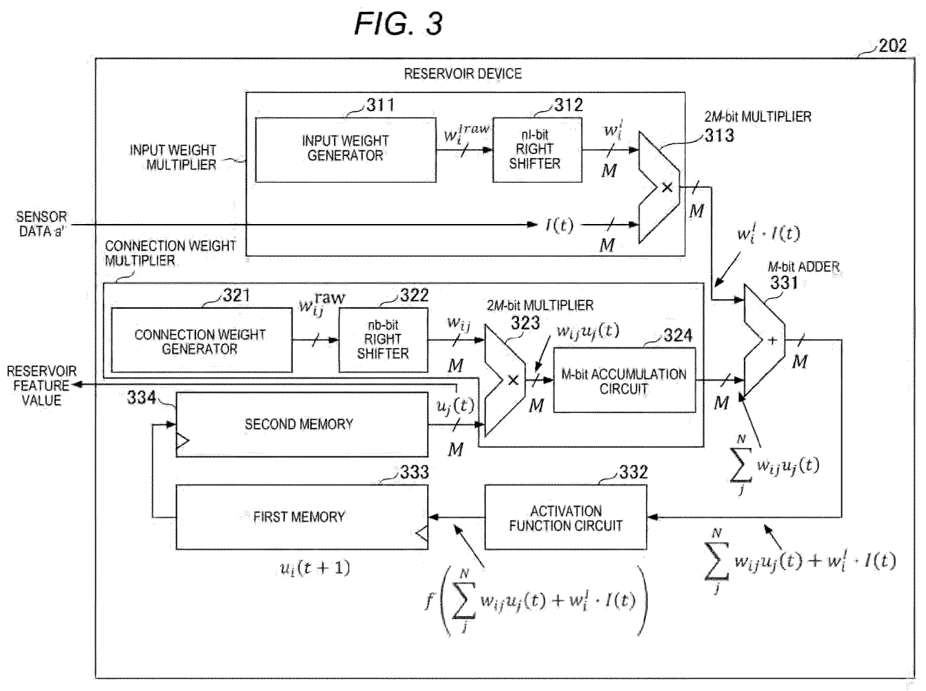

First, details of the hardware configuration of the reservoir device 202 (without feedback) will be described. FIG. 3 is a first diagram illustrating an example of the hardware configuration of the reservoir device.

As illustrated in FIG. 3, the reservoir device 202 (without feedback) includes an input weight generator 311, an nI-bit right shifter 3112, and a 2M-bit multiplier 313 (these are an example of an input weight multiplier). The reservoir device 202 includes a connection weight generator 321, an nb-bit right shifter 322, a 2M-bit multiplier 323, and an M-bit accumulation circuit 324 (these are an example of a connection weight multiplier). The reservoir device 202 includes an M-bit adder 331, an activation function circuit 332, a first memory 333, and a second memory 334. Triangular symbols in the drawing indicate clock input.

The input weight generator 311 functions as a random number generator. More specifically, the input weight generator 311 is implemented by a first periodic function circuit such as
a linear feedback shift register (LFSR) having M-bit log₂ N possible register states, or
a chaotic circuit. The output wᵢ^{Iraw} of the input weight generator 311 is input into the nI-bit right shifter 312.

The nI-bit right shifter 312 calculates (2^{-nI})×(the output wᵢ^{Iraw} of the input weight generator) by shifting the output wᵢ^{Iraw} of the input weight generator 311 to the right by nI bits and outputs the input weight wᵢ^{I}.

The 2M-bit multiplier 313 is an example of a first multiplier. The 2M-bit multiplier 313 multiplies the input weight wᵢ^{I} output from the nI-bit right shifter 312 by I(t), which is the value of the sensor data a′, and outputs (wᵢ^{I})·(I(t)) as a multiplication result.

The connection weight generator 321 functions as a random number generator. More specifically, the connection weight generator 321 is implemented by a second periodic function circuit such as
an LFSR having M-bit log₂ N possible register states, or
a chaotic circuit. The output wᵢⱼ^{raw} of the connection weight generator 321 is input into the nb-bit right shifter 322.

The nb-bit right shifter 322 calculates (2^{-nb})×(the output wᵢⱼ^{raw} of the connection weight generator) by shifting the output wᵢⱼ^{raw} of the connection weight generator 321 to the right by nb bits and outputs the connection weight wᵢⱼ.

The 2M-bit multiplier 323 is an example of a second multiplier. The 2M-bit multiplier 323 multiplies the connection weight wᵢⱼ output from the nb-bit right shifter 322 by uⱼ(t), which is the j-th reservoir node state calculated one timing ago, and outputs (wᵢⱼ)×(uⱼ(t)) as a multiplication result.

The M-bit accumulation circuit 324 is an example of an accumulator, adds up the output (wᵢⱼ)×(uⱼ(t)) of the 2M-bit multiplier 323 for as many as the number of reservoir nodes, and outputs an addition result.

The M-bit adder 331 is an example of an adder and calculates Equation (5) by adding the multiplication result output from the 2M-bit multiplier 313 and the addition result output from the M-bit accumulation circuit 324 to each other.

$$\begin{matrix}[ Equation 5 ] & \\ {\sum }_{j}^{N} {w}_{ij} {u}_{j} ( t ) + \text{?} \cdot \text{?} ( t ) & ( 5 )\end{matrix}$$

$$\text{?} \text{indicates text missing or illegible when filed}$$

The M-bit adder 331 inputs a calculation result of Equation (5) into the activation function circuit 332.

The activation function circuit 332 is an example of an operation circuit and calculates the i-th reservoir node state uᵢ(t+1) at time t+1 by inputting the calculation result of Equation (5) into the activation function f. The activation function circuit 332 writes the calculated reservoir node state uᵢ(t+1) into the first memory 333.

The first memory 333 holds the i-th reservoir node state uᵢ(t+1) at time t+1 calculated by the activation function circuit 332. When the i-th reservoir node state uᵢ(t+1) at time t+1 is completely written into the first memory 333, the second memory 334 is updated with the i-th reservoir node state uᵢ(t+1) at time t+1.

The second memory 334 holds the j-th reservoir node state uᵢ(t) (j=1, 2, . . . N) calculated one timing ago. The J-th reservoir node state uⱼ(t) (j=1, 2, . . . N) calculated one timing ago and held in the second memory 334 is read by the process state predictor 204 in an order of j=1, 2, . . . N each time a clock rises. The read j-th reservoir node state uⱼ(t) (j=1, 2, . . . N) is input into the 2M-bit multiplier 323. The value of the subsequent sensor data a′ is input as the value of the sensor data a′ when the clock rises N times.

(2-2) Details of Reservoir Device 202 (with Feedback)

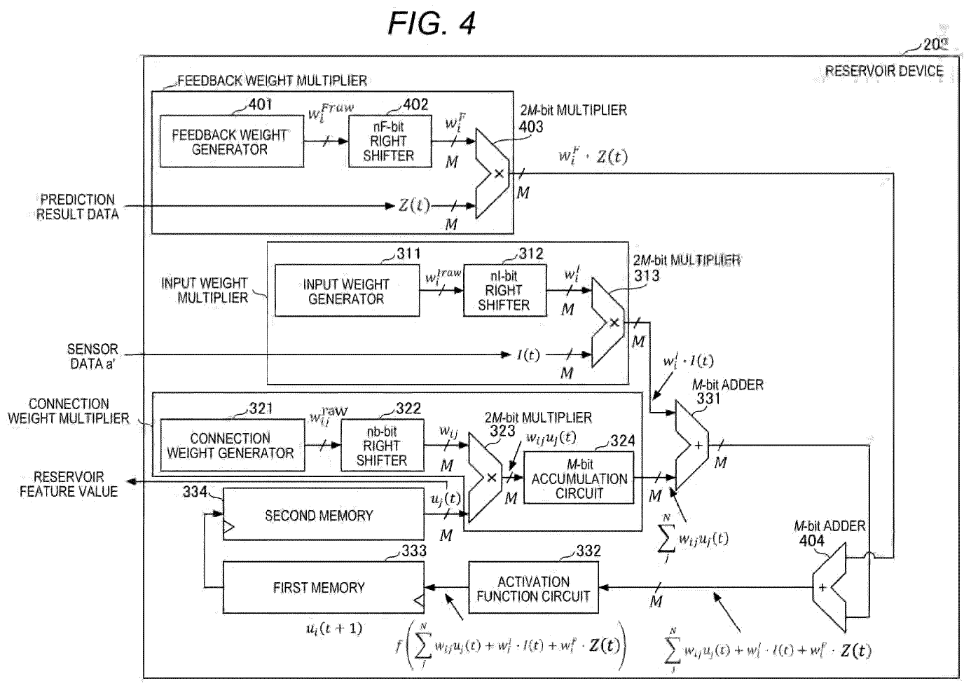

Next, details of the hardware configuration of the reservoir device 202 (with feedback) will be described. FIG. 4 is a second diagram illustrating an example of the hardware configuration of the reservoir device.

As illustrated in FIG. 4, the reservoir device 202 (with feedback) has: the same hardware configuration as the hardware configuration of the reservoir device 202 (without feedback) illustrated in FIG. 3. The reservoir device 202 (with feedback) further includes
a feedback weight generator 401, an nF-bit right shifter 402, a 2M-bit multiplier 403 (these are an example of a feedback weight multiplier), and
an M-bit adder 404 (an example of the adder). Triangular symbols in the drawing indicate clock input.

The feedback weight generator 402 functions as a random number generator. More specifically, the feedback weight generator 401 is implemented by a third periodic function circuit such as
a linear feedback shift register (LFSR) having M-bit log₂ N possible register states, or
a chaotic circuit. The output wᵢ^{Fraw} of the feedback weight generator 401 is input into the nF-bit right shifter 402.

The nF-bit right shifter 402 calculates (2^{-nF})×(the output wᵢ^{Fraw} of the feedback weight generator) by shifting the output wᵢ^{Fraw} of the feedback weight generator 401 to the right by nF bits and outputs the feedback weight wᵢ^{F}.

The 2M-bit multiplier 403 is an example of a third multiplier. The 2M-bit multiplier 403 multiplies the feedback weight wᵢ^{F} output from the nF-bit right shifter 402 by Z(t), which is the value of the prediction result data, and outputs (wᵢ^{F})·(Z(t)) as a multiplication result.

The M-bit adder 404 calculates Equation (6) by adding the calculation result of Equation (5) calculated by the M-bit adder 331 and the output (wᵢ^{F})·(Z(t)) of the 2M-bit multiplier 403 to each other.

$$\begin{matrix}[ Equation 6 ] & \\ {\sum }_{j}^{N} {w}_{ij} {u}_{j} ( t ) + \text{?} \cdot \text{?} ( t ) + \text{?} \cdot Z ( t ) & ( 6 )\end{matrix}$$

$$\text{?} \text{indicates text missing or illegible when filed}$$

The M-bit adder 404 inputs a calculation result of Equation (6) into the activation function circuit 332.

### (3) Details of Each Unit Included in Reservoir Device 202

Next, details of each unit included in the reservoir device 202 (without feedback) or the reservoir device 202 (with feedback) will be described.

### (3-1) Overview of Outputs of Input Weight Generator, Connection Weight Generator, and Feedback Weight Generator

First, an overview of the outputs of the input weight generator 311, the connection weight generator 321, and the feedback weight generator 401 included in the reservoir device 202 will be described. As described above, in the present embodiment, the outputs of the input weight generator 311, the connection weight generator 321, and the feedback weight generator 401 are generated using a periodic function circuit such as an LFSR or a chaotic circuit. Thus, according to the present embodiment, for example, the output of the input weight generator 311, the output of the connection weight generator 321, and the output of the feedback weight generator 401 can be implemented with lower power and fewer resources than when N² random number values are stored in a memory or the like.

### (3-1-1) Details of LFSR

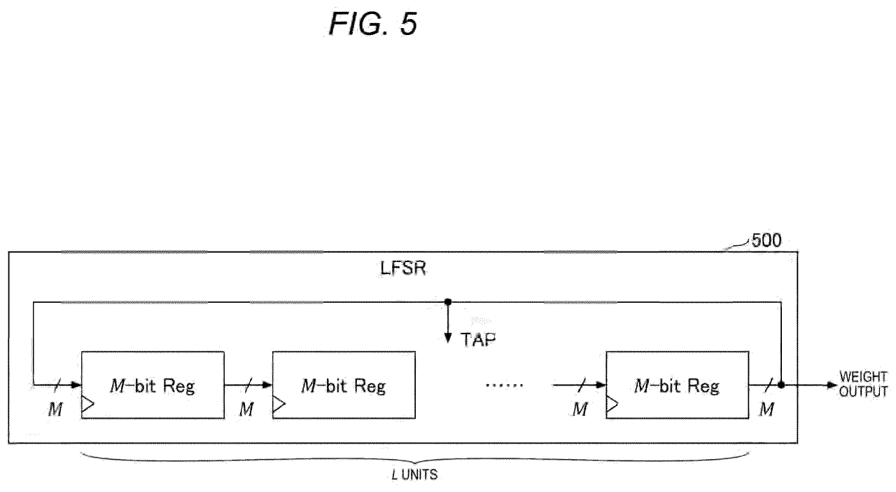

A detailed configuration for implementing the input weight generator 311, the connection weight generator 321, and the feedback weight generator 401 using a linear feedback shift register (LFSR) will be described. FIG. 5 is a diagram illustrating an example of the LFSR. As illustrated in FIG. 5, an LFSR 500 includes L M-bit registers. In the LFSR, cycles of wᵢ^{Iraw}, wᵢⱼ^{raw}, and wᵢ^{Fraw} output from the input weight generator 311, the connection weight generator 321, and the feedback weight generator 401, respectively, are determined by the number L of M-bit registers. Specifically, the following is established.
For wᵢ^{Iraw} output from the input weight generator 311, the cycle N is implemented by L=log₂ N.
For wᵢ^{Fraw} output from the feedback weight generator 401, the cycle N is implemented by L=log₂ N.
For wᵢⱼ^{raw} output from the connection weight generator 321, the cycle N² is implemented by L=log₂ N².

### (3-1-2) Details of Chaotic Circuit

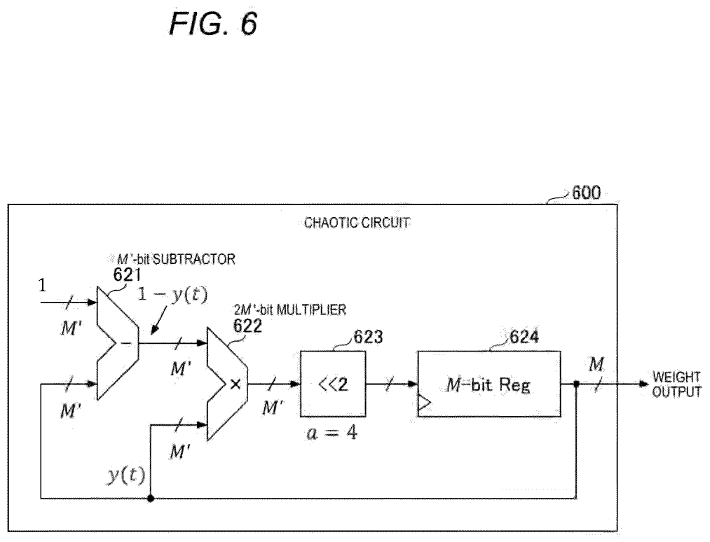

Next, a detailed configuration for implementing the input weight generator 311, the connection weight generator 321, and the feedback weight generator 401 using a chaotic circuit will be described. FIG. 6 is a diagram illustrating an example of the chaotic circuit. In the present embodiment, a chaotic circuit 600 uses occurrence of chaos at a=4 in a logistic map (a quadratic function represented by y(t+1)=a×y(t)×(1−y(t))).

As illustrated in FIG. 6, the chaotic circuit 600 includes art M′-bit subtractor 621, a 2M′-bit multiplier 622, a shifter 623, and an M′-bit register 624. In the chaotic circuit. 600, the cycles of wᵢ^{Iraw}, wᵢⱼ^{raw}, and wᵢ^{Fraw} output from the input weight generator 311, the connection weight generator 321, and the feedback weight generator 401, respectively, are determined by a value of M′. Specifically, the cycles are as follows:
for wᵢ^{Iraw} output from the input weight generator 311, M′=cycle N or greater,
for wᵢ^{Fraw} output from the feedback weight generator 401, M′=cycle N or greater, and
for wᵢⱼ^{raw} output from the connection weight generator 321, M′=cycle N² or greater.

Implementation of the input weight generator 311, the connection weight generator 321, and the feedback weight generator 401 using the LFSR 500 and using the chaotic circuit 600 has the following advantages.
The LFSR 500 does not include a subtractor or a multiplier. Thus, fewer resources are used when the number (N) of reservoir nodes is small (that is, when the number of M-bit registers is small).
The chaotic circuit 600 does not change in configuration even when the number (N) of reservoir nodes is increased. Thus, fewer resources are used when the number (N) of reservoir nodes is large.
   (3-2) Overview of nI-Bit Right Shifter, nb-Bit Right Shifter, and nF-Bit Right Shifter (Overview of input Weight, Connection Weight, and Feedback Weight)

Next, an overview of the input weight, the connection weight, and the feedback weight calculated by the nI-bit right shifter 312, the nb-bit right shifter 322, and the nF-bit right shifter 402, respectively, included in the reservoir device 202 will be described.

As described above, the reservoir device 202 calculates (2^{-nI})×(the output wᵢ^{Iraw} of the input weight generator) by shifting the output wᵢ^{Iraw} of the input weight generator 311 to the right by nI bits and outputs the input weight wᵢ^{I}.

The reservoir device 202 calculates (2^{-nb})×(the output wᵢⱼ^{raw} of the connection weight generator) by shifting the output wᵢⱼ^{raw} of the connection weight generator 321 to the right by nb bits and outputs the connection weight wᵢⱼ.

The reservoir device 202 calculates (2^{-nF})×(the output wᵢ^{Fraw} of the feedback weight generator) by shifting the output wᵢ^{Fraw} of the feedback weight generator 401 to the right by nF bits and outputs the feedback weight wᵢ^{F}.

In the reservoir device 202, the connection weight wᵢⱼ needs to satisfy a necessary condition of an echo state property (ESP). That is, the output wᵢⱼ^{raw} of the connection weight generator 321 needs to be scaled to a value satisfying the necessary condition of the ESP in the nb-bit right shifter 322, and parameters used for scaling are set in advance in the nb-bit right shifter 322.

In the reservoir device 202, the input weight wᵢ^{I} can be optimized by scaling the whole input weights (i=1, 2, . . . N) in accordance with a condition of the input sensor data. That is, parameters used for scaling are set in advance in the nI-bit right shifter 312 in order to scale the output wᵢ^{Iraw} of the input weight generator 311 to an optimal value.

The feedback weight wᵢ^{F} can be optimized by scaling the whole feedback weights (i=1, 2, . . . N) in accordance with the prediction result data obtained one timing ago. That is, parameters used for scaling are set in advance in the nF-bit right shifter 402 in order to scale the output wᵢ^{Fraw} of the feedback weight generator 401 to an optimal value.

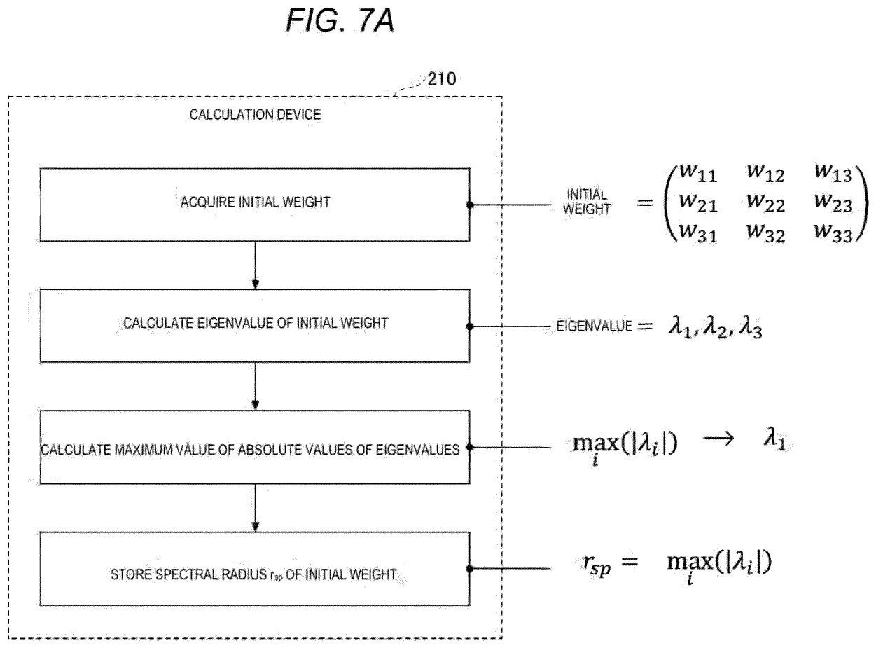

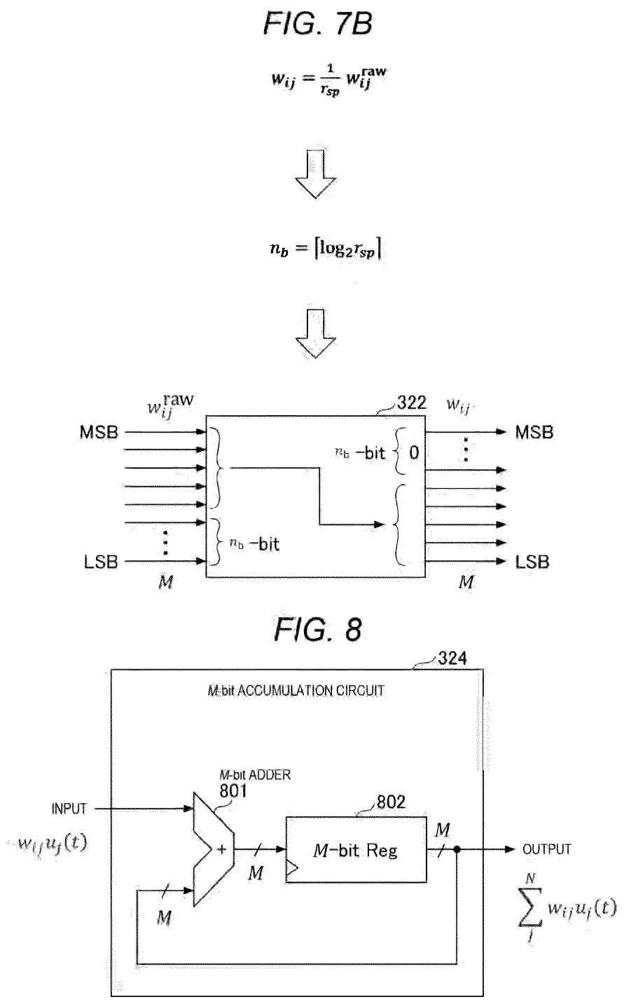

FIG. 7A is a diagram illustrating a method of calculating the parameters used for scaling and, for example, illustrates a method of calculating the parameters used for scaling the connection weight.

As illustrated in FIG. 7A, the calculation device 210 acquires a possible value (referred to as an initial weight) of the output wᵢⱼ^{raw} of the connection weight generator 321. For convenience of description, the example of FIG. 7A indicates a state where nine initial weights are acquired.

Next, the calculation device 210 calculates an eigenvalue of the initial weight (an eigenvalue of linear algebra). The example of FIG. 7A indicates a state where λ₁, λ₂, and λ₃ are calculated as the eigenvalues of the initial weight.

Next, the calculation device 210 calculates a maximum value of absolute values of the eigenvalues. The example of FIG. 7A indicates that the maximum value of the absolute values of the eigenvalues is λ₁. Next, the calculation device 210 stores the maximum value of the absolute values of the eigenvalues as a spectral radius rₛₚ of the initial weight.

The necessary condition of the ESP is “the maximum value of the absolute values of the eigenvalues (that is, the spectral radius rₛₚ of the initial weight) is less than 1”. Therefore, in the reservoir device 202, a spectral radius of the connection weight output from the nb-bit right shifter 322 is configured to be less than 1 (configured to satisfy the necessary condition of the ESP) by
setting the spectral radius rₛₚ calculated in the calculation device 210, in the nb-bit right shifter 322, and
multiplying the output wᵢⱼ^{raw} of the connection weight generator by (1/spectral radius rₛₚ) in the nb-bit right shifter 322.

### (3-2-1) Details of Nb-Bit Right Shifter

Next, details of the nb-bit right shifter 322 configured to satisfy the necessary condition of the ESP will be described. As described above, in order to satisfy the necessary condition of the ESP, the nb-bit right shifter 322 performs scaling by multiplying the output wᵢⱼ^{raw} of the connection weight generator by (1/spectral radius rₛₚ).

In the present embodiment, in order to facilitate processing of multiplying the output wᵢⱼ^{raw} of the connection weight generator by (i/spectral radius rₛₚ), the processing is substituted by logarithmically quantizing the spectral radius rₛₚ and using a bit shift operation. Thus, according to the present embodiment, scaling can be implemented with fewer resources.

FIG. 7B is a diagram illustrating an example of the nb-bit right shifter. As illustrated in FIG. 7B, the nb-bit right shifter 322 executes processing of shifting the output wᵢⱼ^{raw} of the connection weight generator to the right by nb bits (nb=[log₂ rₛₚ]).

When the input sensor data (the sensor data a′) is excessively large, the nI-bit right shifter 312 performs scaling to obtain an optimal multiplication result by increasing a value of nI bits.

In the nF-bit right shifter 402, when a value of nF bits is increased, feedback based on the prediction result data obtained one timing ago is decreased. Conversely, when the value of nF bits is reduced, the feedback is increased. Therefore, the nF-bit right shifter 402 adjusts a degree of feedback in accordance with a characteristic of the prediction result data.

### (3-3) Details of M-Bit Accumulation Circuit

Next, details of the M-bit accumulation circuit 324 included in the reservoir device 202 will be described. FIG. 8 is a diagram illustrating art example of a detailed configuration of the M-bit accumulation circuit. As illustrated in FIG. 8, the M-bit accumulation circuit 324 includes an M-bit adder 801 and an M-bit register 802.

The M-bit adder 801 receives input of the output (wᵢⱼ)×(uⱼ(t)) of the 2M-bit multiplier 323 and adds the input to an addition result output from the M-bit register 802.

The M-bit register 802 returns the addition result to the M-bit adder 801, and when addition corresponding to the number N of reservoir nodes is completed, resets the addition result after outputting N addition results.

### (3-4) Overview of Activation Function Circuit

Next, an overview of the activation function circuit 332 included in the reservoir device 202 will be described. As described above, while tan h (the hyperbolic tangent function) is used in the activation function in outputting the reservoir feature value, the activation function circuit 332 of the present embodiment uses the activation function f.

The following requirements are considered as requirements necessary for the activation function used for outputting the reservoir feature value.
The activation function is an odd function symmetric with respect to the origin.
The activation function has nonlinearity.
The activation function can be calculated by simple circuit calculation.
A output value of the activation function does not fall outside a range of ±1.

Therefore, in the present embodiment, the activation function f satisfying the requirements is as follows.
The activation function f is represented using fixed-point or floating-point polynomial calculation in which a coefficient aᵢ=(i=1, 2, . . . 2p−1) is variable.
In order to obtain the odd function symmetric with respect to the origin, an even-power (even function) term is multiplied by sgn(−x) in the form of the activation function f.

Specifically, the activation function f is as follows.

$$\begin{matrix}[ Equation 7 ] & \\ f ( x ) = \text{?} + sgn ( - x ) \text{?} & ( 7 )\end{matrix}$$

$$\text{?} \text{indicates text missing or illegible when filed}$$

(p is an odd number)

i In Equation (7), for example, with p=5 and coefficient aᵢ=1 (i=1, 2, . . . 2p−1), the activation function f can be represented as follows.

$$\begin{matrix}[ Equation 8 ] & \\ f ( x ) = x + {x}^{3} + {x}^{5} + {x}^{7} + {x}^{9} + sgn ( - x ) \cdot ( {x}^{2} + {x}^{4} + {x}^{6} + {x}^{8} ) & ( 8 )\end{matrix}$$

For simplification of description, the coefficient aᵢ (i=1, 2, . . . 2p−1) is 1.

The activation function circuit 332 of the present embodiment is configured to use the activation function f instead of tan h as a function satisfying the necessary requirements as the activation function. Thus, according to the present embodiment, the activation function circuit. 332 does not need to use a large-size LUT, and resources of the reservoir device 202 can be reduced.

### (3-4-1) Details of Activation Function Circuit

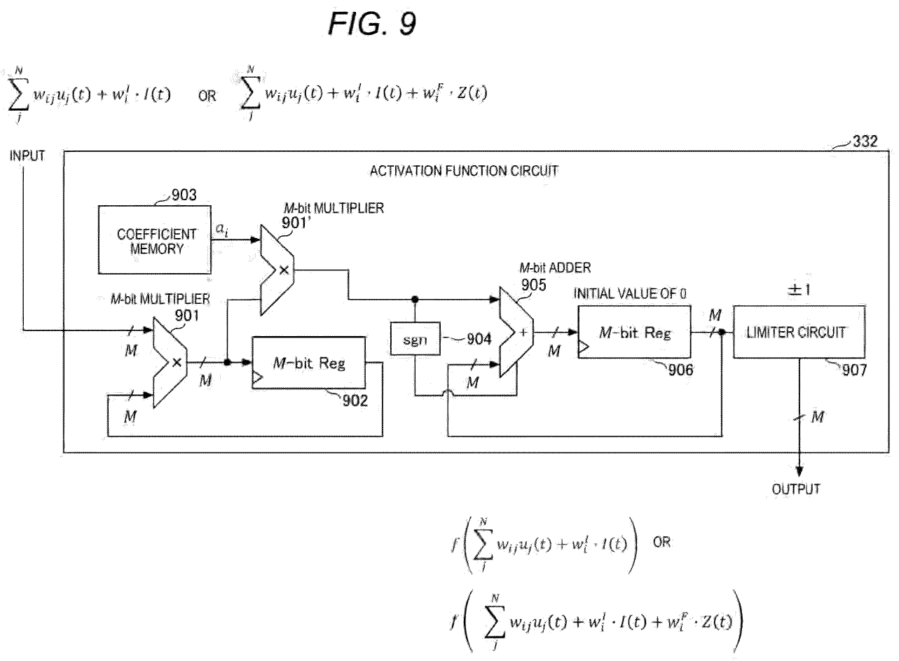

Next, details of the activation function circuit 332 configured to execute the activation function f of Equation (7) will be described. FIG. 9 is a diagram illustrating an example of a detailed configuration of the activation function circuit. As illustrated in FIG. 9, the activation function circuit 332 includes an M-bit multiplier 901, an M-bit multiplier 901′, an M-bit register 902, a coefficient memory 903, an sgn operator 904, an M-bit adder 905, an M-bit register 906, and a limiter circuit 907.

When the calculation result of Equation (5) or the calculation result of Equation (6) is sequentially input into the M-bit multiplier 901, the M-bit multiplier 901 multiplies a multiplication result output from the M-bit register 902 by the input. The M-bit multiplier 901′ multiplies a multiplication result output from the M-bit multiplier 901 by the corresponding coefficient aᵢ (i=1, 2, . . . 2p−1). The M-bit multiplier 901′ inputs the multiplication result into the M-bit adder 905 and the sgn operator 904.

The M-bit register 902 sequentially stores the multiplication result sequentially output from the M-bit multiplier 901.

The sgn operator 904 is a sign determination circuit and outputs a plus sign for an odd-numbered multiplication result and a minus sign for an even-numbered multiplication result among multiplication results output from the M-bit multiplier 901′.

The M-bit adder 905 adds the odd-numbered multiplication result among the multiplication results output from the M-bit multiplier 901′ to a calculation result stored in the M-bit register 906. The M-bit adder 905 subtracts the even-numbered multiplication result among the multiplication results output from the M-bit multiplier 901′ from the calculation result stored in the M-bit register 906. The M-bit adder 905 inputs the calculation results after addition and subtraction into the M-bit register 906.

The M-bit register 906 sequentially stores the calculation results sequentially output from the M-bit adder 905. When all calculation results are stored in the M-bit register 906, all calculation results are read by the limiter circuit 907.

The limiter circuit 907 reads all calculation results from the M-bit register 906, and when the calculation result exceeding upper and lower limit values is included, replaces the calculation result exceeding the upper and lower limit values with the upper and lower limit values and outputs the replaced calculation result.

### (3-4-2) Details of Limiter Circuit in Activation Function Circuit

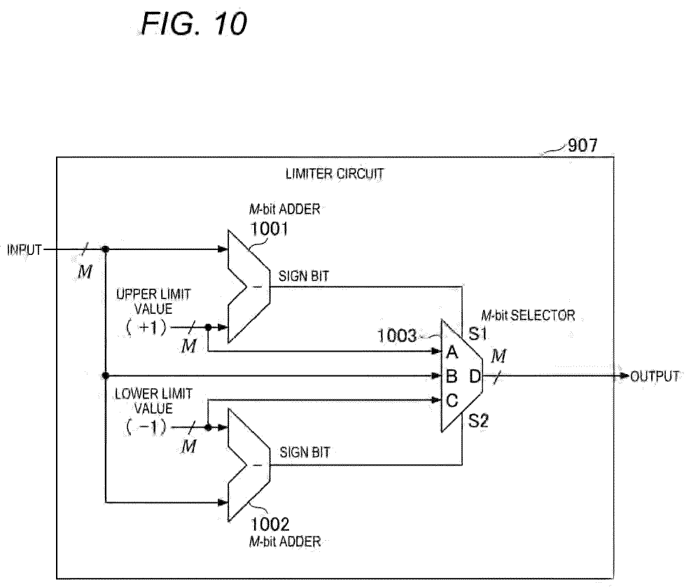

Next, details of the limiter circuit 907 included in the activation function circuit 332 will be described. FIG. 10 is a diagram illustrating an example of the limiter circuit. As illustrated in FIG. 10, the limiter circuit 907 includes an M-bit adder 1001, an M-bit adder 1002, and an M-bit selector 1003.

The M-bit adder 1001 receives input of all calculation results read from the M-bit register 906, calculates a difference with respect to the upper limit value, and inputs a sign bit indicating a sign (+ or −) of the calculation result to the M-bit selector 1003.

The M-bit adder 1002 receives input of all calculation results read from the M-bit register 906, calculates a difference with respect to the lower limit value, and inputs a sign bit indicating a sign (+ or −) of the calculation result to the M-bit selector 1003.

The M-bit selector 1003 receives input of all calculation results read from the M-bit register 906 and selects and outputs any one of the calculation result or the upper limit value in accordance with the sign bit input from the M-bit adder 1001.

The M-bit selector 1003 receives input of all calculation results read from the M-bit register 906 and selects and outputs any one of the calculation result or the lower limit value in accordance with the sign bit input from the M-bit adder 1002.

(3-4-3) Coefficient aᵢ (i=1, 2, . . . 2p−1) Set in Activation Function Circuit

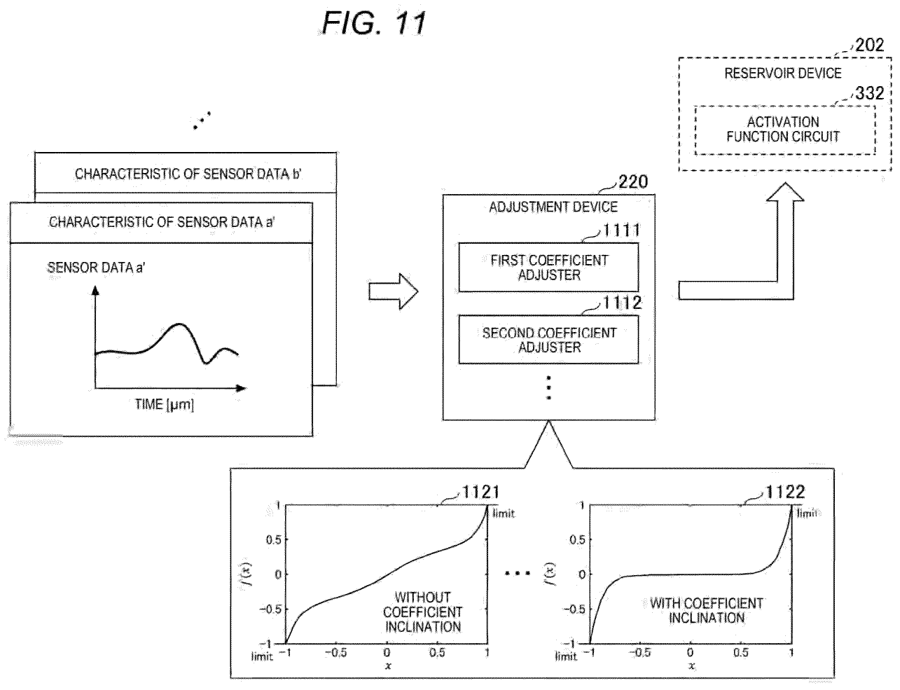

Next, details of processing of the adjustment device 220 configured to adjust the coefficient aᵢ (i=1, 2, . . . 2p−1) set in the activation function circuit 332 will be described. FIG. 11 is a diagram illustrating a specific example of processing of the adjustment device configured to adjust the coefficient of the polynomial of the activation function.

As described above, the adjustment device 220 calculates the coefficient aᵢ (i=1, 2, . . . 2p−1) used for processing of the activation function circuit 332 in advance and sets the coefficient aᵢ in the coefficient memory 903 (an example of a holder). Specifically, as illustrated in FIG. 11, the adjustment device 220 includes a first coefficient adjuster 1111, a second coefficient adjuster 1112, . . . for as many as the number of pieces of sensor data.

For example, the first coefficient adjuster 1111 adjusts the coefficient aᵢ (i=1, 2, . . . 2p−1) in accordance with the characteristic of the sensor data a′. The second coefficient adjuster 1112 adjusts the coefficient aᵢ (i=1, 2, . . . 2p−1) in accordance with a characteristic of the sensor data b′.

The adjusted coefficient aᵢ (i=1, 2, . . . 2p−1) adjusted by the adjustment device 220 is set in the activation function circuit 332 of the reservoir device 202. The first coefficient adjuster 1111, the second coefficient adjuster 1112, . . . and the like perform any method of adjusting the coefficient aᵢ (i=1, 2, . . . 2p−1).

For example, as described using Equation (8), with p=5 and the coefficient aᵢ (i=1, 2, . . . 2p−1)=1, the activation function f has a value indicated by the reference sign 1121 of FIG. 11. The activation function f having the value indicated by the reference sign 1121 has a large storage capacity with a low order and a zero storage capacity with a high order. The storage capacity is an indicator representing how far back to use the value of the sensor data used by the reservoir device to calculate the reservoir feature value.

Accordingly, the activation function f having the value indicated by the reference sign 1121 is effective for calculating the reservoir feature value using the low-order value furthest in the past, that is, when the characteristic of the sensor data is linear or weakly nonlinear.

Meanwhile, p=5 and the coefficient aᵢ (i=1, 2, . . . 2p−1) with inclination indicated in, for example, Equation (9) are considered.

$$\begin{matrix}[ Equation 9 ] & \\ f ( x ) = sgn ( - x ) \times ( \frac{{x}^{2}}{256} + \frac{{x}^{4}}{64} + \frac{{x}^{6}}{16} + \frac{{x}^{8}}{4} ) + ( \frac{x}{256} + \frac{{x}^{3}}{64} + \frac{{x}^{5}}{16} + \frac{{x}^{7}}{4} + {x}^{9} ) & ( 9 )\end{matrix}$$

In this case, the activation function f has a value indicated by the reference sign 1122 of FIG. 11. The activation function f having the value indicated by the reference sign 1122 has a low value of the storage capacity with either a low order or a high order (however, the storage capacity is not zero).

Accordingly, the activation function f having the value indicated by the reference sign 1122 is effective for calculating the reservoir feature value using a high-order value, that is, when the characteristic of the sensor data is nonlinear.

By representing the activation function f using fixed-point or floating-point polynomial calculation, the reservoir device 202 according to the present embodiment can calculate the reservoir feature value corresponding to the characteristic of the sensor data.

### (4) Details of Functional Configuration of Process State Predictor 204

Next, details of a functional configuration of the process state predictor 204 will be described. As described above, the process state predictor 204 operates in a plurality of periods. Therefore, hereinafter, a relationship between the periods will be described first using a transition diagram of each period, and the functional configuration of the process state predictor 204 for each period will be described next.

### (4-1) Relationship Between Each of Periods

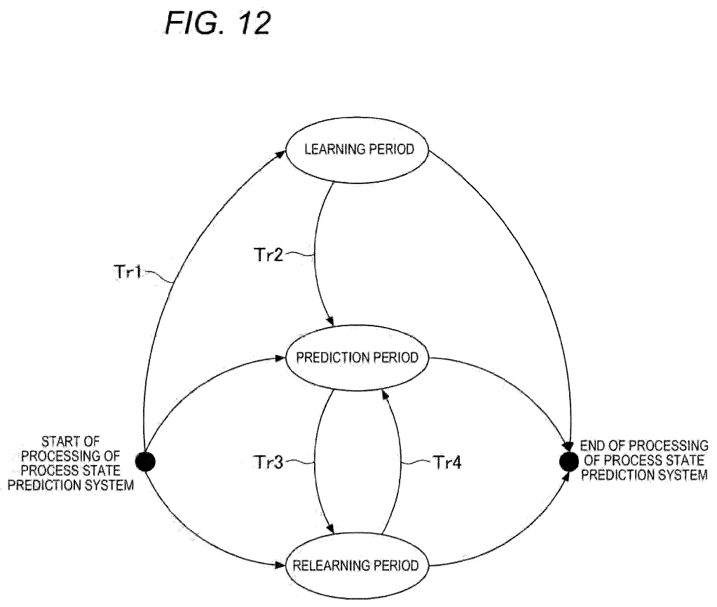

FIG. 12 is an example of the transition diagram of each period to which the process state predictor transitions. As illustrated in FIG. 12, when processing of the process state prediction system 128 starts, the process state predictor 204 starts operation by transitioning to any period (any period of the learning period, the prediction period, or the relearning period). For simplification of description, starting operation by transitioning to the learning period will be described.

When the process state predictor 204 receives input of the switching information from the management device 123 and transitions to the learning period (arrow Tr1), the process state predictor 204 calculates the weight parameter by performing the learning processing for a predetermined learning time using the reservoir feature value and the process state data (the ground truth data).

When the learning processing ends, the process state predictor 204 outputs the end information and transitions to the prediction period by receiving input of the switching information from the management device 123 (arrow Tr2). In the prediction period, the process state predictor 204 performs prediction processing based on the calculated weight parameter and outputs the prediction result data based on the reservoir feature value.

While the process state predictor 204 is performing the prediction processing in the prediction period, the management device 123 determines whether relearning is necessary. When the management device 123 determines that relearning is necessary, the management device 123 inputs the switching information into the process state predictor 204. Accordingly, the process state predictor 204 transitions to the relearning period (arrow Tr3).

In the relearning period, the process state predictor 204 calculates the weight parameter for each learning parameter set by performing the relearning processing while changing the learning parameter set (to be described in detail later). Next, the process state predictor 204 performs the prediction processing in a state where each calculated weight parameter is set, and outputs the prediction result data. The management device 123 specifies the weight parameter corresponding to the prediction result data falling within an allowable range and having the highest prediction accuracy and inputs the switching information into the process state predictor 204. Accordingly, the process state predictor 204 transitions to the prediction period (arrow Tr4).

### (4-2) Functional Configuration of Process State Predictor 204 in Learning Period

Next, a functional configuration of the process state predictor 204 in each period will be described. First, a functional configuration of the process state predictor 204 in the learning period will be described. FIG. 12 is a diagram illustrating an example of the functional configuration of the process state predictor in the learning period.

As illustrated in FIG. 12, the process state predictor 204 functions as a First-Order Reduced and Controlled Error (FORCE) learner 1200 based on the recursive least squares in the learning period. In the present embodiment, “learning parameter set 0” is set in the FORCE learner 1200 based on the recursive least squares, and the FORCE learner 1200 performs FORCE learning processing based on the recursive least squares through the following processing procedure (refer to the reference sign 1201). In each drawing below, “τ” denotes a time axis of the process state predictor 204 and is a time one clock behind real time (t) (τ=t−1). Accordingly, for example, S(τ+1) in the drawing is represented by S(t) in real time.

### 1) Calculation of Output Data

When the FORCE learner 1200 acquires the reservoir feature value (a vector R), the FORCE learner 1200 calculates output data (Z) by multiplying the reservoir feature value by a transposed vector obtained by transposing a recursive weight parameter (a vector W). In the present embodiment, the recursive weight parameter (the vector W) refers to the weight parameter recursively updated during the FORCE learning processing based on the recursive least squares.

### 2) Calculation of Error

The FORCE learner 1200 calculates error (e) between the output data (Z) and the process state data (S).

### 3) Calculation of Coefficient Matrix

The FORCE learner 1200 calculates a coefficient matrix (a matrix P) used for calculating the recursive weight parameter (the vector W).

### 4) Calculation of Recursive Weight Parameter

The FORCE learner 1200 updates the recursive weight parameter (the vector W) based on the calculated error (e), the acquired reservoir feature value (the vector R), and the calculated coefficient matrix (the matrix P).

The FORCE learner 1200 calculates the weight parameter by repeating the processing of 1) to 4) for the predetermined learning time.

### (4-3) Functional Configuration of Process State Predictor 204 in Prediction Period

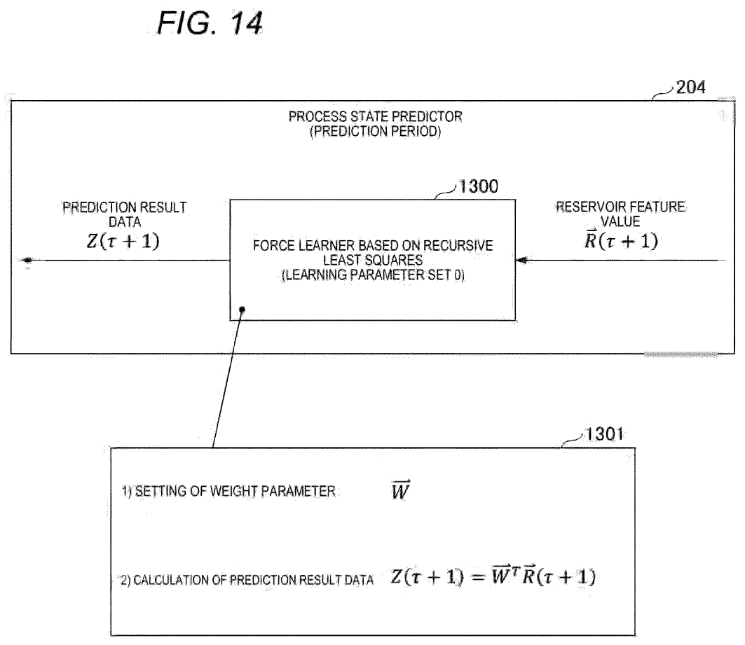

Next, a functional configuration of the process state predictor 204 in the prediction period will be described. FIG. 14 is a diagram illustrating an example of the functional configuration of the process state predictor in the prediction period.

As illustrated in FIG. 14, the process state predictor 204 functions as a FORCE learner 1300 based on the recursive least squares in the prediction period. In the present embodiment, the FORCE learner 1300 refers to a state where the weight parameter calculated by performing the FORCE learning processing in the FORCE learner 1200 is set and where the prediction result data (Z) can be output. The FORCE learner 1300 performs the prediction processing through the following processing procedure (refer to the reference sign 1301).

1) The FORCE learner 1300 sets the weight parameter (the vector W) calculated by performing the FORCE learning processing.

2) When the FORCE learner 1300 acquires the reservoir feature value (the vector R), the FORCE learner 1300 multiplies the reservoir feature value by a transposed vector obtained by transposing the weight parameter (the vector W) and outputs the prediction result data (Z).

### (4-4) Functional Configuration of Process State Predictor 204 in Relearning Period

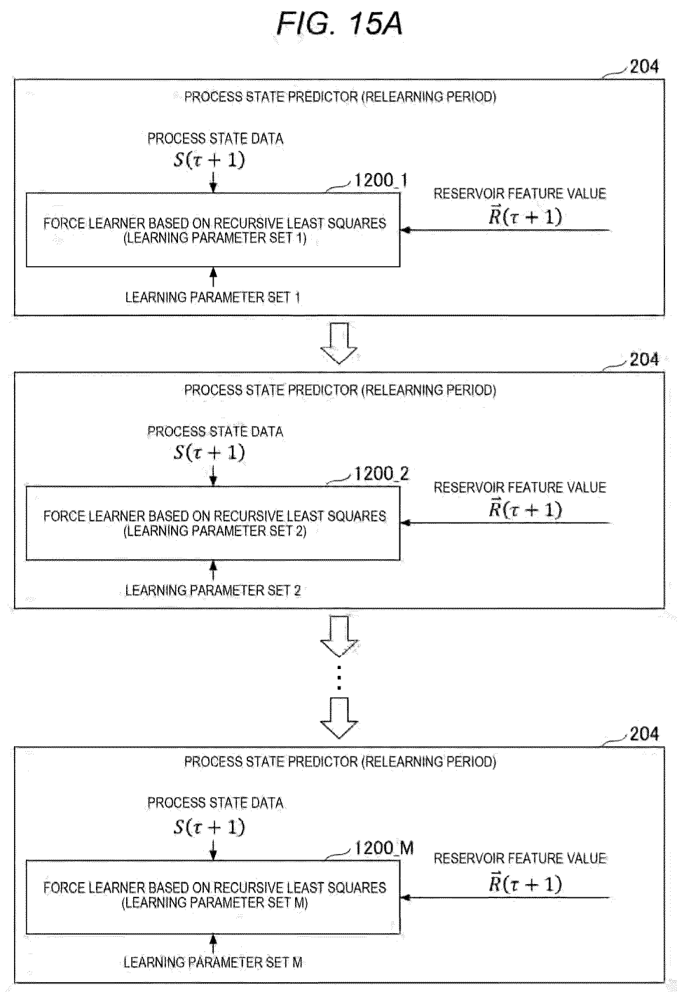

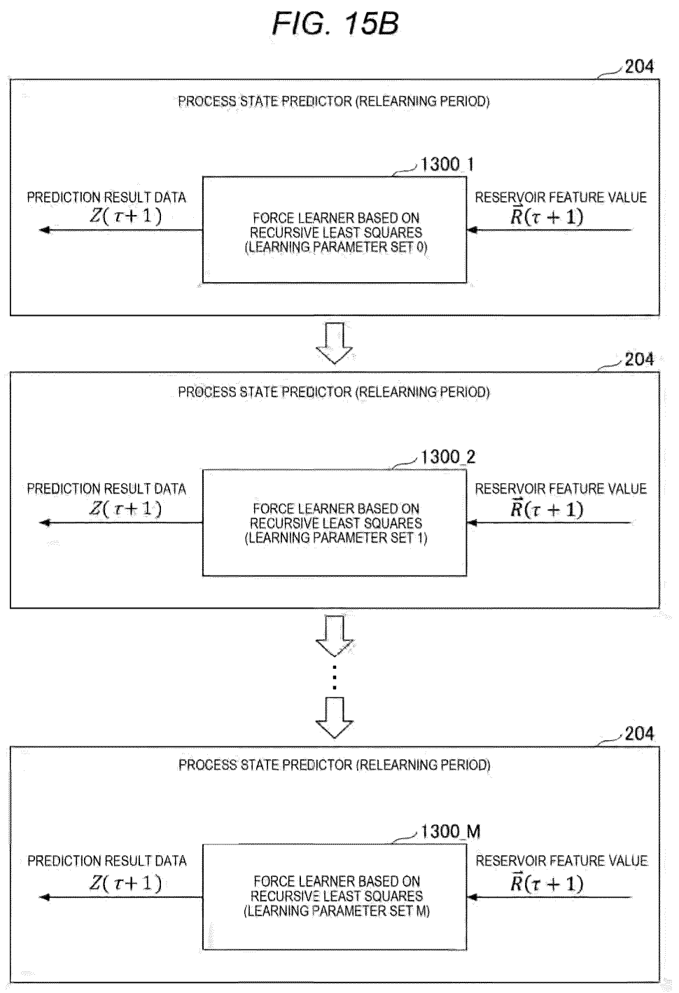

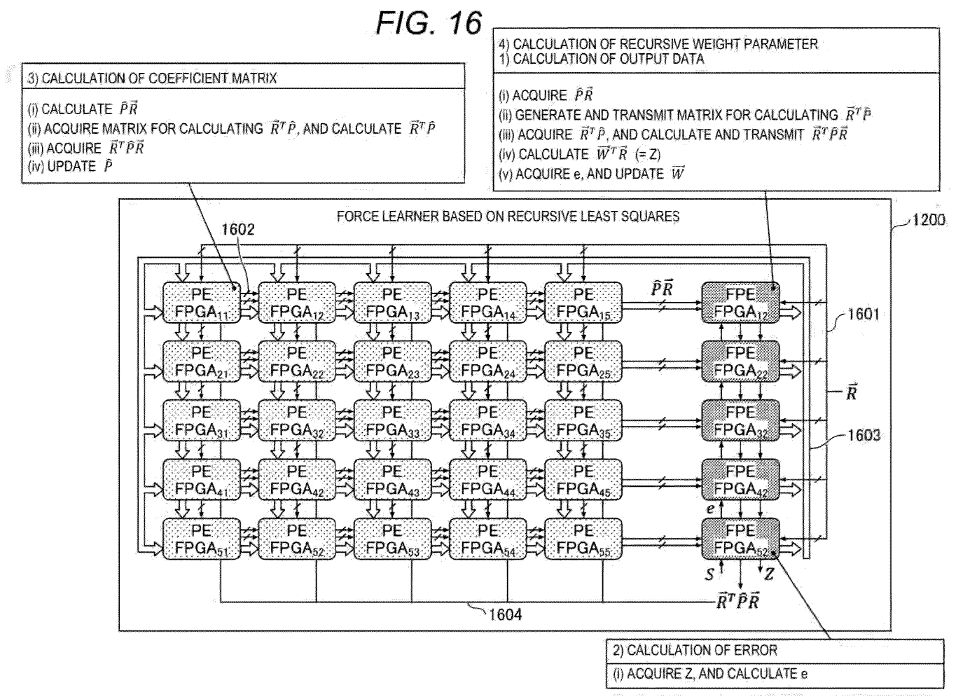

Next, a functional configuration of the process state predictor 204 in the relearning period will be described. FIGS. 15A and 15B are first and second diagrams illustrating an example of the functional configuration of the process state predictor in the relearning period.

As illustrated in FIGS. 15A and 15B, the process state predictor 204 functions as FORCE learners 1200_1 to 1200_H based on the recursive least squares and FORCE learners 1300_1 to 1300_M based on the recursive least squares: in the relearning period.

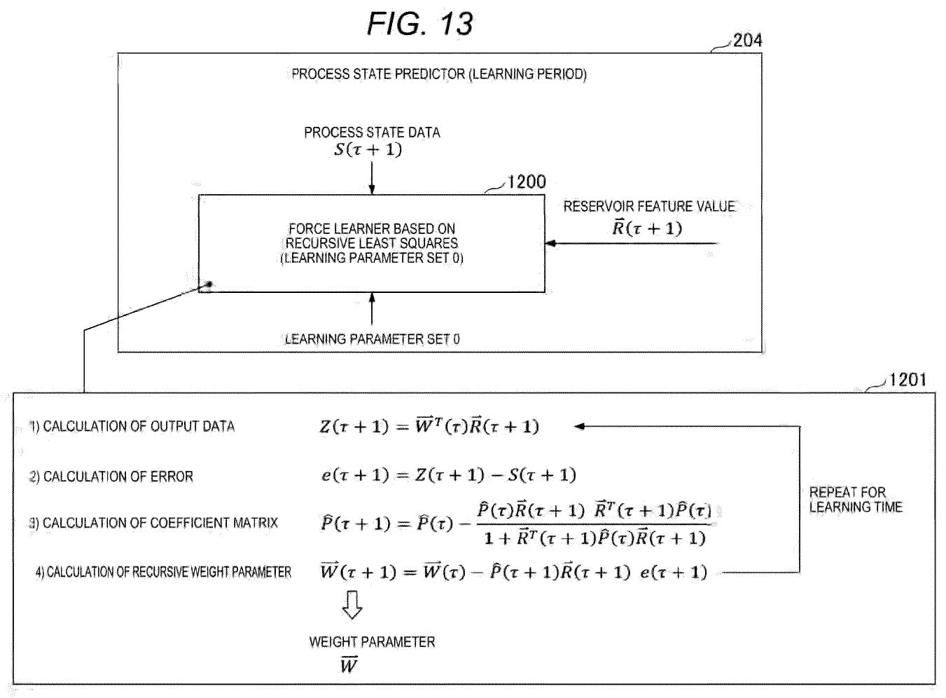

In the present embodiment, “learning parameter set 1” is set in the FORCE learner 1200_1 of FIG. 15A, and the FORCE learning processing based on the recursive least squares is performed through the processing procedure described in FIG. 13 (refer to the reference sign 1201).

In the present embodiment, the FORCE learner 1300_1 of FIG. 15B refers to a state where the weight parameter calculated by performing the FORCE learning processing in the FORCE learner 1200_1 is set and where the prediction result data (Z) can be output. When the FORCE learner 1300_1 acquires the reservoir feature value, the FORCE learner 1300_1 multiplies the reservoir feature value by the transposed vector obtained by transposing the weight parameter and outputs the prediction result data.

Similarly, “learning parameter set 2” is set in the FORCE learner 1200_2 of FIG. 15A, and the FORCE learning processing based on the recursive least squares is performed through the processing procedure described in FIG. 13 (refer to the reference sign 1201).

In the present embodiment, the FORCE learner 1300_2 of FIG. 15B refers to a state where the weight parameter calculated by performing the FORCE learning processing in the FORCE learner 1200_2 is set and where the prediction result data (Z) can be output. When the FORCE learner 1300_2 acquires the reservoir feature value, the FORCE learner 1300_2 multiplies the reservoir feature value by the transposed vector obtained by transposing the weight parameter and outputs the prediction result data.

Similarly, “learning parameter set M” is set in the FORCE learner 1200_M of FIG. 15A, and the FORCE learning processing based on the recursive least squares is performed through the processing procedure described in FIG. 13 (refer to the reference sign 1201).

In the present embodiment, the FORCE learner 1300_M of FIG. 15B refers to a state where the weight parameter calculated by performing the FORCE learning processing in the FORCE learner 1200_M is set and where the prediction result data (Z) can be output. When the FORCE learner 1300_M acquires the reservoir feature value, the FORCE learner 1300_M multiplies the reservoir feature value by the transposed vector obtained by transposing the weight parameter and outputs the prediction result data.

As described above, when processing ends based on the functional configurations illustrated in FIGS. 15A and 15B in the relearning period, a transition is made to the prediction period again, and processing is performed based on the functional configuration illustrated in FIG. 14. In the prediction period after relearning, the process state predictor 204 functions as a FORCE learner 1300_X based on the recursive least squares. The FORCE learner 1300_X refers to, among the FORCE learners 1300_1 to 1300_M,
the FORCE learner in which “learning parameter set X” is set, and
the FORCE learner in which the weight parameter that achieves that the output prediction result data falls within a predetermined allowable range and that achieves the highest prediction accuracy is set. The learning parameter set X is a learning parameter set used when the output prediction result data falls within the predetermined allowable range and the highest prediction accuracy is calculated.

### (5) Details of Hardware Configuration of FORCE Learner Based on Recursive Least Squares

Next, a hardware configuration of the FORCE learner functioning as the FORCE learners 1200, 1200_1 to 1200_M, 1300, and 1300_1 to 1300_M based on the recursive least squares will be described. In the present embodiment, the FORCE learners 1200, 1200_1 to 1200_M, 1300, and 1300_1 to 1300_M use common hardware. Thus, a hardware configuration of the FORCE learner 1200 will be described below.

### (5-1) Overall Configuration

FIG. 16 is a diagram illustrating an example of the hardware configuration of the FORCE learner based on the recursive least squares.

As illustrated in FIG. 16, the FORCE learner 1200 based on the recursive least squares includes
a plurality of (in the example of FIG. 16, 25) field programmable gate arrays (FPGAs) functioning as processing elements (PEs), and
a plurality of (in the example of FIG. 16, five) FPGAs functioning as functional PEs (FPEs). In FIG. 16, the FPGA part may be implemented by a dedicated chip.

Each of the plurality of FPGAs functioning as the PEs executes 3) calculation of the coefficient matrix in the processing procedures of 1) to 4) of the FORCE learning based on the recursive least squares described using FIG. 13. Specifically, each of the plurality of FPGAs functioning as the PEs calculates the coefficient matrix (the matrix P) through the following procedure.

(i) When a part of the reservoir feature value (the vector R) is input through a signal line 1601, a product of the part of the reservoir feature value and a part of the coefficient matrix (the matrix P) is calculated, and a calculation result is transmitted to an adjacent FPGA through a signal line 1602.

(ii) From the FPGA functioning as the FPE, a matrix for calculating a product of the transposed vector obtained by transposing the part of the reservoir feature value (the vector R) and the part of the coefficient matrix (the matrix P) is acquired through a signal line 1603. The product of the transposed vector obtained by transposing the part of the reservoir feature value (the vector R) and the part of the coefficient matrix (the matrix P) is calculated using the acquired matrix.

(iii) From the FPGA functioning as the FPE, a calculation result of the product of the transposed vector obtained by transposing the part of the reservoir feature value (the vector R), the part of the coefficient matrix (the matrix P), and the part of the reservoir feature value (the vector R) is acquired through a signal line 1604.

(iv) The whole coefficient matrix (the matrix P) is updated using the calculation result calculated by performing (i) to (iii) or the acquired calculation result.

Each of the plurality of FPGAs functioning as the PEs repeats execution of (i) to (iv).

Meanwhile, each of the plurality of FPGAs functioning as the FPEs executes (4) calculation of the recursive weight parameter and (1) calculation of the output data in the processing procedures of 1) to 4) of the FORCE learning processing based on the recursive least squares described using FIG. 13. Specifically, each of the plurality of FPGAs functioning as the FPEs calculates the recursive weight parameter and the output data through the following procedure.

(i) From the FPGA functioning as the PE, the calculation result of the product of the part of the coefficient matrix (the matrix P) and the part of the reservoir feature value (the vector R) is acquired through the signal line 1602.

(ii) The matrix for calculating the product of the transposed vector obtained by transposing the part of the reservoir feature value (the vector R) and the part of the coefficient matrix (the matrix P) is generated and transmitted to the plurality of FPGAs functioning as the PEs through the signal line 1603.

(iii) A calculation result of the product of the transposed vector obtained by transposing the part of the reservoir feature value (the vector R) and the part of the coefficient matrix (the matrix P) is acquired. A calculation result obtained by multiplying the acquired calculation result by the part of the reservoir feature value (the vector R) is transmitted to the plurality of FPGAs functioning as the PEs through the signal line 1604.

(iv) A part of the output data (Z) is calculated by calculating a product of a transposed vector obtained by transposing a part of the recursive weight parameter (the vector W) and the part of the reservoir feature value (the vector R) acquired through the signal line 1601.

(v) The error (e) is acquired, and the whole recursive weight parameter (the vector W) is updated using the calculation result of (i).

Each of the plurality of FPGAs functioning as the FPEs repeats execution of (i) to (v).

Meanwhile, the FPGA positioned in the last stage among the plurality of FPGAs functioning as the FPEs executes 2) calculation of the error in addition to 4) calculation of the recursive weight parameter and 1) calculation of the output data. Specifically, the FPGA positioned in the last stage among the plurality of FPGAs functioning as the FPEs calculates the error through the following procedure.

(i) The error (e) is calculated by aggregating all of the parts of the output data (Z) acquired from each FPGA positioned in an upper stage and calculating a difference with respect to the process state data (S). The calculated error (e) is transmitted to each FPGA positioned in the upper stage.

The FORCE learner 1200 based on the recursive least squares implements the FORCE learning processing based on the recursive least squares by executing the processing procedures of 1) to 4) using the plurality of FPGAs functioning as the PEs and the plurality of FPGAs functioning as the FPEs.

### (5-2) Details of Processing of Each FPGA

Next, details of processing of each FPGA included in the FORCE learner 1200 based on the recursive least squares will be described.

### (5-2-1) Part 1 of Details of Processing of FPGA Functioning as PE

First, details of processing of the FPGA functioning as the PE will be described. As described above, when the reservoir feature value (the vector R) is input, the FPGA functioning as the PE calculates the product of the reservoir feature value (the vector R) and the coefficient matrix (the matrix P).

In the FORCE learner 1200 based on the recursive least squares, each of the plurality of FPGAs functioning as the PEs and disposed in a vertical direction calculates the product of the part of the coefficient matrix (the matrix P) and the part of the reservoir feature value (the vector R). Accordingly, the FORCE learner 1200 based on the recursive least squares can parallelly perform processing of multiplying parts of the coefficient matrix (the matrix P) different from each other by the same part of the reservoir feature value (the vector P) in parallel.

In the FORCE learner 1200 based on the recursive least squares, each of the plurality of PEs disposed in a horizontal direction serially processes the part of the reservoir feature value (the vector R) obtained by dividing the reservoir feature value (the vector R), which is time series data.

By combining parallel processing and serial processing with each other in implementing the FORCE learning processing based on the recursive least squares, the number of operations of one FPGA can be reduced. Consequently, the FORCE learner 1200 based on the recursive least squares can increase a speed of the FORCE learning processing.

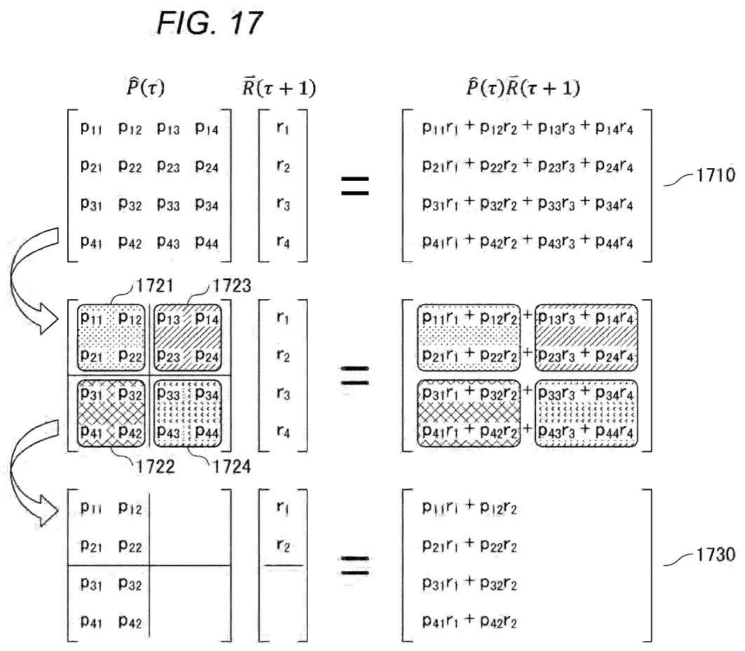

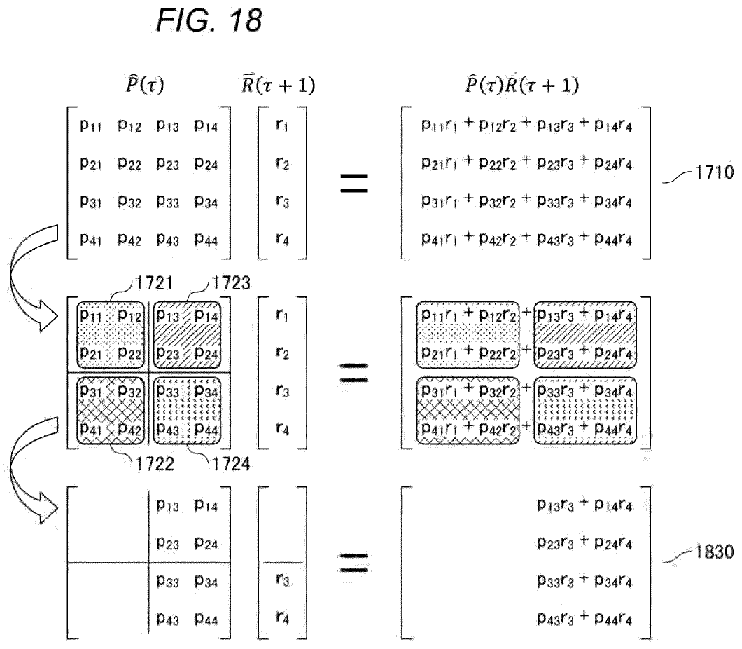

FIGS. 17 and 18 are first and second diagrams illustrating the parallel processing and the serial processing implemented in the FORCE learner based on the recursive least squares. In FIGS. 17 and 18, for simplification of description, the number of output-side electrodes is “4” (the number of elements of the reservoir feature value (the vector R) is four). Only two FPGAs functioning as the PEs in the vertical direction and only two FPGAs functioning as the PEs in the horizontal direction (total four) are illustrated (refer to FPGAs 1721, 1722, 1723, and 1724).

The product of the coefficient matrix (the matrix P) and the reservoir feature value (the vector R) is executed using one FPGA. In this case, 16 multiplications are needed, as indicated by the reference sign 1710. Meanwhile, the number of multiplications can be reduced to half by disposing two FPGAs functioning as the PEs in the vertical direction. The number of multiplications can be further reduced to half by disposing two FPGAs functioning as the PEs in the horizontal direction and dividing the reservoir feature value (the vector R) into two parts and inputting the divided part into each FPGA.

In FIG. 17, the reference sign 1730 indicates a state where (r₁, r₂), which is a part of the reservoir feature value (the vector R) in the vector R divided into two parts, is input into each of the FPGAs 1721 and 1722 and where each of the FPGAs 1721 and 1722 executes four multiplications.

In FIG. 18, the reference sign 1830 indicates a state where (r₃, r₄), which is a part of the reservoir feature value (the vector PR) in the reservoir feature value (the vector R) divided into two parts, is input into each of the FPGAs 1723 and 1724. The reference sign 1830 indicates a state where each of the FPGAs 1723 and 1724 executes four multiplications.

The FORCE learner 1200 based on the recursive least squares is configured such that the plurality of FPGAs functioning as the PEs are disposed in the vertical direction and the horizontal direction and each FPGA executes a part of matrix operations of a plurality of rows and a plurality of columns executed in the FORCE learning processing.

Accordingly, the FORCE learner 1200 based on the recursive least squares can increase the speed of the FORCE learning processing based on the recursive least squares.

### (5-2-2) Part 2 of Details of Processing of FPGA Functioning as PE

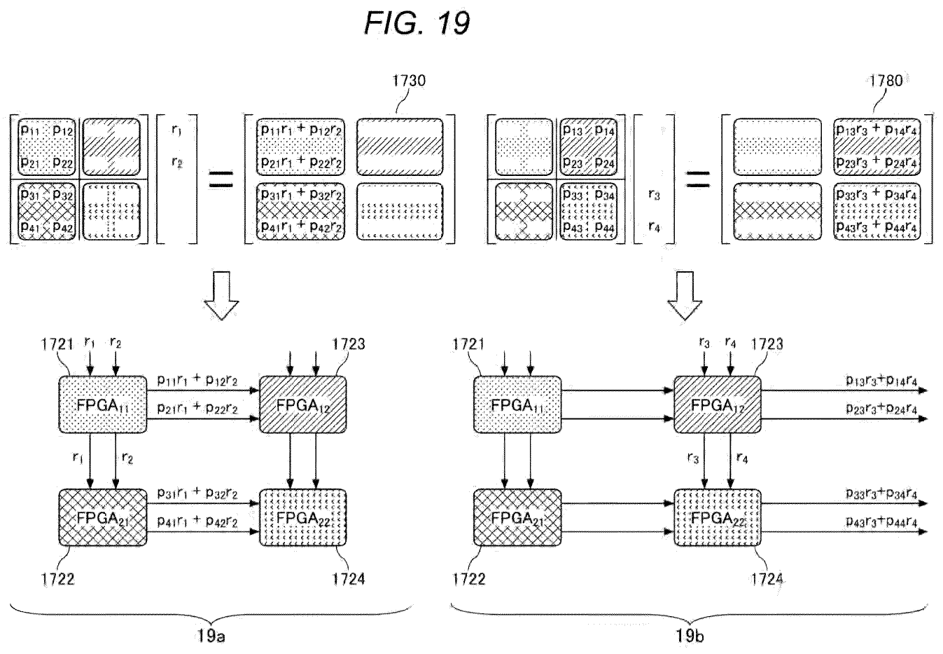

Next, details of transmission processing as processing of the FPGA functioning as the PE will be described. As described above, the FPGA functioning as the PE transmits the calculation result of the product of the coefficient matrix (the matrix P) and the reservoir feature value (the vector R) to the adjacent FPGA. FIG. 19 is a first diagram illustrating the transmission processing implemented in the FORCE learner based on the recursive least squares.

19a of FIG. 19 illustrates a state where each of the FPGAs 1721 and 1722 executes the product of (r₁, r₂), which is the part of the reservoir feature value (the vector R) in the reservoir feature value (the vector R) divided into two parts, and the part of the coefficient matrix (the matrix P). 19a of FIG. 19 illustrates a state where the FPGAs 1721 and 1722 transmit execution results to the FPGAs 1723 and 1724, respectively.

As illustrated in 19a of FIG. 19, from the FPGA 1721, p₁₁r₁+p₁₂r₂ and p₂₁r₁+p₂₂r₂, which are the calculation results, are transmitted to the FPGA 1723 over one clock. From the FPGA 1722, p₃₁r₁+p₃₂r₂ and p₄₁r₁+p₄₂r₂ are transmitted to the FPGA 1724 over one clock. Here, p₃₁r₁+p₃₂r₂ and p₄₁r₁+p₄₂r₂ are the calculation results of the product of (r₁, r₂), which is the part of the reservoir feature value (the vector R) transmitted to the FPGA 1722 from the FPGA 1721 over one clock, and the part of the coefficient matrix (the matrix P).

Meanwhile, 19b of FIG. 19 illustrates a state where each of the FPGAs 1723 and 1724 executes the product of (r₃, r₄), which is the part of the reservoir feature value (the vector R) in the reservoir feature value (the vector R) divided into two parts, and the part of the coefficient matrix (the matrix P). 19b of FIG. 19 illustrates a state where each of the FPGAs 1723 and 1724 transmits an execution result to the adjacent FPGA on the right (not illustrated).

As illustrated in 19b of FIG. 19, from the FPGA 1723, an addition result obtained by adding p₃₁r₃+p₁₄r₄, which is a calculation result, to p₁₁r₁+p₁₂r₂, which is a transmission result, is transmitted to the FPGA (not illustrated). From the FPGA 1723, an addition result obtained by adding p₂₃r₃+p₂₄r₄, which is a calculation result, to p₂₁r₁+p₂₂r₂, which is a transmission result, is transmitted to the FPGA (not illustrated).

From the FPGA 1724, an addition result obtained by adding p₃₃r₃+p₃₄r₄, which is a calculation result, to p₃₁r₁+p₃₂r₂, which is a transmission result, is transmitted to the FPGA (not illustrated). From the FPGA 1724, an addition result obtained by adding p₄r₃+p₄₄r₄, which is a calculation result, to p₄₁r₁+p₄₂r₂, which is a transmission result, is transmitted to the FPGA (not illustrated).

### (5-2-3) Part 1 of Details of Processing of FPGA Functioning as FPE

Next, details of processing of the FPGA functioning as the FPE will be described. As described above, the FPGA, functioning as the FPE executes “substitution processing” of generating the matrix for calculating “the product of the transposed vector obtained by transposing the part of the reservoir feature value (the vector R) and the part of the coefficient matrix (the matrix P)” used for calculating the coefficient matrix (the matrix P).

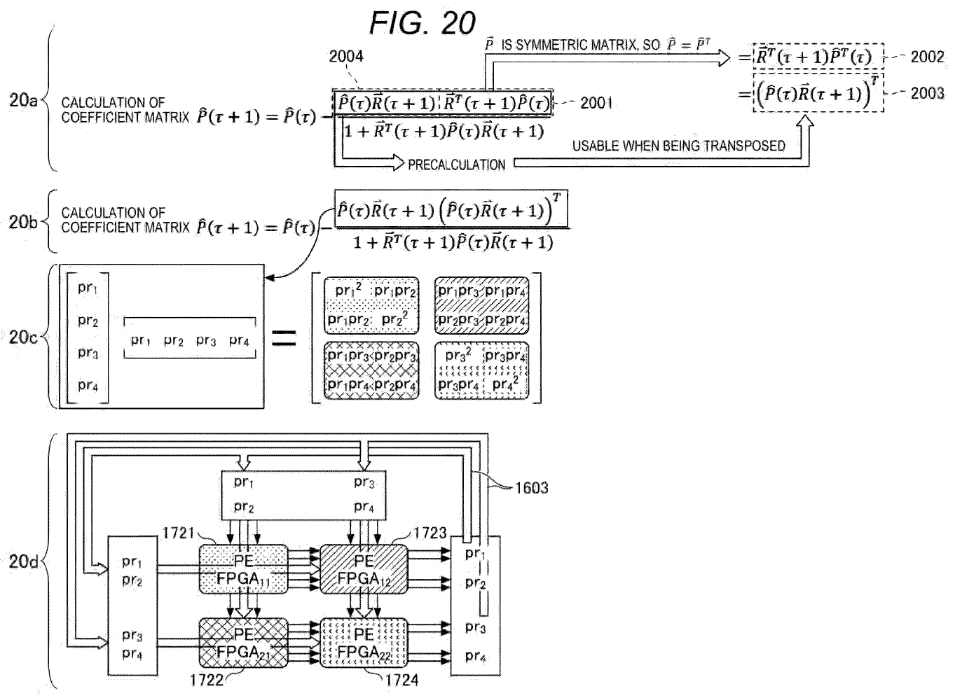

FIG. 20 is a diagram illustrating the substitution processing implemented in the FORCE learner based on the recursive least squares. 20a of FIG. 20 illustrates a relationship between calculation of the coefficient matrix (the matrix P) and the substitution processing. As illustrated in 20a of FIG. 20, in “the product of the transposed matrix obtained by transposing the reservoir feature value (the vector R) and the coefficient matrix (the matrix P)” (the reference sign 2001) to be calculated in calculating the coefficient matrix (the matrix P), the coefficient matrix (the matrix P) is a symmetric matrix (has symmetry). Thus, the coefficient matrix (the matrix P) is equal to the transposed matrix obtained by transposing the coefficient matrix (the matrix P).

Accordingly,
“the product of the transposed matrix obtained by transposing the reservoir feature value (the vector R) and the coefficient matrix (the matrix P)” (the reference sign 2001)
   is equal to
“the product of the transposed matrix obtained by transposing the reservoir feature value (the vector P) and the transposed matrix obtained by transposing the coefficient matrix (the matrix P)” (the reference sign 2002). That is, the above is equal to “a transposed matrix obtained by transposing the product of the reservoir feature value (the vector R) and the coefficient matrix (the matrix P)” (the reference sign 2003).

Here, “the product of the reservoir feature value (the vector R) and the coefficient matrix (the matrix P)” is already calculated when the product is calculated (the reference sign 2004). Thus, by transposing the calculation result using symmetry, the transposed calculation result can be substituted for “the product of the transposed matrix obtained by transposing the reservoir feature value (the vector R) and the coefficient matrix (the matrix P)” (the reference sign 2001).

20b of FIG. 20 illustrates a mathematical equation after substitution when
“the product of the transposed matrix obtained by transposing the reservoir feature value (the vector R) and the coefficient matrix (the matrix P)” (the reference sign 2001)
   is substituted with
“the transposed matrix obtained by transposing the product of the reservoir feature value (the vector R) and the coefficient matrix (the matrix P)” (the reference sign 2003)
   in calculating the coefficient matrix (the matrix P).

The right-hand side of 20c of FIG. 20 indicates the calculation result and indicates which pr is necessary for each element of the matrix on the right-hand side among pr₁, pr₂, pr₃, and pr₄. The upper left element of the matrix needs pr₁ and pr₂, the lower left element and the upper right element need pr₁, pr₂, pr₃, and pr₄, and the lower right element needs pr₃ and pr₄.

20d of FIG. 20 illustrates a state where the FPGA functioning as the FPE (not illustrated) transmits a vector for calculating
“the product of the part of the coefficient matrix (the matrix P) and the part of the reservoir feature value (the vector R)”, and
“the transposed vector obtained by transposing the product of the part of the “coefficient matrix (the matrix P) and the part of the reservoir feature value (the vector R)”
   to the FPGAs 1721 to 1724 through the signal line 1603. 20d of FIG. 20 illustrates a state where the FPGAs 1721 to 1724 calculate a product of
“the product of the part of the coefficient matrix (the matrix P) and the part of the reservoir feature value (the vector R)”, and
“the transposed vector obtained by transposing the product of the part of the coefficient matrix (the matrix P) and the part of the reservoir feature value (the vector R)”.

Specifically, the FPGA 1721, the FPGA 1722, the FPGA 1723, and the FPGA 1724 calculate a product of the upper left element, a product of the lower left element, a product of the upper right element, and a product of the lower right element, respectively, of the matrix on the right-hand side of 20c of FIG. 2f).

In performing an operation including a transposed vector and executed in the FORCE learning processing based on the recursive least squares, the FORCE learner 1200 based on the recursive least squares substitutes the operation by acquiring an operation result of an operation not including a transposed vector and transposing the acquired operation result.

Accordingly, the FORCE learner 1200 based on the recursive least squares can reduce the number of operations in implementing the FORCE learning processing based on the recursive least squares. Consequently, the FORCE learner 1200 based on the recursive least squares can increase the speed of the FORCE learning processing.

### (5-2-4) Part 1 of Details of Processing of FPGA Functioning as FPE

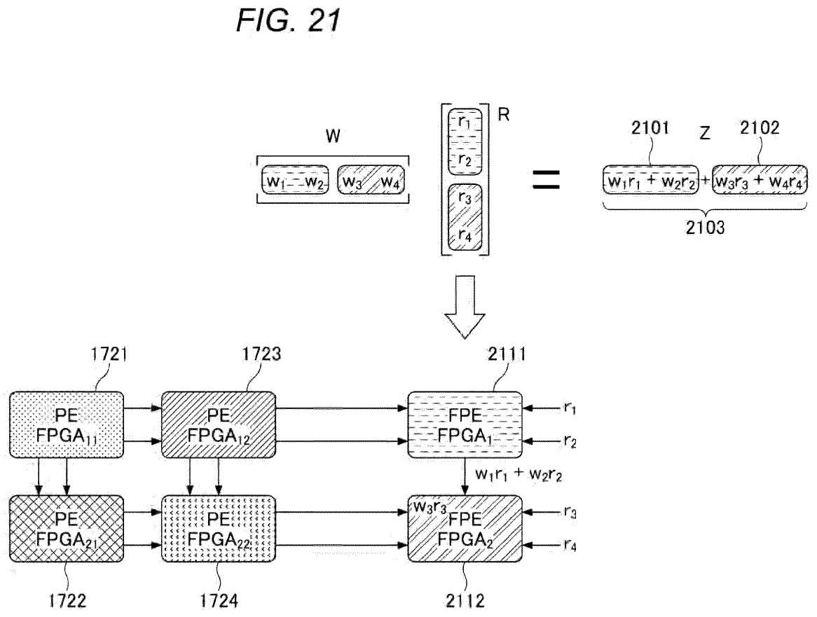

Next, details of the transmission processing of the FPGA functioning as the FPE will be described. As described above, when the part of the reservoir feature value (the vector R) is input, the FPGA functioning as the FPE calculates the product of the part of the reservoir feature value and the part of the recursive weight parameter (the vector W) and transmits the part of the output data (Z), which is the calculation result, to the adjacent FPGA. FIG. 21 is a second diagram illustrating the transmission processing implemented in the FORCE learner based on the recursive least squares.

As illustrated in FIG. 21, an FPGA 2111 calculates a product of
(r₁, r₂), which is the part of the reservoir feature value (the vector R) in the reservoir feature value (the vector R) divided into two parts, and
(w₁, w₂), which is the part of the recursive weight parameter (the vector W), and
   transmits a calculation result (the reference sign 2101) to an FPGA 2112. The FPGA 2111 transmits w₁r₁+w₂r₂, which is the calculation result (the reference sign 2101), to the FPGA 2112 over one clock.

The FPGA 2112 calculates the product of (r₃, r₄), which is the part of the reservoir feature value (the vector R) in the reservoir feature value (the vector R) divided into two parts, and (w₃, w₄), which is the part of the recursive weight parameter (the vector Wt. The FPGA 2112 adds the calculation result (the reference sign 2102) to the calculation result (the reference sign 2101) transmitted from the FPGA 2111 and obtains an addition result (the reference sign 2103).

### (5-2-5) Part 2 of Details of Processing of FPGA Functioning as FPE

Next, details of processing of the FPGA functioning as the FPE will be described. As described above, the FPGA functioning as the FPE acquires the calculation result of the product of the part of the reservoir feature value (the vector R) and the part of the coefficient matrix (the matrix P). The FPGA functioning as the FPE calculates the product of the part of the reservoir feature value (the vector R), the part of the coefficient matrix (the matrix P), and the transposed vector obtained by transposing the part of the reservoir feature value (the vector R) acquired through the signal line 1601. The FPGA functioning as the FPE executes distribution processing of distributing the calculation result to the FPGAs functioning as the PEs.

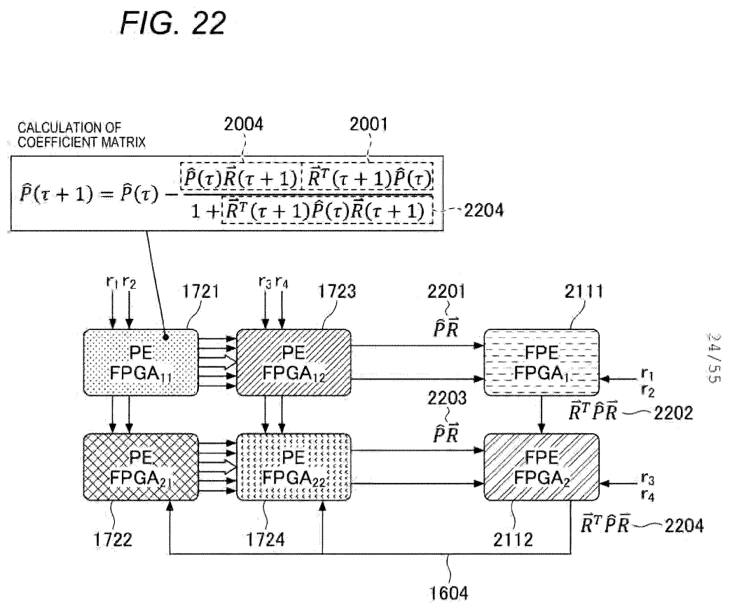

FIG. 22 is a diagram illustrating the distribution processing implemented in the FORCE learner based on the recursive least squares. As illustrated in FIG. 22, the FPGA 2111 functioning as the FPE acquires the calculation result (the reference sign 2201) of the product of the part of the coefficient matrix (the matrix P) and the part of the vector R from the corresponding FPGA functioning as the PE. The FPGA 2111 functioning as the FPE calculates the product of the acquired calculation result (the reference sign 2201) and the transposed vector obtained by transposing the part (r₁, r₂) of the reservoir feature value (the vector R) and transmits the calculation result (the reference sign 2202) to the FPGA 2112.

The FPGA 2112 functioning as the FPE acquires the calculation result (the reference sign 2203) of the product of the part of the coefficient matrix (the matrix P) and the part of the vector R from the corresponding FPGA functioning as the PE. The FPGA 2112 functioning as the FPE calculates the product of the acquired calculation result (the reference sign 2202) and the transposed vector obtained by transposing the part (r₃, r₄) of the reservoir feature value (the vector R). The FPGA 2112 functioning as the FPE adds the calculation result to the calculation result (the reference sign 2202) transmitted from the FPGA 2111. The FPGA 2112 functioning as the FPE transmits the addition result (the reference sign 2204) to the FPGAs 1721 to 1724 functioning as the PEs through the signal line 1604.

Accordingly, each of the FPGAs 1721 to 1724 can calculate the part of the coefficient matrix (the matrix Q). For example, the following applies to the FPGA 1721.
“The product of the part of the reservoir feature value (the vector R) and the part of the coefficient matrix (the matrix P)” (the reference sign 2004) is calculated in advance.
“The product of the transposed vector obtained by transposing the part of the reservoir feature value (the vector R) and the part of the coefficient matrix (the matrix P)” (the reference sign 2001) is calculated through the substitution processing based on the matrix acquired through the signal line 1603, as described in FIG. 20.
“The product of the transposed vector obtained by transposing the part of the reservoir feature value (the vector R), the part of the coefficient matrix (the matrix P), and the part of the reservoir feature value (the vector R)” (the reference sign 2204) is acquired through the signal line 1604.

Accordingly, the FPGA 1721 to the FPGA 1724 can calculate the coefficient matrix (the matrix P).

### (5-2-6) Part 3 of Details of Processing of FPGA Functioning as FPE

Next, details of processing of the FPGA functioning as the FPE will be described. As described above, the FPGA positioned in the last stage among the FPGAs functioning as the FPEs executes calculation of the error in addition to calculation of the recursive weight parameter and calculation of the output data.

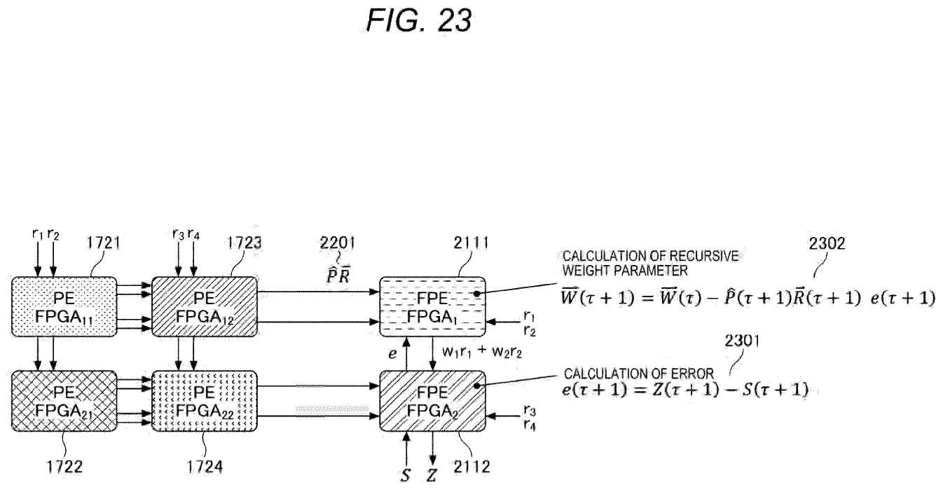

FIG. 23 is a diagram illustrating weight parameter update processing implemented in the FORCE learner based on the recursive least squares. As illustrated in FIG. 23, the FPGA 2112 positioned in the last stage calculates the part (=w₃r₃+w₄r₄) of the output data (Z). The FPGA 2112 positioned in the last stage aggregates the output data (Z) by adding the calculated part to the part (=w₁r₁+w₂r₂) of the output data (Z) acquired from the FPGA 2111 functioning as the FPE.

The FPGA 2112 positioned in the last stage calculates the error (e) by calculating a difference between the aggregated output data (Z) and the process state data (S) (the reference sign 2301). The FPGA 2112 positioned in the last stage transmits the calculated error (e) to the FPGA 2111 positioned in the upper stage. The FPGA 2111 and the FPGA 2112 update the recursive weight parameter using the calculated error (e).

For example, the FPGA 2111 acquires the calculation result (the reference sign 2201) of the product of the part of the reservoir feature value (the vector R) and the part of the coefficient matrix (the matrix P). The FPGA 2111 multiplies the calculation result by the error (e) obtained from the FPGA 2112 and subtracts the multiplied calculation result from the current recursive weight parameter (the vector W). Accordingly, the FPGA 2111 can update the recursive weight parameter (the vector W) (the reference sign 2302).

### (5-3) Timing Chart of FORCE Learning Processing Performed by FORCE Learner 1200 Based on Recursive Least Squares

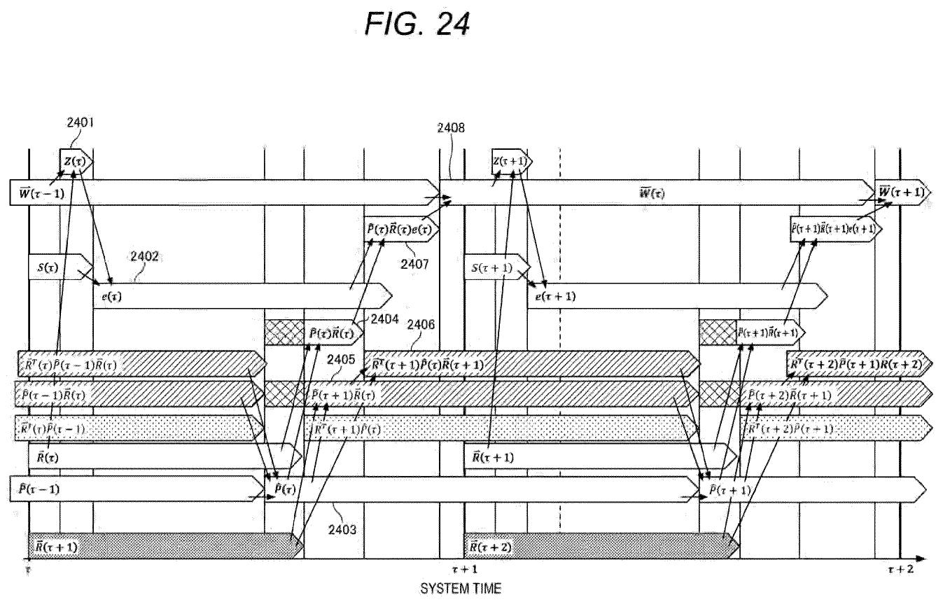

Next, a timing chart of the FORCE learning processing performed by the FORCE learner 1200 based on the recursive least squares will be described. FIG. 24 is an example of the timing chart of the FORCE learning processing performed by the FORCE learner based on the recursive least squares.

As illustrated in FIG. 24, the FPGA functioning as the FPE calculates the output data (Z(τ)) by calculating the product of
the recursive weight parameter (the vector W(τ−1)), and
the reservoir feature value (the vector R(τ))
   (the reference sign 2401).

The FPGA functioning as the FPE calculates the error (e(τ)) based on the output data (Z(τ)) and the process state data (S(τ)) (the reference sign 2402).

The FPGA functioning as the PE calculates the coefficient matrix (the matrix P(τ)) based on
the product of the transposed vector obtained by transposing the reservoir feature value (the vector R(τ)), the coefficient matrix (the matrix P(τ−1)), and the reservoir feature value (the vector R(τ)),
the product of the coefficient matrix (the matrix P(τ−1)) and the reservoir feature value (the vector R(τ)), and
the coefficient matrix (the matrix P(τ−1))
   (the reference sign 2403).

The FPGA functioning as the PE calculates the product of the coefficient matrix (the matrix P(τ)) and the reservoir feature value (the vector R(τ)) (the reference sign 2404). The FPGA functioning as the PE calculates the product of the coefficient matrix (the matrix P(τ+1)) and the reservoir feature value (the vector R(τ)) (the reference sign 2405).

The FPGA functioning as the PE calculates the product of
the transposed vector obtained by transposing the reservoir feature value (the vector R(τ+1)), and
the calculation result of the product of the coefficient matrix (the matrix P(τ)) and the reservoir feature value (the vector R(τ+1))
   (the reference sign 2406).

Next, the FPGA functioning as the FPE calculates the product of
the calculation result of the product of the coefficient matrix (the matrix P(τ)) and the reservoir feature value (the vector R(τ)), and
the error (e(τ))
   (the reference sign 2407).

The FPGA functioning as the FPE updates the recursive weight parameter (the vector W(τ)) and calculates the recursive weight parameter (the vector. W(τ)) based on
the calculation result obtained by calculating the product of the coefficient matrix (the matrix P(τ)), the reservoir feature value (the vector R(τ)), and the error (e(τ)), and
the recursive weight parameter (the vector W(τ−1)) (the reference sign 2406).

Accordingly, the FPGA functioning as the FPE can calculate the output data (Z(τ+1)). Then, the same processing is repeated as system time passes.

As illustrated in FIG. 24, the FORCE learner 1200 based on the recursive least squares is configured such that execution timings of the product of the reservoir feature value (the vector R) and the coefficient matrix (the matrix P) executed between
calculation of the recursive weight parameter (the vector W(τ−1)), and
calculation of the recursive weight parameter (the vector W(τ))
   overlap with each other. Specifically, the FORCE learner 1200 based on the recursive least squares adjusts the execution timings by buffering calculation results in the FPGA functioning as the PE and the FPGA functioning as the FPE.

Accordingly, the FORCE learner 1200 based on the recursive least squares can reduce a time needed for updating the recursive weight parameter.

As described above, the process state predictor 204 is configured with hardware that performs the FORCE learning processing based on the recursive least squares, and processing for high-speed updating of the recursive weight parameter is performed. Accordingly, the process state predictor 204 can learn the weight parameter by detecting short behavior occurring in the sensor data.

According to the applicants of the present application, when each FPGA operates at 200 MHz, 960 [ns] is implemented as the time required for the FORCE learner 1200 to update the recursive weight parameter based on the recursive least squares.

### <Details of Management Device>

Next, details of the management device 123 connected to the process state prediction system 128 will be described.

### (1) Hardware Configuration of Management Device 123

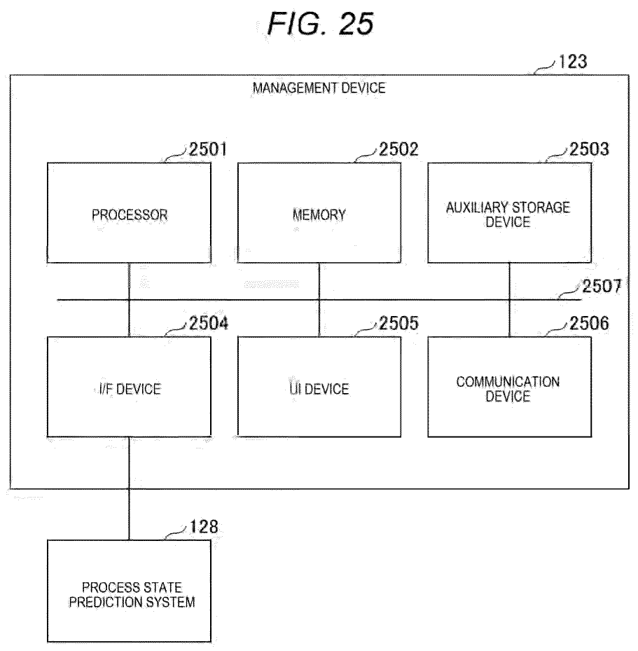

First, a hardware configuration of the management device 123 will be described. FIG. 25 is a diagram illustrating an example of the hardware configuration of the management device.

As illustrated, in FIG. 25, the management device 123 includes a processor 2501, a memory 2502, an auxiliary storage device 2503, an interface (I/F) device 2504, a UT device 2505, and a communication device 2506. Hardware units of the management device 123 are connected to each other through a bus 2507.

The processor 2501 includes various operation devices such as a central processing unit (CPU) and a graphics processing unit (GPU). The processor 2501 reads various programs (for example, a management program) onto the memory 2502 and executes the programs.

The memory 2502 includes a main storage device such as a read only memory (ROM) and a random access memory (RAM). The processor 2501 and the memory 2502 form a so-called computer, and the computer implements various functions by the processor 2501 executing the various programs read onto the memory 2502.

The auxiliary storage device 2503 stores the various programs and stores various data used by the processor 2501 to execute the various programs. A data storage 2607 (to be described later) is implemented in the auxiliary storage device 2503.

The I/F device 2504 is a connection device connected to the process state prediction system 128.

The UI device 2505 is a user interface device for allowing a manager of the management device 123 to input various instructions into the management device 123. The communication device 2506 is a communication device for communicating with an external device (not illustrated) through a network.

### (2) Functional Configuration of Manager 124

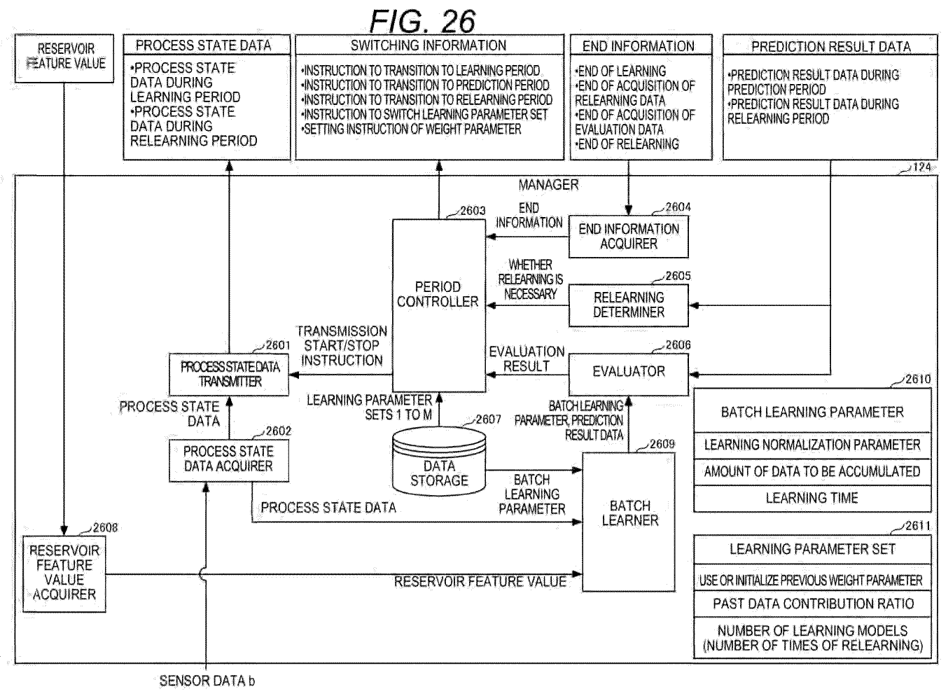

Next, a functional configuration of the manager 124 of the management device 123 will be described. FIG. 26 is a diagram illustrating an example of the functional configuration of the manager. As described above, the management program is installed on the management device 123, and by executing the program, the manager 124 of the management device 123 functions as
a process state data transmitter 2601,
a process state data acquirer 2602,
a period controller 2603,
an end information acquirer 2604,
a relearning determiner 2605,
an evaluator 2606,
a reservoir feature value acquirer 2608, and
a batch learner 2609.

Based on a transmission start/stop instruction from the period controller 2603, the process state data transmitter 2601, for example, receives the sensor data b transmitted from the sensor b 122b as the process state data (the ground truth data) through the process state data acquirer 2602. The process state data transmitter 2601 transmits the acquired process state data (the ground truth data) to the process state prediction system 128. The process state data transmitted by the process state data transmitter 2601 includes the process state data transmitted during the learning period and the process state data transmitted during the relearning period.

The process state data acquirer 2602 acquires the sensor data b transmitted from the sensor b 122b. The process state data acquirer 2602 notifies the process state data transmitter 2601 and the batch learner 2609 of the acquired sensor data b as the process state data.

The period controller 603 transmits various switching information to the process state prediction system 128. As illustrated in FIG. 26, the various switching information transmitted by the period controller 2603 includes
an instruction to transition to the learning period,
an instruction to transition to the prediction period,
an instruction to transition to the relearning period,
an instruction to switch the learning parameter set, and
a setting instruction of the weight parameter.

When processing of the process state prediction system 128 starts, the period controller 2603 transmits the instruction to transition to the learning period to the process state prediction system 128 and instructs the process state data transmitter 2601 to start transmitting the process state data.

When the period controller 2603 receives the end information of the FORCE learning processing from the end information acquirer 2604, the period controller 2603 transmits the instruction to transition to the prediction period to the process state prediction system 128. At that time, the period controller 2603 instructs the process state data transmitter 2601 to stop transmitting the process state data.

When the period controller 2603 receives a determination result indicating that relearning is necessary from the relearning determiner 2605, the period controller 2603 transmits the instruction to transition to the relearning period to the process state prediction system 128. At that time, the period controller 2603 instructs the process state data transmitter 2601 to start transmitting the process state data.

When the period controller 2603 acquires the end information of acquisition of relearning data and the end information of acquisition of evaluation data from the end information acquirer 2604, the period controller 2603 reads the learning parameter set from the data storage 2607 and transmits the learning parameter set to the process state prediction system 128. At that time, the period controller 2603 instructs the process state data transmitter 2601 to stop transmitting the process state data.

As illustrated in FIG. 26, the data storage 2607 stores the learning parameter set I to the learning parameter set M. The period controller 2603 transmits the read learning parameter set I to the read learning parameter set M to the process state prediction system 128.

As indicated by the reference sign 2611, the learning parameter set includes “use or initialize previous weight parameter”, “past data contribution ratio”, “number of learning models”, and the like as information items.

Each time the period controller 2603 acquires the end information of the FORCE relearning processing from the end information acquirer 2604, the period controller 2603 transmits the instruction to switch the learning parameter set to the process state prediction system 128.

As illustrated in FIG. 26, in the relearning period, the reservoir feature value acquirer 2608 acquires the reservoir feature value from the process state prediction system 128 as the learning data and the evaluation data and notifies the batch learner 2609 of the reservoir feature value. As described above, in the relearning period, the process state data acquirer 2602 acquires the sensor data b as the learning data and notifies the batch learner 2609 of the acquired sensor data b as the process state data.

The batch learner 2609 executes batch learning based on a batch learning parameter read from the data storage 2607, using the learning data obtained by accumulating the reservoir feature value and the process state data for the predetermined learning time. The batch learning refers to learning of the weight parameter from the reservoir feature value and the process state data obtained for the predetermined learning time.

The batch learning parameter used for the batch learning includes “learning normalization parameter”, “amount of data to be accumulated (a batch size)”, “learning time”, and the like as information items.

When the batch learning is completed, the batch learner 2609 predicts the process state data based on the reservoir feature value acquired as the evaluation data and notifies the evaluator 2606 of a prediction result (a batch learning prediction result) of the batch learner 2609.

The period controller 2603 receives an evaluation result from the evaluator 2606 and transmits the setting instruction, of the weight parameter to the process state prediction system 128 based on the received evaluation result.

The evaluation result includes the prediction accuracy calculated for each prediction result data by performing the prediction processing on the evaluation data, using each weight parameter calculated by performing the FORCE relearning processing based on each learning parameter seq.

The period controller 2603 provides the setting instruction to the process state prediction system 128 to set the weight parameter that achieves that the prediction result data falls within the predetermined allowable range and that achieves the highest prediction accuracy. The predetermined allowable range may be set to a fixed value or may be set to a value calculated based on the batch learning prediction result calculated by the batch learner 2609.

After the period controller 2603 transmits the setting instruction of the weight parameter, the period controller 2603 transmits the instruction to transition to the prediction period to the process state prediction system 128.

The end information acquirer 2604 acquires various end information (the end information of the FORCE learning processing, the end information of acquisition of the relearning data, the end information of acquisition of the evaluation data, and the end information of the FORCE relearning processing) from the process state prediction system 128. The end information acquirer 2604 transmits the acquired various end information to the period controller 2603.

The relearning determiner 2605 determines whether relearning is necessary based on the prediction accuracy of the prediction result data received from the process state prediction system 128 during the prediction period. When the relearning determiner 2605 determines that relearning is necessary, the relearning determiner 2605 transmits a determination result indicating that relearning is necessary to the period controller 2603. In addition, when an event that needs relearning occurs, the relearning determiner 2605 transmits a determination result indicating that relearning is necessary to the period controller 2603.

The evaluator 2606 evaluates the prediction accuracy of the prediction result data received from the process state prediction system 128 each time the learning parameter set is switched during the relearning period, and transmits the evaluation result to the period controller 2603. As described above, in evaluating the prediction result data, the evaluator 2606 may evaluate the prediction result data, using the allowable range calculated based on the batch learning prediction result calculated by the batch learner 2609.

### <Process State Prediction Processing Performed by Manager and Process State Prediction System>

Next, a flow of process state prediction processing performed by the manager 124 and the process state prediction system 128 will be described.

### (1) Overall Flow of Process State Prediction Processing

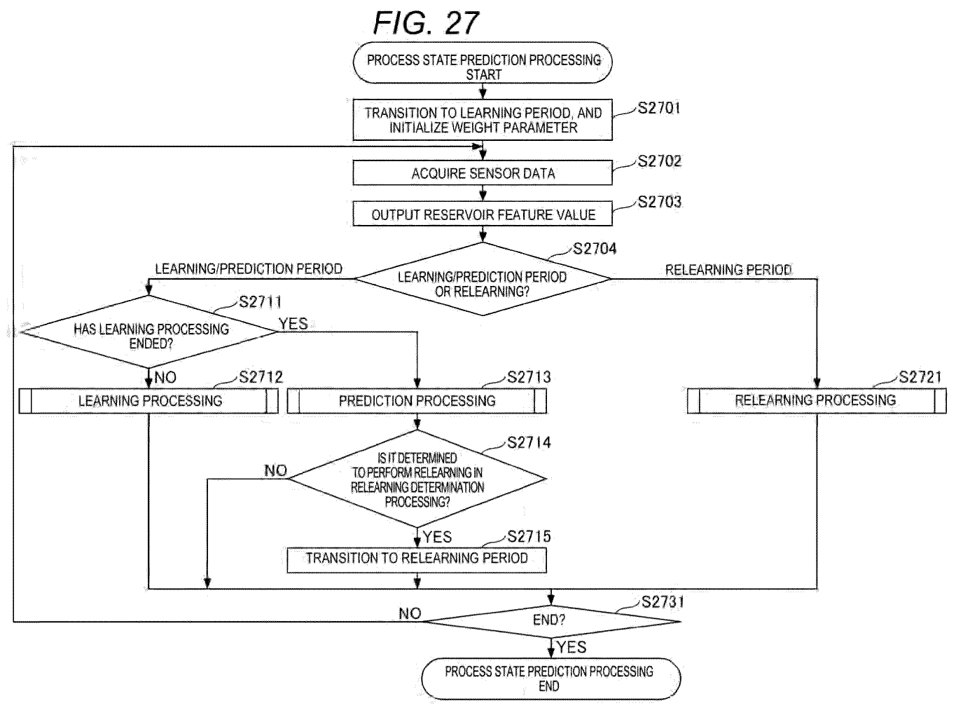

First, an overall flow of the process state prediction processing will be described. FIG. 27 is an example of a flowchart illustrating the overall flow of the process state prediction processing performed by the manager and the process state prediction system. The processing illustrated in FIG. 27 starts when the process state prediction system 128 starts up.

In step S2701, the manager 124 transmits the instruction to transition to the learning period to the process state prediction system 128. Accordingly, the process state predictor 204 of the process state prediction system 128 transitions to the learning period and initializes the weight parameter of the FORCE learner 1200.

In step S2702, the I/O controller 201 of the process state prediction system 128 acquires the time series sensor data a output by the sensor 122a.

In step S2703, the reservoir device 202 of the process state prediction system 128 receives input of the sensor data a′ output from the I/O controller 201 and outputs the reservoir feature value.

In step S2704, the process state predictor 204 of the process state prediction system 128 determines the current period. When the instruction to transition to the learning period or the instruction to transition to the prediction period is received from the manager 124 of the management device 123, the process state predictor 204 determines that the current period is the learning period or the prediction period in step S2704. In this case, the process state predictor 204 proceeds to step S2711.

In step S2711, the process state predictor 204 of the process state prediction system 128 determines whether the FORCE learning processing has ended. When a determination that the FORCE learning processing has not ended is made in step S2711 (NO in step S2711), the flow proceeds to step S2712.

In step S2712, the process state predictor 204 of the process state prediction system 128 performs the FORCE learning processing. Details of the FORCE learning processing (step S2712) will be described later.

Meanwhile, when a determination that the FORCE learning processing has ended is made in step S2711 (YES in step S2711), the flow proceeds to step S2713.

In step S2713, the process state predictor 204 of the process state prediction system 128 performs the prediction processing. Details of the prediction processing (step S2713) will be described later.

In step S2714, the manager 124 of the management device 123 determines whether relearning is necessary. When a determination that relearning is not necessary is made in step S2714 (NO in step S2714), the flow proceeds to step S2731.

Meanwhile, when a determination that relearning is necessary is made in step S2714 (YES in step S2714), the flow proceeds to step S2715. Details of relearning determination processing in step S2714 will be described later.

In step S2715, the manager 124 of the management device 123 transmits the instruction to transition to the relearning period and the learning parameter sets 1 to M to the process state prediction system 128. Accordingly, the process state predictor 204 of the process state prediction system 128 transitions to the relearning period and acquires the learning parameter sets 1 to M.

When a determination that the current period is the relearning period is made in step 32704, the flow proceeds to step S2721. When the instruction to transition to the relearning period is received from the manager 124 of the management device 123, the process state predictor 204 determines that the current period is the relearning period.

In step S2721, the process state predictor 204 of the process state prediction system 128 performs the FORCE relearning processing. Details of the FORCE relearning processing (step S2721) will be described later.

In step S2731, the manager 124 of the management device 123 determines whether to end the process state prediction processing. When it is determined not to end the process state prediction processing in step S2731 (NO in step S2731), the flow returns to step S2702.

Meanwhile, when it is determined to end the process state prediction processing in step S2731, the manager 124 of the management device 123 and the process state prediction system 128 ends the process state prediction processing.

### (2) Details of Learning Processing (Step S2712)

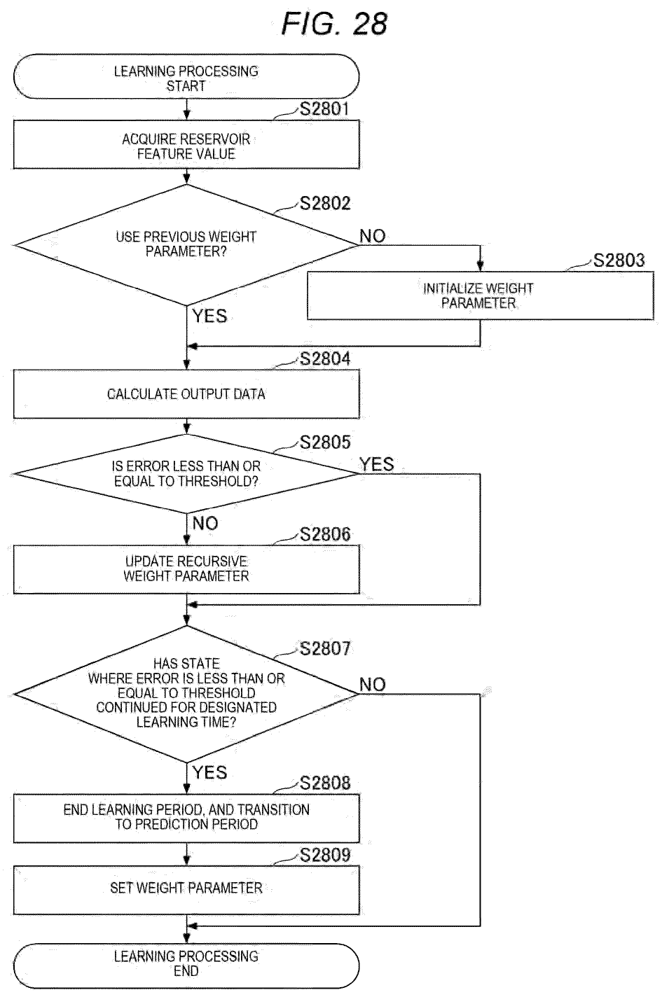

Next, details of the learning processing (step S2712) included in the process state prediction processing will be described. FIG. 28 is an example of a flowchart illustrating a flow of learning processing.

In step S2801, the process state predictor 204 of the process state prediction system 128 acquires the reservoir feature value output from the reservoir device 202 and the process state data (the ground truth data) transmitted from the manager 124 of the management device 123.

In step S2802, the process state predictor 204 of the process state prediction system 128 determines whether the item “use or initialize previous weight parameter” of the reference sign 2611 is “use” in the learning parameter set.

When a determination that the item “use or initialize previous weight parameter” is “use” is made in step S2602 (YES in step 32802), the flow proceeds to step S2804. In this case, the process state predictor 204 of the process state prediction system 128 uses the weight parameter calculated in the previous FORCE learning processing as an initial value of the recursive weight parameter of the FORCE learner 1200 in the current FORCE learning processing.

Meanwhile, when a determination that the Item “use or initialize previous weight parameter” is “initialize” is made in step S2802 (NO in step S2802), the flow proceeds to step S2803.

In step S2803, the process state predictor 204 of the process state prediction system 128 initializes the recursive weight parameter of the FORCE learner 1200 calculated in the previous FORCE learning processing before the current FORCE learning processing.

In step S2804, the FORCE learner 1200 calculates the output data by multiplying the reservoir feature value by the current recursive weight parameter.

In step S2805, the FORCE learner 1200 calculates the error between the calculated output data and the corresponding process state data (the ground truth data). When the FORCE learner 1200 determines that the calculated error is not less than or equal to the threshold (NO in step S2805), the FORCE learner 1200 proceeds to step S2806.

In step S2806, the FORCE learner 1200 updates the recursive weight parameter based on the calculated error and proceeds to step S2807.

Meanwhile, when a determination that the error is less than or equal to the threshold is made in step S2805 (YES in step S2805), the flow directly proceeds to step S2807.

In step S2807, the FORCE learner 1200 determines whether a state where the error is less than or equal to the threshold has continued for the predetermined learning time designated by the learning parameter set. When a determination that the state has not continued is made in step S2807 (NO in step S2807), the flow returns to step S2731 of FIG. 27.

Meanwhile, when a determination that the state has continued is made in step S2807 (YES in step S2807), the flow proceeds to step S2808.

In step S2808, the process state predictor 204 of the process state prediction system 128 transmits the end information of the FORCE learning processing to the management device 123. Accordingly, the manager 124 of the management device 123 determines that the FORCE learning processing has ended, and transmits the instruction to transition to the prediction period to the process state prediction system 128.

In step S2809, the process state predictor 204 of the process state prediction system 128 sets the weight parameter when the FORCE learning processing has ended in the FORCE learner 1300.

### (3) Details of Prediction Processing (Step S2713)

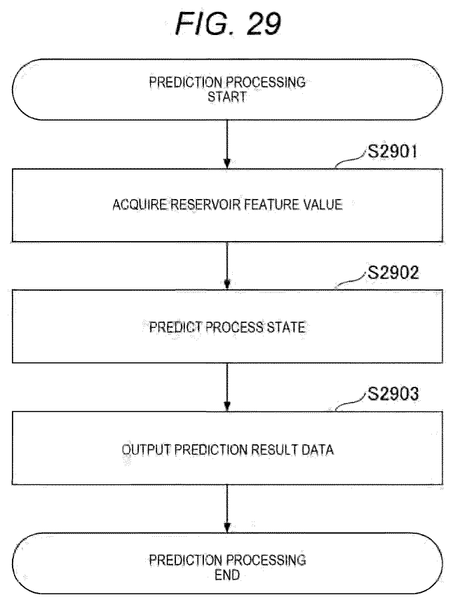

Next, details of the prediction processing (step S2713) included in the process state prediction processing will be described. FIG. 29 is an example of a flowchart illustrating a flow of the prediction processing.

In step S2901, the FORCE learner 1300 acquires the reservoir feature value output from the reservoir device 202.

In step S2902, the FORCE learner 1300 predicts the process state by multiplying the acquired reservoir feature value by the weight parameter.

In step S2903, the FORCE learner 1300 outputs the prediction result data.

### (4) Details of Relearning Determination Processing (Step S2714)

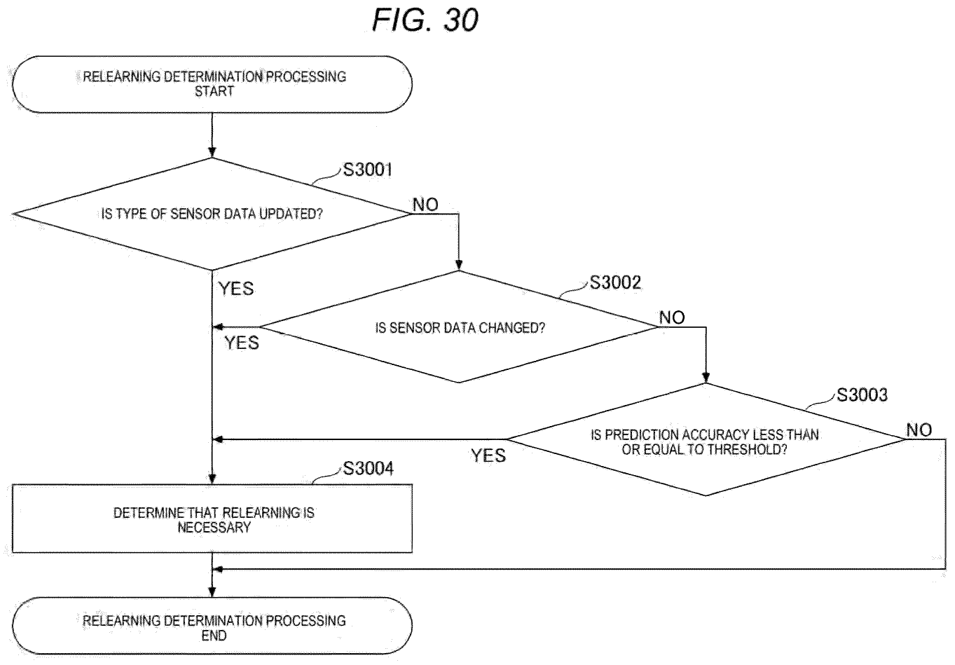

Next, details of the relearning determination processing (step S2714) performed by the manager 124 of the management device 123 will be described. FIG. 30 is an example of a flowchart illustrating a flow of the relearning determination processing.

In step S3001, the manager 124 of the management device 123 determines whether a type of the time series sensor data a acquired by the process state prediction system 128 is changed in the prediction period. When a determination that a change is made is made in step S3001 (YES in step S3001), the flow proceeds to step S3004.

Meanwhile, when a determination that a change is not made is made in step S3001 (NO in step S3001), the flow proceeds to step S3002.

In step S3002, the manager 124 of the management device 123 determines whether the value of the time series sensor data a acquired by the process state prediction system 128 has changed by a predetermined threshold or more in the prediction period. When a determination that the value of the time series sensor data a has changed by the predetermined threshold or more is made in step S3002 (YES in step S3002), the flow proceeds to step S3004.

Meanwhile, when a determination that the value of the time series sensor data a has not changed by the predetermined threshold or more is made in step S3002 (NO in step S3002), the flow proceeds to step S3003.

In step S3003, the manager 124 of the management device 123 determines whether the prediction accuracy of the prediction result data transmitted from the process state prediction system 128 is decreased to a predetermined threshold or lower in the prediction period.

When a determination that the prediction accuracy is decreased to the predetermined threshold or lower is made in step S3003 (YES in step S3003), the flow proceeds to step S3004.

In step S3004, the manager 124 of the management device 123 determines that relearning is necessary.

Meanwhile, when a determination that the prediction accuracy is not decreased to the predetermined threshold or lower is made in step S3003 (NO in step S3003), the flow returns to step S2731 of FIG. 27.

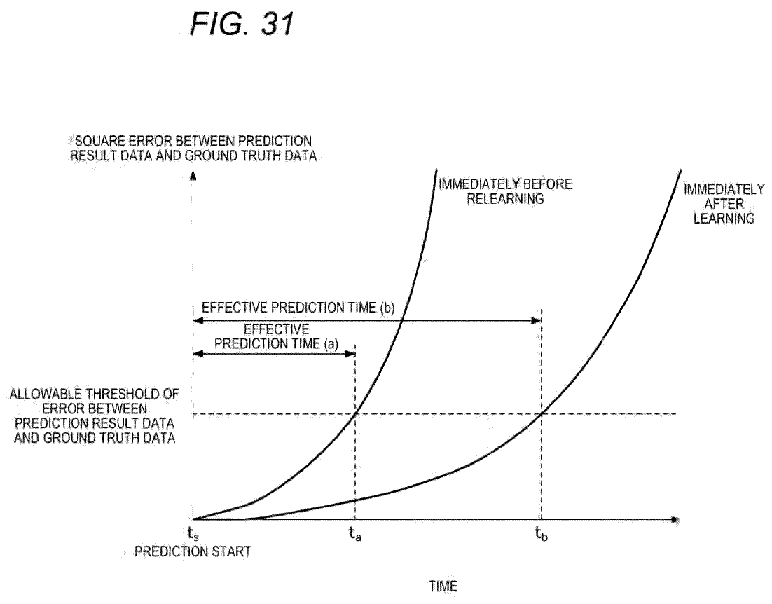

The fact that the prediction accuracy is decreased to the predetermined threshold or lower indicates that the error between the prediction result data and the ground truth data exceeds the allowable threshold (as described above, the time until this point is the “effective prediction time”). Accordingly, the manager 124 of the management device 123 determines whether relearning is necessary by monitoring the effective prediction time. Description will be provided with reference to FIG. 31.

FIG. 31 is a diagram illustrating another example of the effective prediction time. In FIG. 31, a horizontal axis denotes elapsed time from setting of the weight parameter calculated through learning. In FIG. 31, a vertical axis denotes the square error between the prediction result data and the ground truth data.

In the process state prediction system 128, for example, the effective prediction time until the square error between the prediction result data and the ground truth data exceeds the allowable threshold is a time indicated by t_{b} of FIG. 31 (an initial state or a best state). Operation starts from this point, and then the effective prediction time until the square error between the prediction result data and the ground truth data exceeds the allowable threshold reaches tₐ (<t_{b}). That is, relearning is performed when the time in which prediction can be originally performed is reduced (when t_{b}−tₐ reaches the predetermined threshold or higher).

### (5) Details of Relearning Processing (Step S2721)

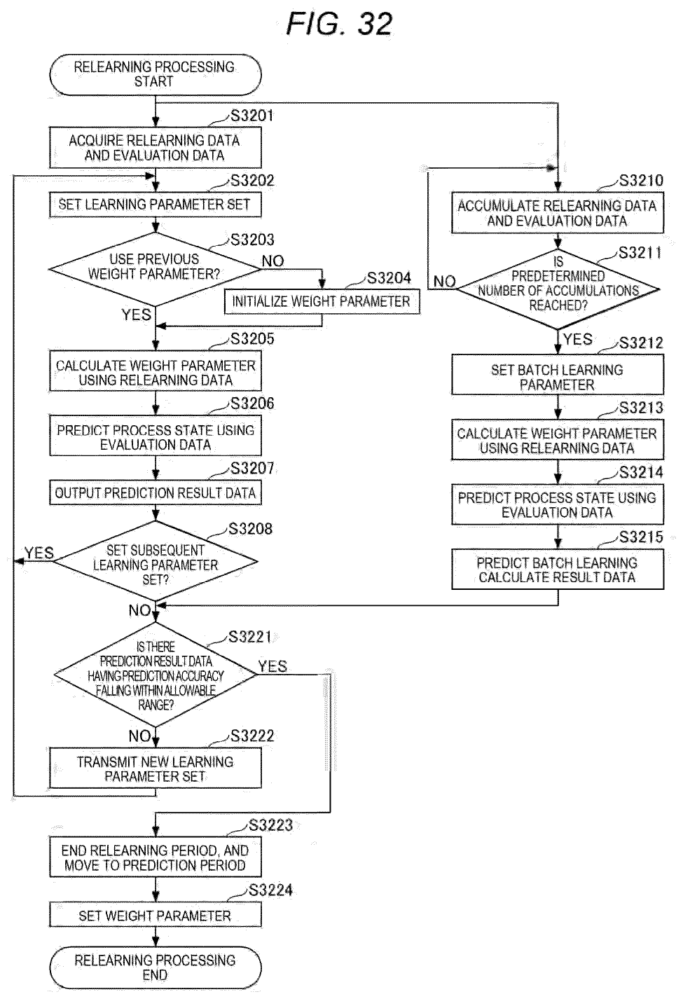

Next, details of the relearning processing (step S2721) included in the process state prediction processing will be described. FIG. 32 is an example of a flowchart illustrating a flow of the relearning processing.

When the relearning processing starts, the process state predictor 204 of the process state prediction system 128 and the manager 124 of the management device 123 parallelly execute processing of step S3201 to step S3208 and processing of step S3210 to step S3215.

First, the processing of step S3201 to step S3208 will be described. In step S3201, the process state predictor 204 of the process state prediction system 128 acquires the reservoir feature value output from the reservoir device 202 and the process state data (the ground truth data) transmitted from the manager 124 of the management device 123.

The process state predictor 204 of the process state prediction system 128 acquires a part of a combination of the reservoir feature value and the process state data (the ground truth data) as the relearning data and acquires the rest of the combination as the evaluation data.

In step S3202, the process state predictor 204 sets any (here, the learning parameter set 1) of the learning parameter sets 1 to M transmitted from the manager 124 of the management device 123 in the FORCE learner 1200_1.

In step S3203, the process state predictor 204 determines whether the item “use or initialize previous weight parameter” of the learning parameter set 1 set in the FORCE learner 1200_1 is “use”.

When a determination that the item “use or initialize previous weight parameter” is “use” is made in step S3203 (YES in step S3203), the flow proceeds to step S3205. In this case, the FORCE learner 1200_1 performs the current FORCE relearning processing using the weight parameter calculated in the previous FORCE learning processing as the initial value of the recursive weight parameter.

Meanwhile, when a determination that the item “use or initialize previous weight parameter” is “initialize” is made in step S3203 (NO in step S3203), the flow proceeds to step S3204.

In step S3204, the process state predictor 204 of the process state prediction system 128 initializes the recursive weight parameter of the FORCE learner 1200_1.

In step S3205, the FORCE learner 1200_1 calculates the weight parameter by performing the FORCE learning processing using the relearning data. The FORCE learner 1200_1 sets the calculated weight parameter in the FORCE learner 1300_1.

In step S3206, the FORCE learner 1300_1 predicts the process state using the evaluation data.

In step S3207, the FORCE learner 1300_1 outputs the prediction result data to the manager 124 of the management device 123.

In step S3208, the process state predictor 204 of the process state prediction system 128 determines whether all learning parameter sets transmitted from the manager 124 of the management device 123 are set in the FORCE learners.

When there is a learning parameter set not set in step S3208, it is determined to set the subsequent learning parameter set (YES in step S3208), and the flow returns to step S3202.

Meanwhile, when a determination that all learning parameter sets are set in the FORCE learners is made in step S3208, it is determined not to set the subsequent learning parameter (NO in step S3208), and the flow proceeds to step S3221.

Next, the processing of step S3210 to step S3215 will be described. In step S3210, the process state predictor 204 of the process state prediction system 128 outputs the acquired reservoir feature value to the manager 124 of the management device 123. The manager 124 of the management device 123 accumulates the part of the combination of the reservoir feature value output from the process state predictor 204 and the process state data (the ground truth data) as the relearning data and accumulates the rest of the combination as the evaluation data.

In step S3211, the process state predictor 204 of the process state prediction system 128 determines whether both of the accumulated relearning data and the accumulated evaluation data have reached a predetermined size.

When a determination that the predetermined size is not reached is made in step S3211 (NO in step S3211), the flow returns to step S3210.

Meanwhile, when a determination that the predetermined size is reached is made in step S3211 (YES in step S3211), the flow proceeds to step S3212.

In step S3212, the manager 124 of the management device 123 sets the batch learning parameter.

In step S3213, the manager 124 of the management device 123 calculates the weight parameter by performing the batch learning processing using the accumulated relearning data.

In step S3214, the manager 124 of the management device 123 predicts the process state using the accumulated evaluation data based on the calculated weight parameter.

In step S3215, the manager 124 of the management device 123 calculates batch learning prediction result data.

In step S3221, the manager 124 of the management device 123 determines whether there is prediction result data having the prediction accuracy falling within the predetermined allowable range in each prediction result data transmitted from the process state prediction system 128 for each learning parameter set. The manager 124 of the management device 123 calculates the predetermined allowable range based on the calculated batch learning prediction result data.

When a determination that there is no prediction result data falling within the predetermined allowable range is made in step S3221 (NO in step S3221), the flow proceeds to step S3222.

In step S3222, the manager 124 of the management device 123 generates a new learning parameter set, transmits the generated learning parameter set to the process state prediction system 128, and returns to step S3202.

Meanwhile, when a determination that there is prediction result data falling within the predetermined allowable range is made in step S3221 (YES in step S3221), the flow proceeds to step S3223.

In step S3223, the manager 124 of the management device 123 ends the relearning period and transmits the instruction to transition to the prediction period to the process state prediction system 128. The manager 124 of the management device 123 provides the setting instruction to the process state prediction system 128 to set the weight parameter that achieves that the prediction result data falls within the predetermined allowable range and that achieves the highest prediction accuracy.

In step S3224, the process state predictor 204 of the process state prediction system 128 transitions to the prediction period. The process state predictor 204 of the process state prediction system 128 sets the weight parameter that achieves that the prediction result data falls within the predetermined allowable range and that achieves the highest prediction accuracy, in the FORCE learner 1300_X. Accordingly, in the prediction period after relearning, the prediction result data can be calculated using the weight parameter obtained through relearning based on an appropriate learning parameter set.

### SUMMARY

As is clarified from the above description, the process state prediction system 128 according to the first embodiment predicts the process state by processing the time series sensor data through reservoir computing. At that time, in order to implement the reservoir device 202 using a digital circuit, the mathematical equation executed in the reservoir device 202 is changed. Accordingly, resources of the digital circuit are reduced, and a processing time of the digital circuit is shortened. In addition, the following is performed.
The input weight, the connection weight, and the feedback weight are generated using a periodic function circuit,
   Scaling is performed using a shifter.
   The reservoir feature value is calculated by configuring the activation function circuit using fixed-point or floating-point polynomial calculation.

Thus, according to the first embodiment, further reduction of resources and improvement in a processing speed in the reservoir device 202 can be implemented.

Consequently, the reservoir device 202 according to the first embodiment can output the reservoir feature value by detecting short behavior occurring in the sensor data and thus, can improve the prediction accuracy in predicting the process state based on the time series sensor data.

In the process state prediction system 128 according to the first embodiment, the process state predictor learns the weight parameter using the hardware performing the FORCE learning processing based on the recursive least squares.

Accordingly, the process state prediction system 128 according to the first embodiment can learn the weight parameter by detecting short behavior occurring in the sensor data.

Consequently, according to the first embodiment, the prediction accuracy in predicting the process state based on the time series sensor data can be improved.

In the process state prediction system 128 according to the first embodiment, the following is performed.
The weight parameter is relearned when a determination that relearning is necessary is made during the prediction period after learning.
In relearning the weight parameter, the learning parameter is optimized.

Accordingly, the process state prediction system 128 according to the first embodiment can suppress a decrease in the prediction accuracy caused by a change over time in the manufacturing process.

Consequently, according to the first embodiment, the prediction accuracy in predicting the process state based on the time series sensor data can be improved.

### Second Embodiment

The first embodiment describes implementation of the reservoir device 202 of the process state prediction system 128 using an adder, a multiplier, and the like. However, the reservoir device 202 may be configured to further reduce resources. For example, the reservoir device 202 may be implemented using a bit shifter instead of using a multiplier. Hereinafter, the second embodiment will be described with a focus on the differences from the first embodiment.

### <Configuration for Weighting>

In the first embodiment, each of
weighting of I(t), which is the value of the sensor data a′,
weighting of uⱼ(t), which is the reservoir node state, and
weighting of Z(t), which is the prediction result data
   is implemented by a configuration including a multiplier (the 2M-bit multipliers 313, 323, and 403). Meanwhile, in the second embodiment, weighting of I(t), which is the value of the sensor data a′, weighting of uⱼ(t), which is the reservoir node state, and weighting of Z(t), which is the prediction result data, are implemented using a “weight bit shift multiplier” not including a multiplier.

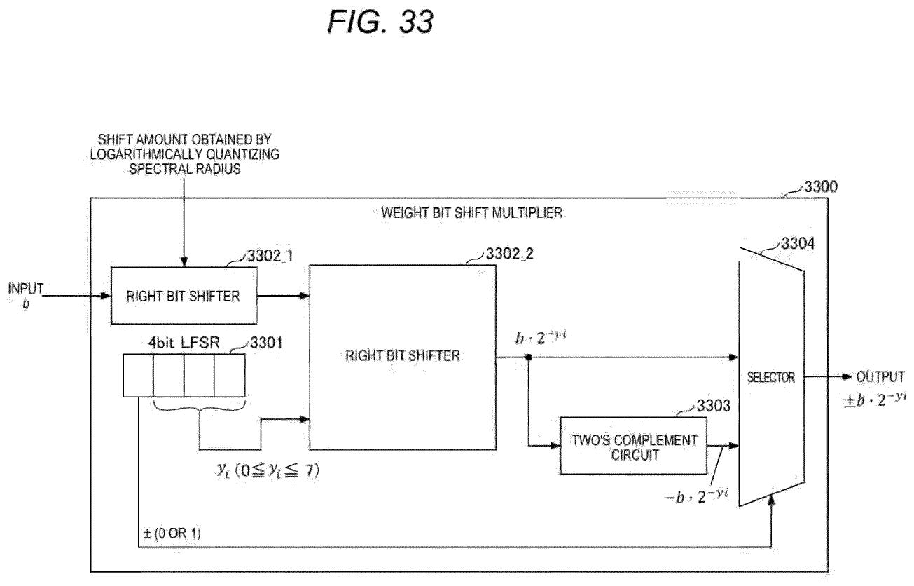

FIG. 33 is a first diagram illustrating an example of the weight bit shift multiplier in the second embodiment. As illustrated in FIG. 33, a weight bit shift multiplier 3300 includes a P-bit LFSR 3301 (P is an integer greater than or equal to two; in the example of FIG. 33, P=“4”), a right bit shifter 3302_1, a right bit shifter 3302_2, a two's complement circuit 3303, and a selector 3304.

In the P-bit LFSR 3301 (an example of the first to third periodic function circuits), a value of one bit at the head among P bits is input into a switching input of the selector 3304, and a value of the remaining (P−1) bits is input into a shift amount input of the right bit shifter 3302_2.

The right bit shifter 3302_1 shifts a value (b) input into the weight bit shift multiplier 3300 to the right by a value of an exponent obtained by logarithmically quantizing the spectral radius.

The right bit shifter 3302_2 shifts a result output from the right bit shifter 3302_1 to the right by a shift amount corresponding to a value (yᵢ) of the (P−1) bits output from the P-bit LFSR 3301. The right bit shifter 3302_2 inputs a value after shift (a power of two; b·2^{-yi}) into the two's complement circuit 3303 and the selector 3304. When P is “4”, the selector 3304 randomly selects 16 weights. For example, the 16 weights refer to “0, −2⁻⁶, −2⁻⁶, −2⁻⁵, −2⁻⁴, −2⁻³, −2⁻², −2⁻¹, −2⁻¹, 2⁻², 2⁻³, 2⁻⁴, 2⁻⁵, 2⁻⁶, 2⁻⁶, and 0”. In the reservoir device 202 according to the present embodiment, it is clarified through simulation that handling the weights between “−2⁻⁶” and “−2⁻⁶” as “0” does not make a change in performance. Therefore, hereinafter, the P-bit LFSR 3301 will be described as a 4-bit LFSR.

The two's complement circuit 3303 outputs a value (a negative value; −b·2^{-yi}) obtained by inverting a sign of the value after shift shifted by the right bit shifter 3302.

The selector 3304 selects any of the value after shift shifted by the right bit shifter 23302 or its negative value in accordance with the switching input from the 4-bit LFSR 3301. The selector 3304 outputs the selected value as an output value (±b·2^{-yi}) of the weight bit shift multiplier 3300.

The weight bit shift multiplier 3300 performs weighting using any of the power of two or its negative value corresponding to the value output from the 4-bit LFSR 3301 as a weight.

### <Configuration of Each Weight Bit Shift Multiplier>

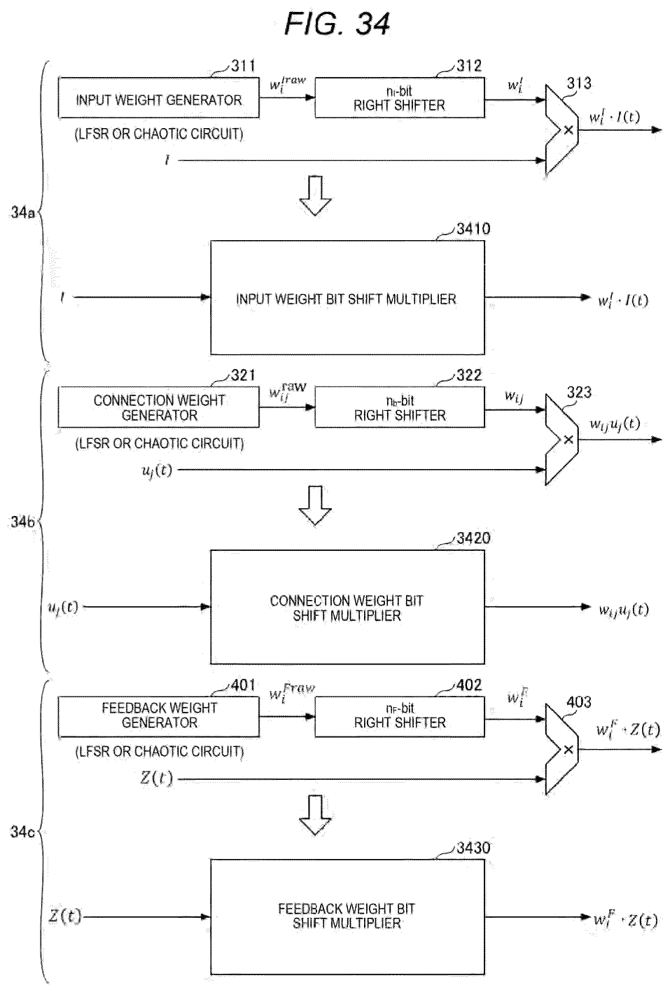

Next, a configuration of each weight bit shift multiplier performing weighting of I(t), which is the value of the sensor data a′, weighting of uⱼ(t), which is the reservoir node state, and weighting of Z(t), which is the prediction result data, in the reservoir device in the second embodiment will be described. FIG. 34 is a diagram illustrating a configuration example of each weight bit shift multiplier.

34a of FIG. 34 illustrates a configuration example for weighting I(t), which is the value of the sensor data a′. In 34a, an upper part illustrates a configuration example that is described using FIG. 3 or FIG. 4 in the first embodiment and that is configured using the input weight generator 311, the nI-bit right shifter 312, and the 2M-bit multiplier. In 34a, a lower part illustrates a configuration example configured using the weight bit shift multiplier described above.

As illustrated in 34a, according to the second embodiment, an input weight bit shift multiplier 3410 of which the output (wᵢⁱ)·(I(t)) when the input (the value of the sensor data a′) is I(t) is (±2^{-yi})·(I(t)) can be implemented. That is, according to the second embodiment, weighting of I(t), which is the value of the sensor data a′, can be implemented without using a multiplier.

34b of FIG. 34 is a configuration example for weighting uⱼ(t), which is the reservoir node state. In 34b, an upper part illustrates a configuration example that is described using FIG. 3 or FIG. 4 in the first embodiment and that is configured using the connection weight generator 321, the nb-bit right shifter 322, and the 2M-bit multiplier 323. In 34b, a lower part illustrates a configuration example configured using the weight bit shift multiplier described above.

As illustrated in 34b, according to the second embodiment, a connection weight bit shift multiplier 3420 of which (wᵢⱼ)×(uⱼ(t)) when the input (the reservoir node state) is uⱼ(t) is (±2^{-yi})×(uⱼ(t)) can be implemented. That is, according to the second embodiment, weighting of uⱼ(t), which is the reservoir node state, can be implemented without using a multiplier.

34c of FIG. 34 illustrates a configuration example for weighting Z(t), which is the prediction result data. In 34c, an upper part illustrates a configuration example that is described using FIG. 3 or FIG. 4 in the first embodiment and that is configured using the feedback weight generator 401, the nF-bit right shifter 402, and the 2M-bit multiplier 403. In 34c, a lower part illustrates a configuration example configured using the weight bit shift multiplier described above.

As illustrated in 34c, according to the second embodiment, a feedback weight bit shift multiplier 3430 of which (wᵢ^{F})·(Z(t)) when the input (the prediction result data) is Z(t) is (±2^{-yi})·(Z(t)) can be implemented. That is, according to the second embodiment, weighting of Z(t), which is the prediction result data, can be implemented without using a multiplier.

### SUMMARY

As is clarified from the above description, in the reservoir device according to the second embodiment, weighting of the value of the sensor data a′, the reservoir node state, and the prediction result data is implemented without using a multiplier. Thus, according to the second embodiment, resources can be reduced.

### Third Embodiment

The first embodiment is configured such that the output wᵢⱼ^{raw} of the connection weight generator 321 is scaled (specifically, multiplied by 1/spectral radius rₛₚ) and input into the 2M-bit multiplier 323 as the connection weight wᵢⱼ to satisfy the necessary condition of the ESP. The 2M-bit multiplier 323 is configured to multiply wᵢⱼ^{raw} after scaling (that is, wᵢⱼ) by uⱼ(t), which is the j-th reservoir node state calculated one timing ago. That is, in the first embodiment, (wᵢⱼ)×(uⱼ(t)), which is the output of the 2M-bit multiplier 323, can be represented by Equation 10.

$$\begin{matrix}[ Equation 10 ] & \\ ( \text{?} {w}_{ij}^{raw} ) {u}_{j} ( t ) & ( 10 )\end{matrix}$$

$$\text{?} \text{indicates text missing or illegible when filed}$$

Meanwhile, when processing of multiplication by 1/spectral radius rₛₚ is performed for uⱼ(t), which is the j-th reservoir node state calculated one timing ago, the same output of the 2M-bit multiplier 323 is obtained. That is, the output of the 2M-bit multiplier 323 may be calculated in a calculation order indicated in Equation 11.

$$\begin{matrix}[ Equation 11 ] & \\ {w}_{ij}^{raw} \{ ( \frac{1}{\text{?}} ) {u}_{j} ( t ) \} & ( 11 )\end{matrix}$$

$$\text{?} \text{indicates text missing or illegible when filed}$$

In other words, in the first embodiment, the nb-bit right shifter 322 for implementing the processing of multiplication by 1/spectral radius re is configured to be disposed between the connection weight generator 321 and the 2M-bit multiplier 323.

However, the reservoir device 202 is not limited to the above configuration. For example, the nb-bit right shifter 322 may be configured to be disposed between the second memory 334 and the 2M-bit multiplier 323.

The processing of multiplication by 1/spectral radius rₛₚ is not limited to the processing implemented by the nb-bit right shifter 322 and may be implemented by, for example, a fixed-point or floating-point multiplier.

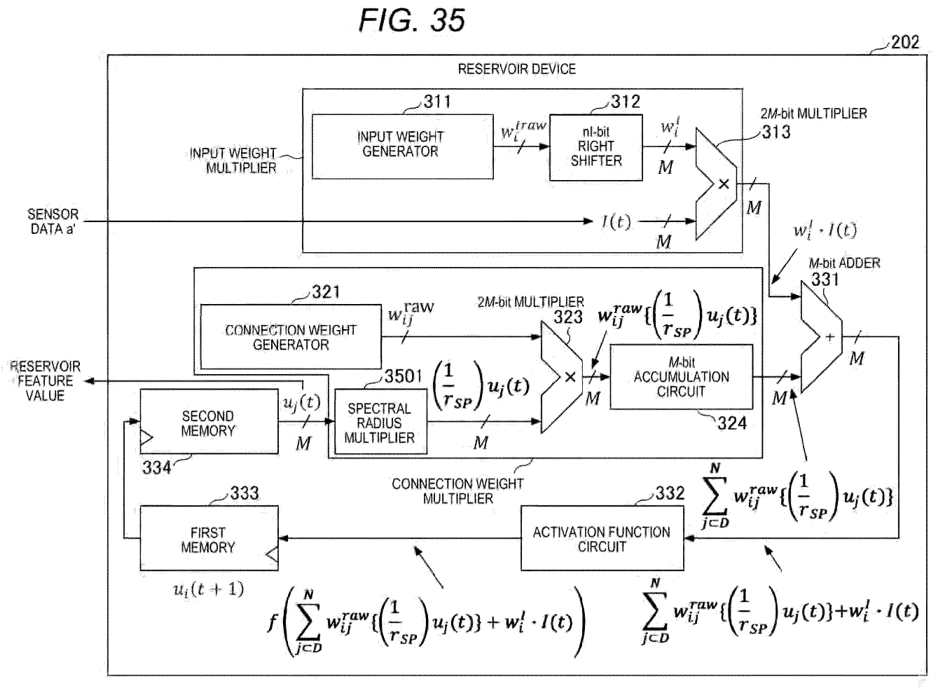

FIG. 35 is a third diagram illustrating an example of the hardware configuration of the reservoir device. Differences from the hardware configuration described using FIG. 3 in the first embodiment include
the nb-bit right shifter 322 is removed, and the output wᵢⱼ^{raw} of the connection weight generator 321 is directly input into the 2M-bit multiplier 323,
a spectral radius multiplier 3501 is added between the second memory 334 and the 2M-bit multiplier 323, and an output (1/spectral radius rₛₚ)uⱼ(t) of the spectral radius multiplier 3501 is input into the 2M-bit multiplier 323, and
wᵢⱼ^{raw}{(1/spectral radius rₛₚ)uⱼ(t)} is output from the 2M-bit multiplier 323.

The spectral radius multiplier 3501 multiplies uⱼ(t), which is the reservoir node state, by a spectral radius calculated in advance or a value obtained by logarithmically quantizing the spectral radius. Accordingly, the spectral radius multiplier 3501 may be implemented by the same configuration as the nb-bit right shifter 322 or may be implemented by the same configuration as the fixed-point or floating-point multiplier.

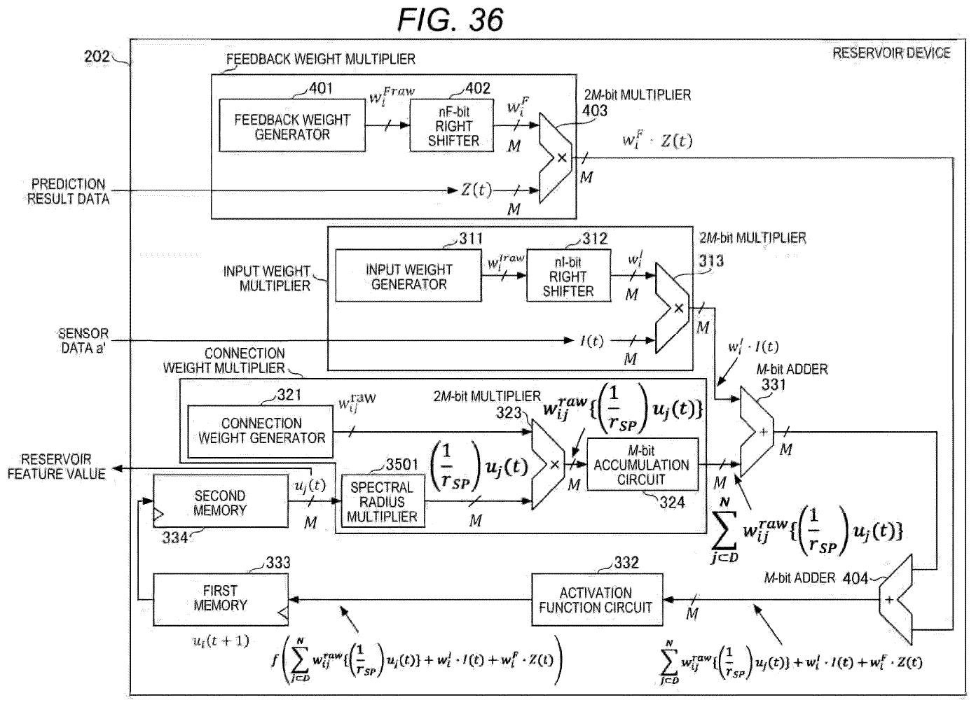

FIG. 36 is a fourth diagram illustrating an example of the hardware configuration of the reservoir device. Differences from the hardware configuration described using FIG. 4 in the first embodiment are the same as the differences between FIG. 3 and FIG. 35 and thus, will not be described here.

According to the third embodiment, the reservoir device 202 can be implemented by a different hardware configuration from the first embodiment.

### Fourth Embodiment

The first embodiment is configured such that the number of reservoir nodes is denoted by N and the M-bit accumulation circuit 324 adds the output (wᵢⱼ)×(uⱼ(t)) of the 2M-bit multiplier 323 for as many as the number of reservoir nodes and outputs the addition result.

Meanwhile, according to such a configuration, a processing time is increased when the number (N) of reservoir nodes is large. Therefore, in the fourth embodiment, in reading the j-th reservoir node state uⱼ(t) (j=1, 2, . . . N) calculated one timing ago from the second memory 334, the number of reservoir node states uⱼ(t) to be read is reduced by restricting the number of addresses to be read. The number of addresses to be read is a number corresponding to the performance (the processing speed and the prediction accuracy) of the reservoir device 202. Accordingly, a processing time of multiplication processing in the 2M-bit multiplier 323 and a processing time of addition processing in the M-bit accumulation circuit 324 can be shortened.

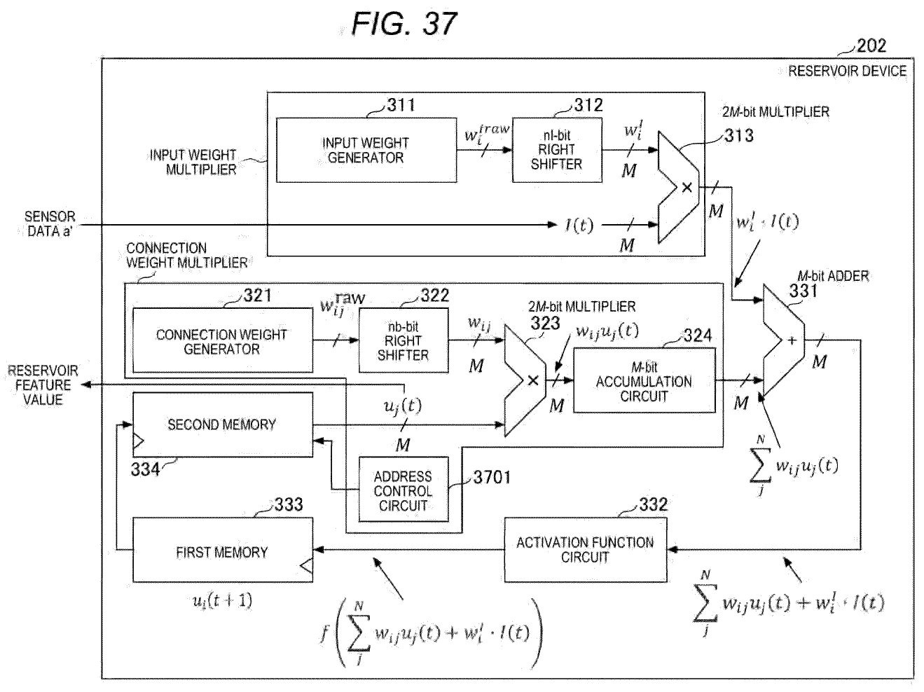

FIG. 37 is a fifth diagram illustrating an example of the hardware configuration of the reservoir device. A difference from the hardware configuration described using FIG. 3 in the first embodiment is addition of an address control circuit 3701.

In reading the j-th reservoir node state uⱼ(t) (j=1, 2, . . . N) calculated one timing ago from the second memory 334, the address control circuit 3701 reduces the number of reservoir node states uⱼ(t) to be read by restricting the number of addresses to be read.

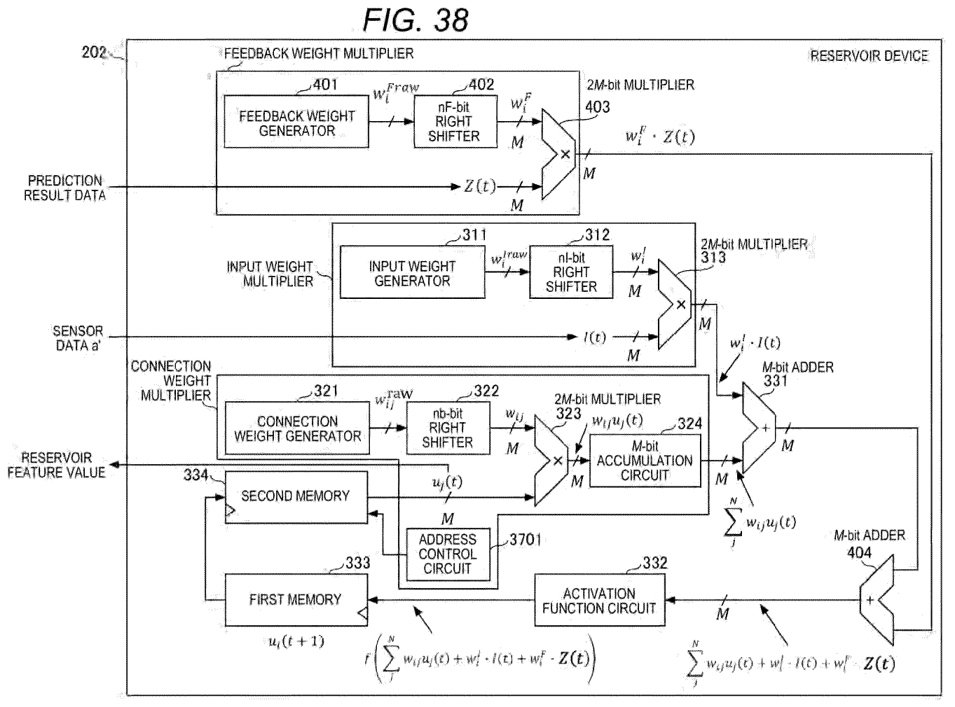

FIG. 38 is a sixth diagram illustrating an example of the hardware configuration of the reservoir device. A difference from the hardware configuration described using FIG. 4 in the first embodiment is addition of the address control circuit 3701.

According to the fourth embodiment, the reservoir device 202 having a shortened processing time can be implemented by the hardware configuration that reduces the number of reservoir node states uⱼ(t) to be read.

### Fifth Embodiment

The first embodiment illustrates the detailed configuration illustrated in FIG. 9 as the activation function circuit 332. However, the activation function circuit 332 is not limited to the configuration and may be implemented by, for example, a piecewise linear function. The limiter circuit 907 described using FIG. 10 in the first embodiment can also be used as an example of a circuit implementing the piecewise linear function.

Alternatively, for example, the activation function circuit 332 may be implemented by a lookup table. Specifically, the lookup table is implemented by providing a memory storing the corresponding i-th reservoir node state uⱼ(t+1) at an address corresponding to the calculation result of Equation (5) or (6) in the first embodiment.

According to the fifth embodiment, the reservoir device 202 can be implemented by a different hardware configuration from the first embodiment.

### Sixth Embodiment

The first to fifth embodiments describe the reservoir device 202 of low power and fewer resources as a digital circuit implementing the function corresponding to the nanomolecular reservoir (processing for outputting the reservoir feature value). Meanwhile, the sixth embodiment describes a reservoir device configured to implement a high-speed function corresponding to the nanomolecular reservoir (processing for outputting the reservoir feature value). Specifically, the sixth embodiment describes a reservoir device that is increased in speed by a configuration of parallelizing processing and reducing the number of operations.

### <Reduction of Number of Operations in Weighted Addition Using Connection Weight in Reservoir Device>

As described in the first embodiment, the reservoir device 202 performs weighted addition for the reservoir node state uⱼ(t) (j=1, 2, . . . N) calculated one timing ago using the connection weight. The weighted addition using the connection weight needs operations for as many as the number (N) of reservoir nodes. Specifically, when the number (N) of reservoir nodes is 100, 100×100 times of multiplication processing (that is, a matrix operation of 100 rows and 100 columns) are necessary.

Meanwhile, in the reservoir device 202, it is known that operation accuracy may be maintained even with a sparse matrix. Therefore, in the sixth embodiment, the number of operations is reduced by
forming the connection weight wᵢⱼ to be a sparse matrix, and
not executing multiplication processing between an element of the connection weight wᵢⱼ of zero and an element of the reservoir node state uⱼ(t). In the present embodiment, such an operation architecture will be referred to as a “variable vector length dot product operation architecture”.

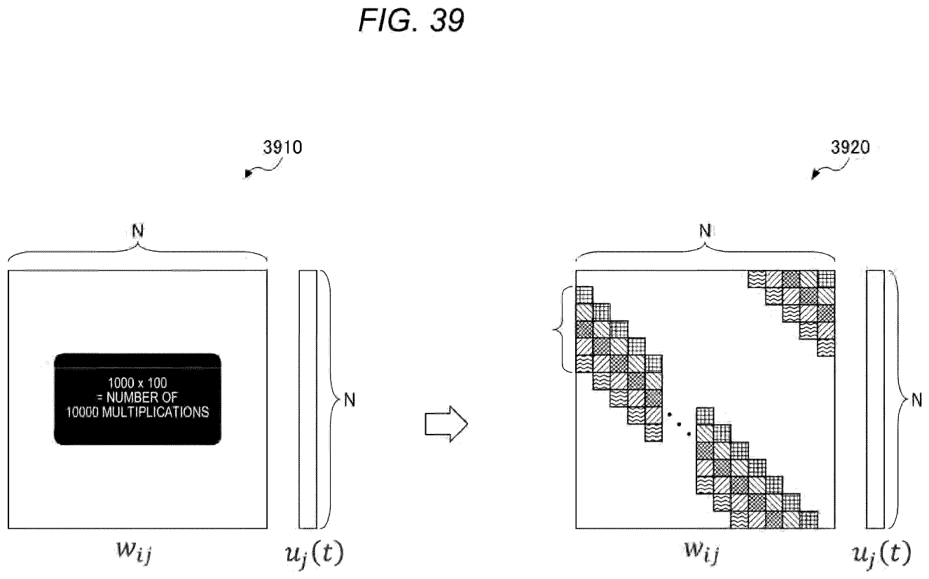

FIG. 39 is a diagram illustrating an example of reducing the number of operations in the reservoir device. In FIG. 39, the reference sign 3910 indicates 100×100 times of multiplication processing executed in performing the weighted addition using the connection weight wᵢⱼ when the number (N) of reservoir nodes is 100.

Meanwhile, in FIG. 39, the reference sign 3920 indicates the variable vector length dot product operation architecture in the sixth embodiment. In the reference sign 3920, an element with hatching is an element having a non-zero value of the connection weight wᵢⱼ, and an element without hatching (a white element) is the element of the connection weight wᵢⱼ of zero.

As indicated by the reference sign 3920, in the variable vector length dot product operation architecture in the sixth embodiment, a distribution of the element of zero (a sparse distribution) is provided with regularity by regularly arranging the element of the connection weight wᵢⱼ of zero. By regularly arranging the element of zero to obtain a distribution having regularity, the reservoir device 202 can recognize the element of zero in advance without reading the connection weight wᵢⱼ. Thus, not only does the reservoir device 202 not need to execute multiplication processing between the element of the connection weight wᵢⱼ of zero and the element of the reservoir node state uⱼ(t) but also does not need to execute reading processing for the element of the corresponding reservoir node state uⱼ(t). Thus, according to the variable vector length dot product operation architecture in the sixth embodiment, a speed of the weighted addition using the connection weight can be increased.

In the reference sign 3920, the number of CUs represents the number of connections per reservoir node. Hereinafter, the number of CUs will be denoted by “N_{CU}”. The example of the reference sign 3920 indicates N_{CU}=5.

### <Specific Example of Processing Based on Variable Vector Length Dot Product Operation Architecture>

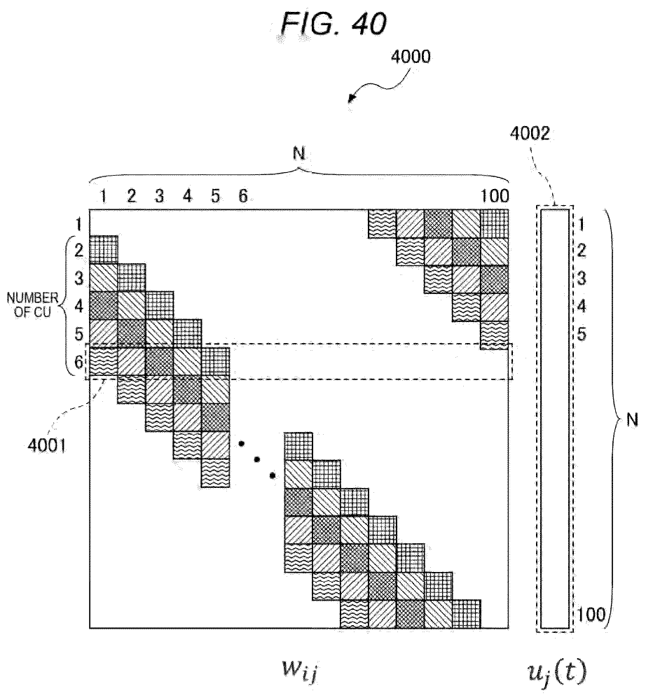

Next, a specific example of processing based on the variable vector length dot product operation architecture in the sixth embodiment will be described. FIG. 40 is a diagram illustrating the specific example of processing based on the variable vector length dot product operation architecture in the reservoir device. The weighted addition for the reservoir node state uⱼ(t) (the reference sign 4002) using the connection weight wᵢⱼ of the sixth row (the reference sign 4001) will be described with reference to FIG. 40.

In the connection weight of the sixth row (the reference sign 4001),
the connection weight of the first column will be denoted by w_{_(6,1)} below,
the connection weight of the second column will be denoted by w_{_(6,2)} below,
the connection weight of the third column will be denoted by w_{_(6,3)} below,
the connection weight of the fourth column will be denoted by w_{_(6,4)} below,
the connection weight of the fifth column will be denoted by w_{_(6,6)} below,
   . . .
the connection weight of the hundredth column will be denoted by w_{_(6,100)}.

As indicated by the reference sign 4001, the element of zero is distributed from the connection weight of the sixth column (w_{_(6,6)}) to the connection weight of the hundredth column (w_{_(6,100)}). Thus, the corresponding reservoir node state uⱼ(t) is not read in the weighted addition. Accordingly, in the weighted addition using the connection weight wᵢⱼ of the sixth row (the reference sign 4001), the first row to the fifth row are read as the corresponding reservoir node state uⱼ(t). Hereinafter, in the reservoir node state uⱼ(t) (the reference sign 4002),
the reservoir node state of the first row will be denoted by u₁(t),
the reservoir node state of the second row will be denoted by u₂(t),
the reservoir node state of the third row will be denoted by u₃(t),
the reservoir node state of the fourth row will, be denoted by u₄(t),
the reservoir node state of the fifth row will be denoted by u₅(t),
   . . .
the reservoir node state of the hundredth row will be denoted by u₁₀₀(t).

According to the above denotation, the weighted addition for the reservoir node state uⱼ(t) (the reference sign 4002) using the connection weight wᵢⱼ of the sixth row (the reference sign 4001) can be represented by Equation 12.

$$\begin{matrix}[ Equation 12 ] & \\ \text{?} {u}_{j} ( t ) = \text{?} \times \text{?} ( t ) + \text{?} \times {u}_{2} ( t ) + \text{?} \times {u}_{3} ( \text{?} ) + \text{?} \times {u}_{4} ( t ) + \text{?} \times {u}_{5} ( t ) & ( 12 )\end{matrix}$$

$$\text{?} \text{indicates text missing or illegible when filed}$$

The above example describes the connection weight of the sixth row (the reference sign 4001). However, according to the variable vector length dot product operation architecture of the sixth embodiment, the same processing is performed for the connection weights of other rows. Consequently, according to the reservoir device 202 in the sixth embodiment, the number of operations of the multiplication processing executed in performing the weighted addition using the connection weight can be reduced from N×N to N×N_{cu}.

### <Parallelization Method and Timing Chart of Multiplication Processing in Reservoir Device>

Next, a parallelization method of parallelly performing the multiplication processing executed in the variable vector length dot product operation architecture will be described.

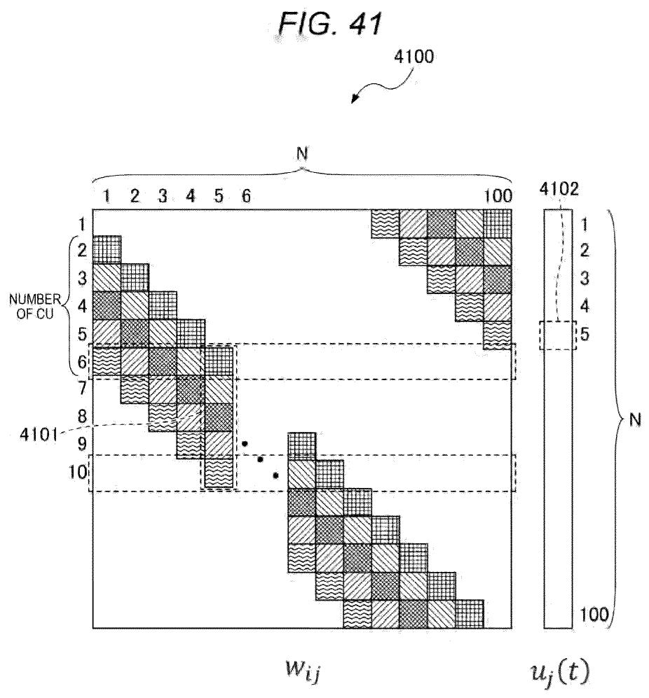

FIG. 41 is a diagram illustrating an overview of the parallel processing in the reservoir device. The parallelization method in the multiplication processing between
the connection weights w_{_(6,1)} to w_{_(6,100)} of the sixth row to the connection weights w_{_(10,1)} to w_{_(10,100)} of the tenth row, and
the reservoir node state u₆(t) of the sixth row to the reservoir node state u₁₀(t) of the tenth row will be described.

In the multiplication processing executed in the variable vector length dot product operation architecture indicated by the reference sign 4100, the multiplication processing indicated by the reference sign 4101 includes each of
w_{_(6,5)}×u₅,
w_{_(7,5)}×u₅,
w_{_(8,5)}×u₅,
w_{_(9,5)}×u₅, and
w_{_(10,5)}×u₅. That is, while the connection weights are different from each other, u₅ is used in common for the reservoir node state (the reference sign 4102).

Thus, when the multiplication processing indicated by the reference sign 4101 is executed at the same timing, a reservoir node state u_{_(5,1)} may be read once. Therefore, in the sixth embodiment, efficient parallel processing is implemented by providing five multipliers to execute the multiplication processing indicated by the reference sign 4101 at the same timing.

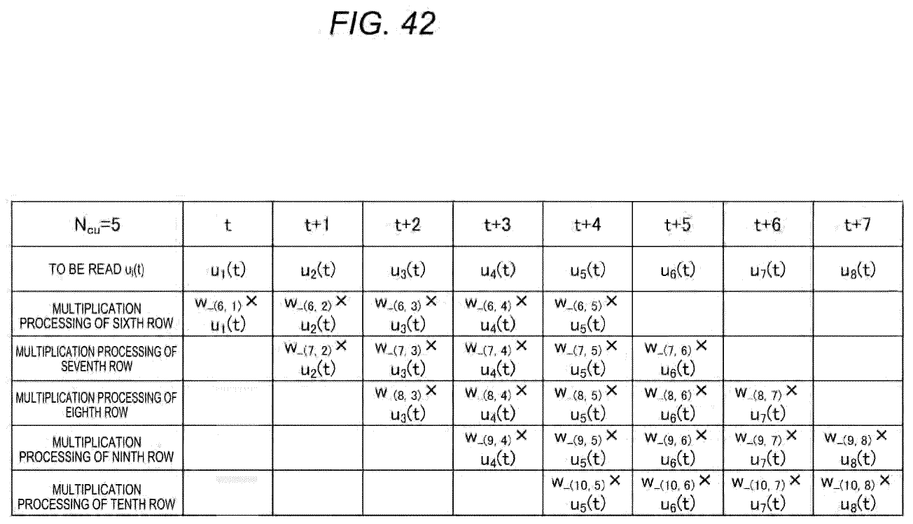

In implementing the parallel processing for reducing the number of reads of the reservoir node state uⱼ(t), a timing chart of each multiplication processing is illustrated in FIG. 42. FIG. 42 illustrates an example of the timing chart of the multiplication processing in the reservoir device. As illustrated in FIG. 42, with N_{cu}=5, for example, five types of multiplication processing can be performed using the reservoir node state u_{_(5,1)}, read at timing t+4 at the same time by causing the five multipliers to perform the parallel processing.

### <Hardware Configuration of Parallelized Reservoir Device>

Next, a hardware configuration of the parallelized reservoir device 202 will be described. As described above, efficient parallel processing can be implemented for the multiplication processing in the weighted addition using the connection weight, by providing multipliers for as many as the number corresponding to a value of N_{cu}. Thus, in the sixth embodiment, the reservoir device 202 is formed using
multipliers corresponding in number to the value of N_{cu} for performing the weighted addition using the connection weight,
one input core for performing weighting using the input weight,
one feedback core for performing weighting using the feedback weight, and
one activation core for calculating the activation function
   (to be described in detail later).

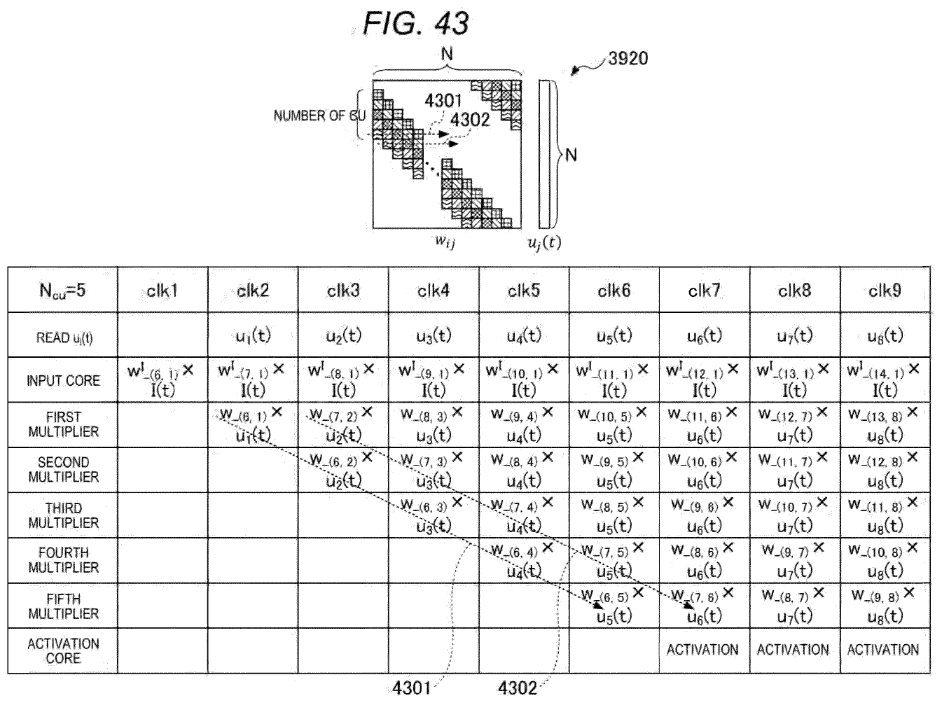

Each unit of the reservoir device 202 executes processing in accordance with the timing chart illustrated in FIG. 43. FIG. 43 is an example of the timing chart of processing of each unit of the reservoir device and illustrates a timing chart of processing of each unit (one input core, five multipliers, and one activation core) of the reservoir device 202 with N_{CU}=5.

In a timing chart 4300 of FIG. 43, a horizontal axis denotes an execution timing of each unit, and each region denotes a length of one clock (clk). In the timing chart 4300 of FIG. 43, a vertical axis denotes each unit (in the example of FIG. 43, an input core, first to fifth multipliers, and an activation core).

According to the timing chart 4300, the reservoir node state u₅ read at an execution timing of clk6 is parallelly processed by the first to fifth multipliers. The reservoir node state u: read at an execution timing of clk7 is parallelly processed by the first to fifth multipliers.

In FIG. 43, multiplication processing of dotted line arrow 4301 of the reference sign 3920 corresponds to multiplication processing of dotted line arrow 4301 in the timing chart 4300. Multiplication processing of dotted line arrow 4302 of the reference sign 3920 corresponds to multiplication processing of dotted line arrow 4302 in the timing chart 4300.

In the example of dotted Line arrow 4301 in the timing chart 4300, weighting is performed by the input core performing the multiplication processing at clk1 using the input weight. In the example of dotted line arrow 4301 in the timing chart 4300, the weighted addition is performed by adding multiplication results while the first to fifth multipliers perform the multiplication processing at clk2 to clk6 using the connection weights w_{_(6,1)} to w_{_(6,5)}, respectively. In the example of dotted line arrow 4301 in the timing chart 4300, the activation core calculates the activation function at clk7.

That is, the reservoir device 202 with N_{cu}=5 can output one i-th reservoir feature value (i is any of 1 to N) in a time length of 7 clocks (clk).

(1) Details of Parallelized Reservoir Device (without Feedback)

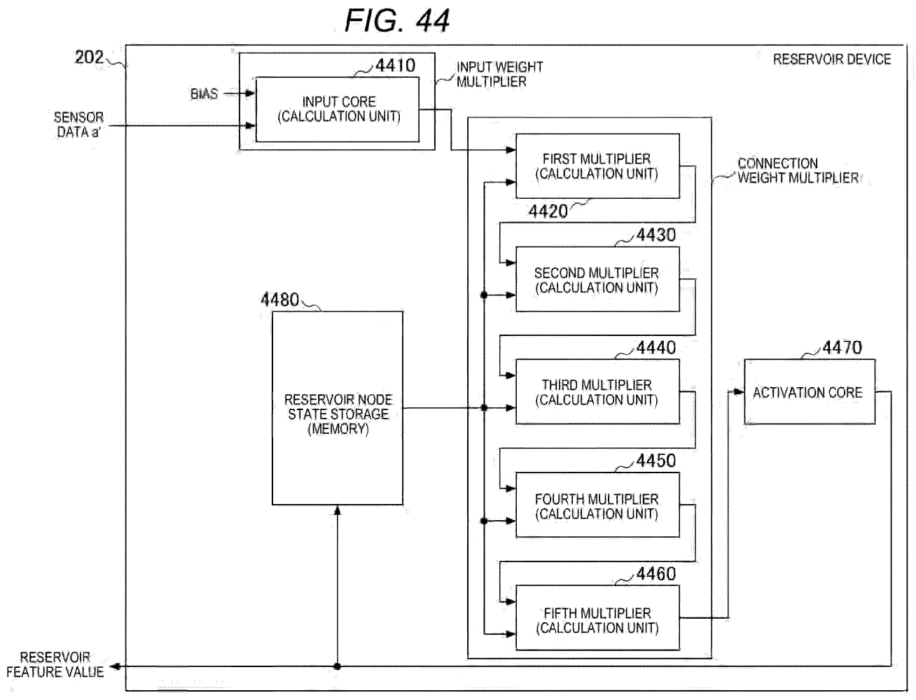

Next, details of a hardware configuration of the parallelized reservoir device 202 (here, without feedback) will be described. FIG. 44 is a seventh diagram illustrating an example of the hardware configuration of the reservoir device and illustrates art example of the hardware configuration of the reservoir device with N_{CU}=5.

As illustrated in FIG. 44, the parallelized reservoir device 202 (without feedback) includes
an input core 4410 (another example of the input weight multiplier),
a first multiplier 4420 to a fifth multiplier 4460 (another example of the connection weight multiplier),
an activation core 4470, and
a reservoir node state storage 4480.

As illustrated in FIG. 44, in the parallelized reservoir device 202 (without feedback), the input core 4410, the first multiplier 4420 to the fifth multiplier 4460, and the activation core 4470 are connected in series with each other.

Specifically, when the input core 4410 receives input of I(t), which is the value of the sensor data a′, and Bias that is a value of a predetermined bias, the input core 4410 outputs an input weighting result ((wᵢ^{I})·(I(t)+Bias)) obtained by weighting I(t) using the input weight.

The input weighting result output by the input core 4410 is input into the first multiplier 4420 together with the reservoir node state uⱼ(t) read from the reservoir node state storage 4480. Accordingly, the first multiplier 4420 outputs an addition result of a first multiplication result obtained by weighting the reservoir node state uⱼ(t) using the connection weight and the input weighting result.

The addition result of the first multiplication result and the input weighting result output by the first multiplier 4420 is input into the second multiplier 4430 together with the reservoir node state uⱼ(t) read from the reservoir node state storage 4480. Accordingly, the second multiplier 4430 outputs an addition result of a second multiplication result obtained by weighting the reservoir node state uⱼ(t) using the connection weight, the input weighting result, and the first multiplication result.

The addition result of the second multiplication result, the input weighting result, and the first multiplication result output by the second multiplier 4430 is input into the third multiplier 4440 together with the reservoir node state uⱼ(t) read from the reservoir node state storage 4480. Accordingly, the third multiplier 4440 outputs an addition result of a third multiplication result obtained by weighting the reservoir node state uⱼ(t) using the connection weight, the input weighting result, and the first and second multiplication results.

The addition result of the third multiplication result, the input weighting result, and the first and second multiplication results output by the third multiplier 4440 is input into the fourth multiplier 4450 together with the reservoir node state uⱼ(t) read from the reservoir node state storage 4480. Accordingly, the fourth multiplier 4450 outputs an addition result of a fourth multiplication result obtained by weighting the reservoir node state uⱼ(t) using the connection weight, the input weighting result, and the first to third multiplication results.

The addition result of the fourth multiplication result, the input weighting result, and the first to third multiplication results output by the fourth multiplier 4450 is input into the fifth multiplier 4460 together with the reservoir node state uⱼ(t) read from the reservoir node state storage 4480. Accordingly, the fifth multiplier 4460 outputs an addition result of a fifth multiplication result obtained by weighting the reservoir node state uⱼ(t) using the connection weight, the input weighting result, and the first to fourth multiplication results.

The addition result of the fifth multiplication result, the input weighting result, and the first to fourth multiplication results output by the fifth multiplier 4460 is input into the activation core 4470. Accordingly, the activation core 4470 outputs the reservoir feature value.

For the reservoir node state uⱼ(t) read from the reservoir node state storage 4480 and input into the first multiplier 4420 to the fifth multiplier 4460, the same element is input at the same timing.

The input core 4410 and the first multiplier 4420 to the fifth multiplier 4460 are configured with the same calculation unit, and a detailed configuration of the calculation unit will be described later. Details of the activation core 4470 will also be described later.

(2) Details of Parallelized Reservoir Device (with Feedback)

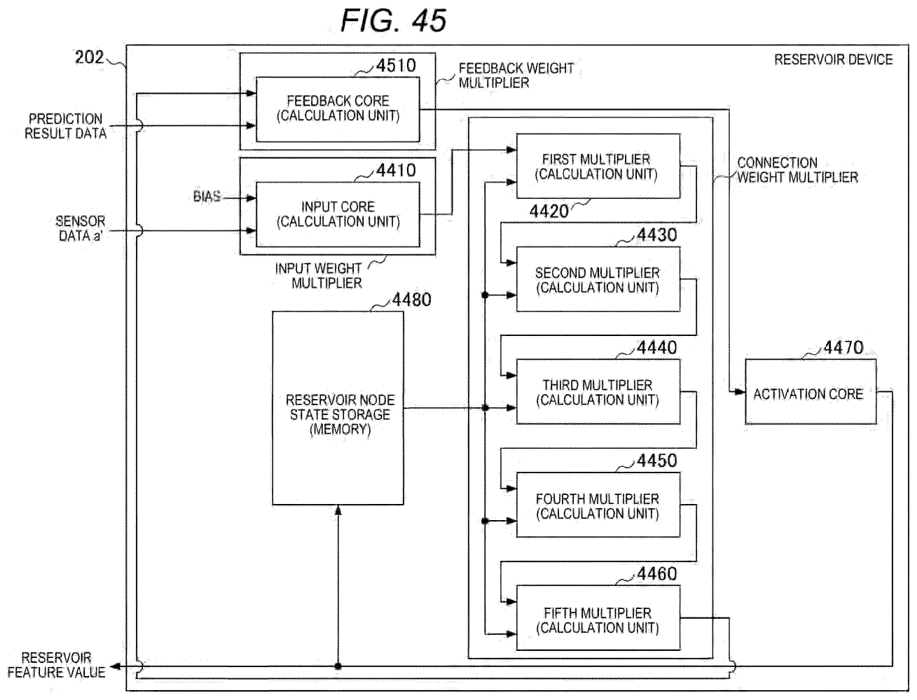

Next, details of a hardware configuration of the parallelized reservoir device 202 (here, with feedback) will be described. FIG. 45 is an eighth diagram illustrating an example of the hardware configuration of the reservoir device and illustrates an example of the hardware configuration of the reservoir device with N_{CU}=5.

As illustrated in FIG. 45, the parallelized reservoir device 202 (with feedback) has the same hardware configuration as the hardware configuration of the parallelized reservoir device 202 (without feedback) illustrated in FIG. 44. The parallelized reservoir device 202 (with feedback) further includes a feedback core 4510 (another example of the feedback weight multiplier). The addition result of the input weighting result and the first to fifth multiplication results output from the fifth multiplier 4460 is output to the feedback core 4510 instead of being output to the activation core 4470.

When the feedback core 4510 receives input of Z(t), which is the value of the prediction result data, the feedback core 4510 calculates a feedback weighting result (wᵢ^{F})·(Z(t)) obtained by weighting Z(t) using the feedback weight.

The feedback core 4510 adds the feedback weighting result (wᵢ^{F})·(Z(t)), the input weighting result, and the first to fifth multiplication results to each other. An addition result is output to the activation core 4470. Accordingly, the activation core 4470 outputs the reservoir feature value.

### (3) Details of Each Unit Included in Parallelized Reservoir Device

Next, details of each unit (the input core 4410, the feedback core 4510, the first multiplier 4420 to the fifth multiplier 4460, and the activation core 4470) included in the parallelized reservoir device 202 will be described.

### (3-1) Details of Calculation Unit

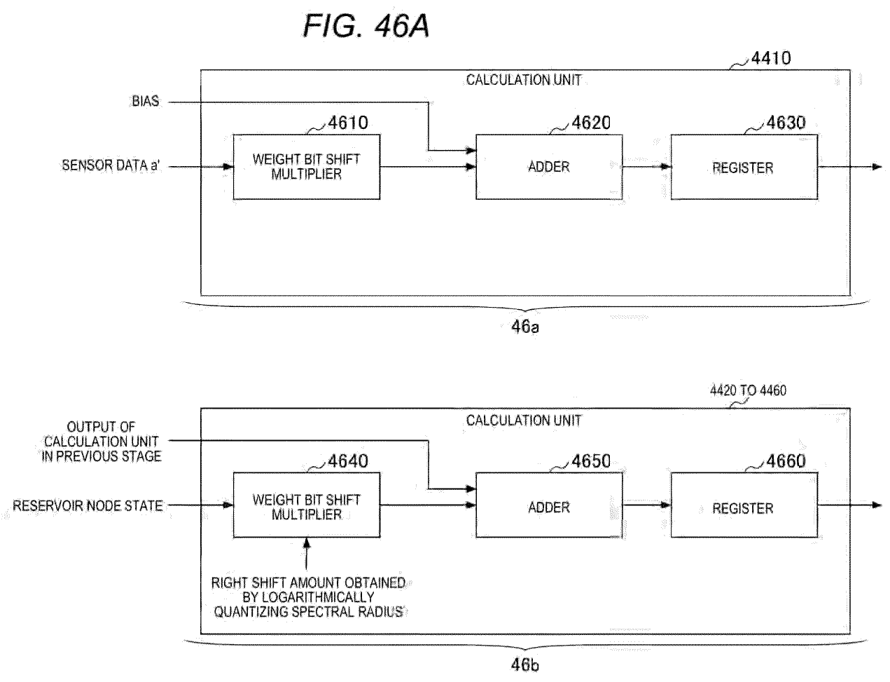

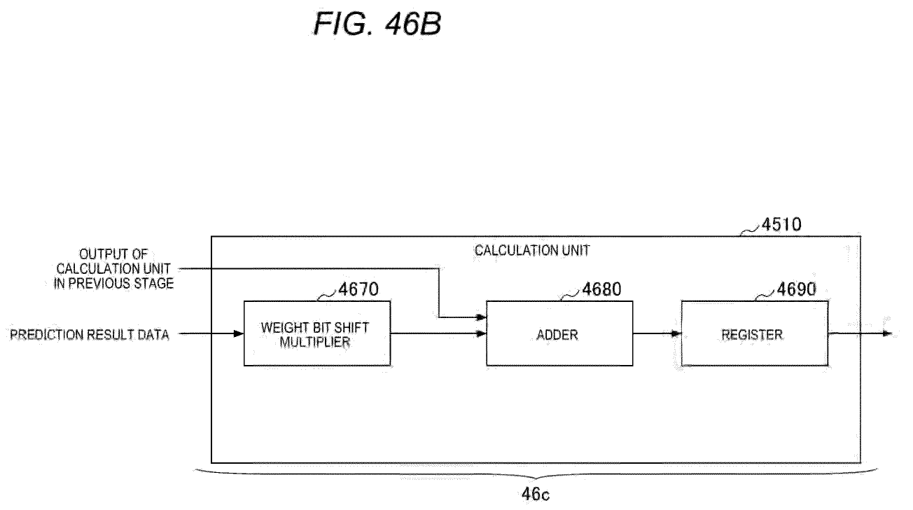

FIGS. 46A and 46B are first and second diagrams illustrating details of the calculation unit constituting the reservoir device. 46a of FIG. 46A is an example of the calculation unit constituting the input core 4410. As illustrated in 46a of FIG. 46A, the calculation unit constituting the input core 4410 includes a weight bit shift multiplier 4610, an adder 4620, and a register 4630.

The weight bit shift multiplier 4610 weights the value of the input sensor data a′ using any of the power of two corresponding to the value output from the 4-bit LFSR, its negative value, or 0 as a weight. Accordingly, the weight bit shift multiplier 4610 outputs an input weighting result. The weight bit shift multiplier 4610 is the same as the weight bit shift multiplier 3300 described using FIG. 33 and thus, will not be described in detail here.

The adder 4620 is an example of the adder and outputs an input weighting result obtained by adding a bias to the input weighting result output by the weight bit shift multiplier 4610.

The register 4630 holds the input weighting result output by the adder 4620. The input weighting result output by the adder 4620 and held in the register 4630 is output to the calculation unit in the subsequent stage.

46b of FIG. 46A is an example of the calculation unit constituting the first multiplier 4420 to the fifth multiplier 4460 and is substantially the same as the calculation unit illustrated in 46a of FIG. 46A.

A weight bit shift multiplier 4640 weights the reservoir node state read from the reservoir node state storage 4480 using any of the power of two corresponding to the value output from the 4-bit. LFSR, its negative value, or 0 as a weight. The weight bit shift multiplier 4640 adjusts the spectral radius by shifting the weighted value to the right by the right shift amount (nb) obtained by logarithmically quantizing the spectral radius.

An adder 4650 is an example of the adder and adds a connection weighting result from the weight bit shift multiplier 4640 to the output from the calculation unit in the previous stage. When the calculation unit constitutes the first multiplier 4420, the output from the calculation unit in the previous stage is the input weighting result. When the calculation unit constitutes any of the multipliers from the second multiplier (the second multiplier 4430 to the fifth multiplier 4460), the output from the calculation unit in the previous stage is the addition result of the multiplier in the previous stage.

A register 4660 holds the addition result output from the adder 4650. The addition result held in the register 4660 is read by the calculation unit in the subsequent stage or the activation core 4470. Specifically, when the calculation unit constitutes the first multiplier 4420 to the fourth multiplier 4450, the addition result is read by the multiplier in the subsequent stage. When the calculation unit constitutes the fifth multiplier 4460 (that is, constitutes the last stage), the addition result is read by the activation core 4470.

46c of FIG. 460 is an example of the calculation unit constituting the feedback core 4510 and is substantially the same as the calculation unit illustrated in 46a of FIG. 46A.

As illustrated in 46c of FIG. 46E, the calculation unit constituting the feedback core 4510 includes a weight bit shift multiplier 4670, an adder 4680, and a register 4690.

The weight bit shift multiplier 4670 weights the value of the input prediction result data, using any of the power of two corresponding to the value output from the 4-bit LFSR, its negative value, or 0 as a weight. Accordingly, the weight bit shift multiplier 4670 outputs a feedback weighting result. The weight bit shift multiplier 4670 is the same as the weight bit shift multiplier 3300 described using FIG. 33 and thus, will not be described in detail here.

The adder 4680 is an example of the adder and outputs a result obtained by adding the output of the calculation unit in the previous stage to the feedback weighting result output by the weight bit shift multiplier 4670.

The register 4690 holds the result output by the adder 4680. The result output by the adder 4680 and held in the register 4690 is output to the activation core 4470.

### (3-2) Details of Activation Core

For example, as described using FIG. 9 and the like in the first embodiment, the activation core 4470 is implemented by the activation function circuit 332 executing the activation function f of Equation (7). Alternatively, for example, the activation core 4470 may be implemented by the limiter circuit 907 executing the piecewise linear function, as described in the fifth embodiment. Alternatively, for example, the activation core 4470 may be implemented by the lookup table, as described in the fifth embodiment.

### <Overall Timing Chart of Reservoir Device>

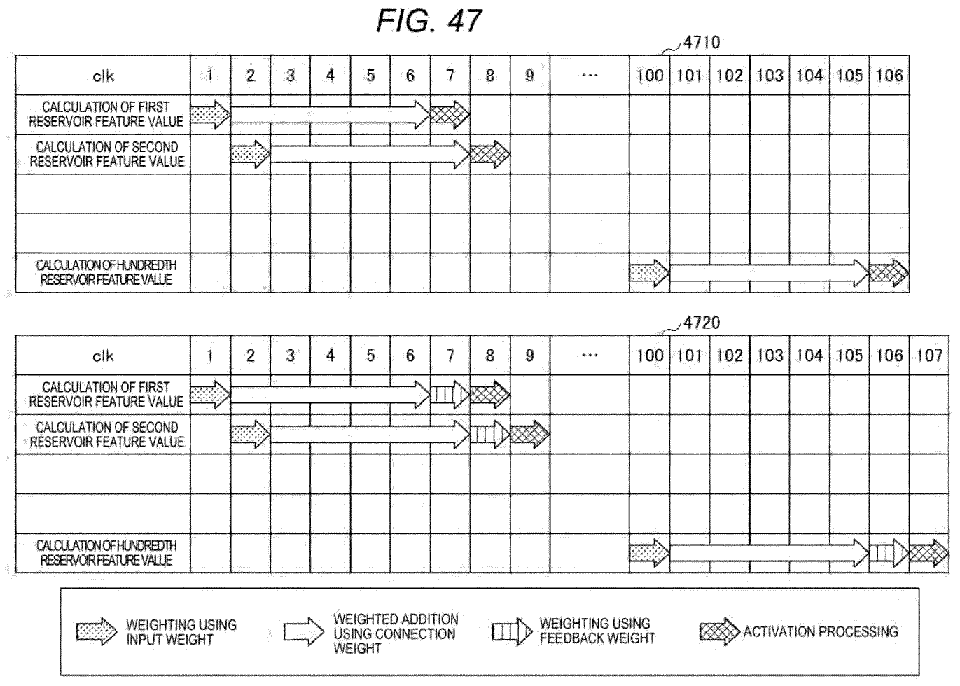

Next, a timing chart of overall processing of the reservoir device 202 in which reduction of the number of operations based on the variable vector length dot product operation architecture and parallelization provided by the above hardware configuration are achieved will, be described. FIG. 47 is an example of an overall timing chart of the reservoir device and illustrates a timing chart on an assumption of
number (N) of reservoir nodes=100, and
number N_{CU} of connections per node=5.

In FIG. 47, a horizontal axis denotes an execution timing, and each region denotes a length of one clock (clk). A wide arrow in the drawing indicates a start timing and an end timing of calculation of the corresponding reservoir feature value. Different types of wide arrows indicate different types of processing. Specifically, as illustrated in the lowermost part of FIG. 47, the wide arrow corresponds to any of
weighting processing using the input weight
weighted addition processing using the connection weight
weighting processing using the feedback weight, or
activation processing.

In FIG. 47, a timing chart 4710 is a timing chart of the reservoir device 202 (without feedback), and a timing chart 4720 is a timing chart of the reservoir device 202 (with feedback).

In any of the timing charts, a time required from the start of calculation of the first reservoir feature value to completion of calculation of the hundredth reservoir feature value is approximately 100 clocks (clk)+α. Use of the reservoir device 202 in which reduction of the number of operations and parallelization are achieved can implement a more significant increase in speed than use of the reservoir device 202 in which reduction of the number of operations and parallelization are not achieved.

<Verification of Prediction Accuracy of Reservoir Device in which Reduction of Number of Operations and Parallelization are Achieved>

Next, the prediction accuracy of the reservoir device 202 in which reduction of the number of operations and parallelization are achieved will be verified. In the present embodiment, verification of the prediction accuracy is performed under the following condition.

### (1) Verification Condition

Activation function: piecewise linear function
Number (N) of reservoir nodes: 100
Number (N_{CU}) of connections per reservoir node: 5
Latency of activation function: 1 clock
Learning condition: initialization data=1000 and learning data=3000
Prediction condition: prediction data=1000
Learning method: batch learning

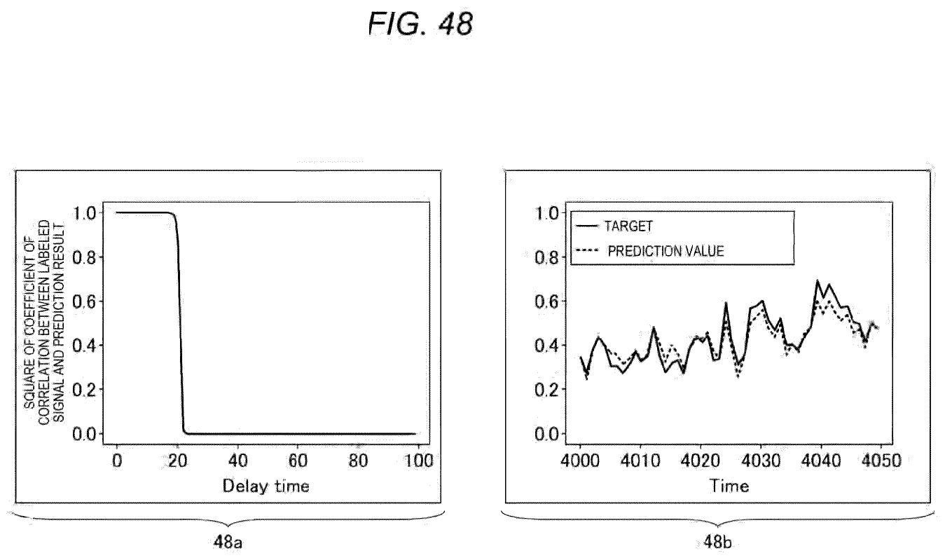

As a result of predicting the reservoir feature value based on the verification condition using prediction data=1000, the following verification result is obtained (FIG. 48 is a diagram illustrating an example of the verification result of the prediction accuracy of the reservoir device).

### (2) Verification Result

Memory capacity (MC): 21.1 (refer to 48a of FIG. 48)
NRMSE (NARMA10): 0.135 (refer to 48b of FIG. 48)
When the FPGA operates at 125 MHz, it is confirmed that a time required for calculating the reservoir feature value is 855 [ns]. This time is shorter than 960 [ns], which is a calculation time of the FORCE learner. Thus, it is verified that the FPGA reservoir and the FORCE learning can be connected to each other by adjusting timings.

NRMSE is the abbreviation for Normalized Root Mean Square Error and refers to the normalized root mean square error. NARMA10 is a general task used for verifying the reservoir device.

### SUMMARY

As is clarified from the above description, the reservoir device 202 according to the sixth embodiment receives input of the time series sensor data measured in a predetermined process and outputs the reservoir feature value based on a result of processing using the input weight multiplier and the connection weight multiplier.

In the reservoir device 202 according to the sixth embodiment, the following is performed.
The input weight multiplier weights the input sensor data, using a value determined by a periodic function as the input weight.
   The connection weight multiplier is a multiplier configured to weight data indicating the states of the nodes, using a value determined by a periodic function as the connection weight, and includes multipliers corresponding in number to the number of connections of each node.
   Each multiplier parallelly performs weighting of the same element in the data indicating the states of the nodes.

Accordingly, the reservoir device 202 according to the sixth embodiment can increase a speed of processing of outputting the reservoir feature value.

### Seventh Embodiment

The sixth embodiment is configured such that the reservoir node state uⱼ(t) is weighted in the weight bit shift multiplier 4640 of each of the calculation units constituting the first multiplier 4420 to the fifth multiplier 4460.

Meanwhile, the spectral radius may be configured to be adjusted before being input into the weight bit shift multiplier 4640, as in the third embodiment. Hereinafter, the seventh embodiment will be described with a focus on the differences from the sixth embodiment.

### <Hardware Configuration of Parallelized Reservoir Device>

First, a hardware configuration of the reservoir device 202 according to the seventh embodiment will be described.

(1) Details of Parallelized Reservoir Device (without Feedback)

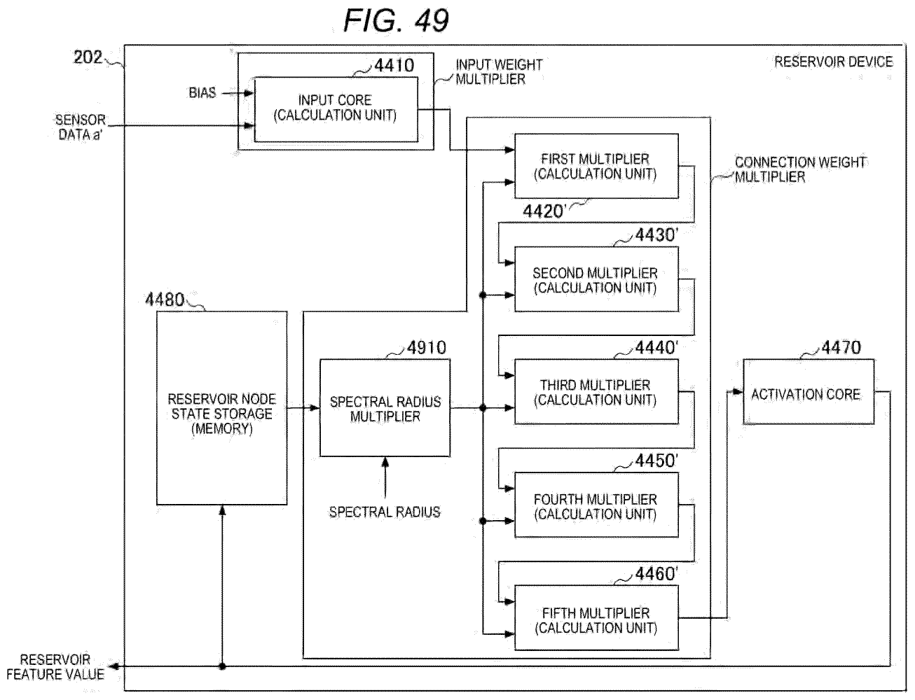

FIG. 49 is a ninth diagram illustrating an example of the hardware configuration of the reservoir device. The reservoir device 202 illustrated in FIG. 49 is different from the hardware configuration described using FIG. 44 in the sixth embodiment in that a spectral radius multiplier 4910 is added and internal configurations of the first to fifth multipliers are changed.

The spectral radius multiplier 4910 is a bit shift circuit or a normal multiplier. The bit shift circuit is used for fewer resources, and the normal multiplier is used for high accuracy. In the present embodiment, use of the normal multiplier will be described below.

An output of the spectral radius multiplier 4910 is the reservoir node state uⱼ(t) multiplied by a reciprocal of the spectral radius (a spectral radius weighting result). The output of the spectral radius multiplier 4910 is input into a first multiplier 4420′ to a fifth multiplier 4460′. Consequently, the first multiplier 4420′ to the fifth multiplier 4460′ do not need to adjust the spectral radius.

(2) Details of Parallelized Reservoir Device (with Feedback)

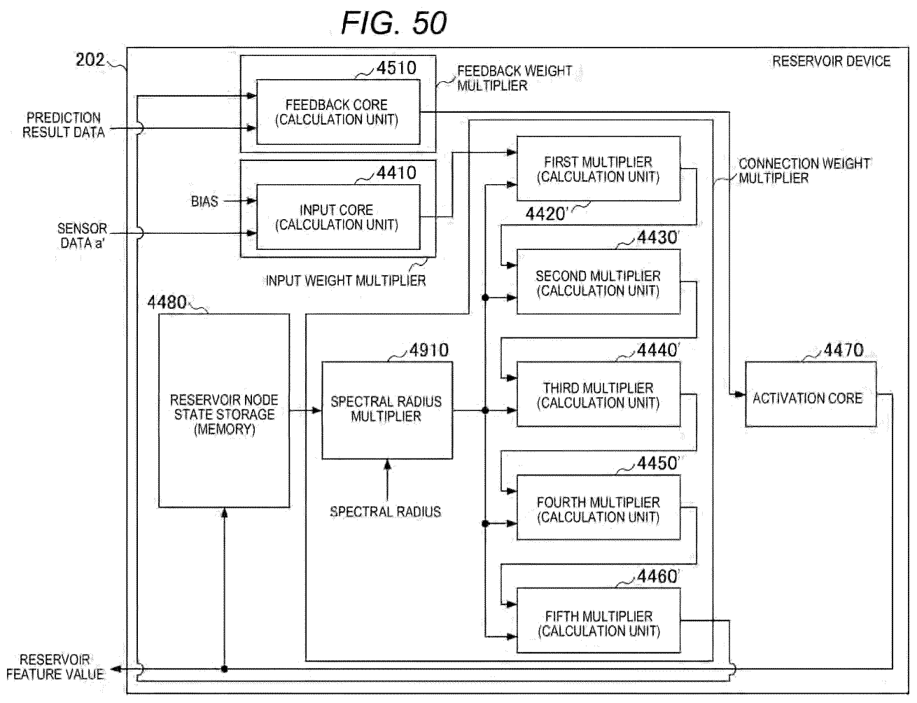

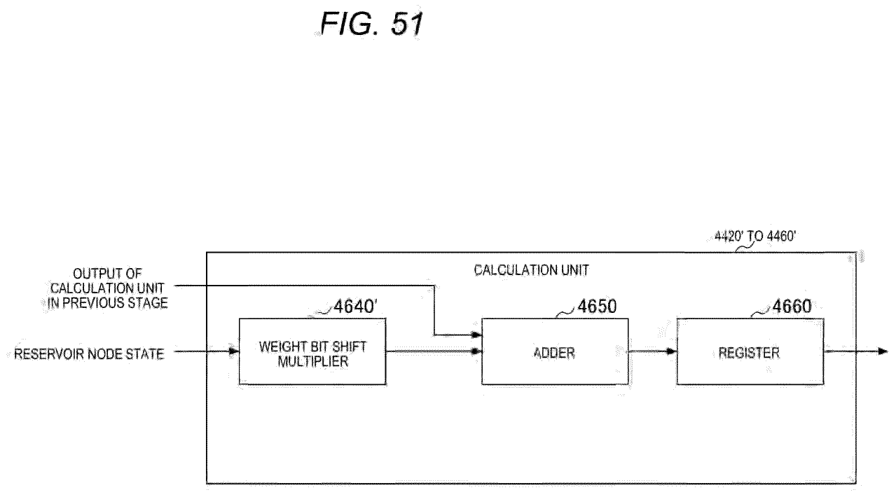

FIG. 50 is a tenth diagram illustrating an example of the hardware configuration of the reservoir device. The reservoir device 202 illustrated in FIG. 50 is different from the hardware configuration described using FIG. 45 in the sixth embodiment in that the spectral radius multiplier 4910 is added and the internal configurations of the first multiplier to the fifth multiplier are changed. Accordingly, the reservoir device 202 illustrated in FIG. 50 can obtain the same effect as that in FIG. 49.

### (3) Details of Calculation Units Constituting First Multiplier to Fifth Multiplier

As described above, the first multiplier 4420′ to the fifth multiplier 4460′ do not need to adjust the spectral radius. Accordingly, details of the calculation units constituting the first multiplier 4420′ to the fifth multiplier 4460′ are changed.

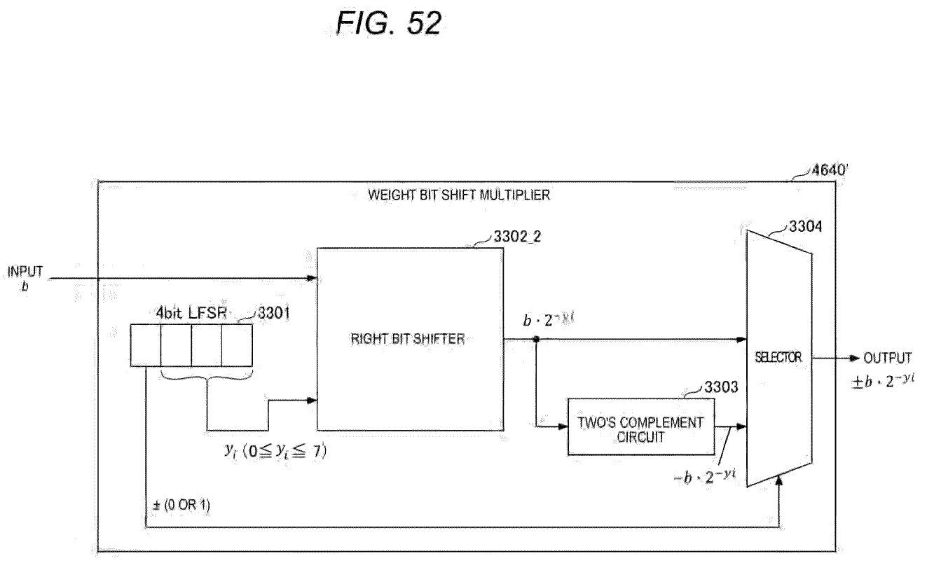

FIG. 51 is a second diagram illustrating details of the calculation unit constituting the reservoir device. FIG. 51 is different from the calculation unit illustrated in 46b of FIG. 46A in that the right shift amount obtained by logarithmically quantizing the spectral radius is not input into a weight bit shift multiplier 4640′. Details of the weight bit shift multiplier 4640′ are illustrated in FIG. 52.

FIG. 52 is a diagram illustrating an example of the weight bit shift multiplier in the seventh embodiment and indicates the weight bit shift multiplier used in the first multiplier 4420′ to the fifth multiplier 4460′ (the weight bit shift multiplier is the same as that in FIG. 33 and thus, will not be described).

According to the seventh embodiment, the parallelized reservoir device 202 can be implemented by a different hardware configuration from the sixth embodiment.

### Other Embodiments

The above embodiment describes output of the presence or absence of an abnormality or the sensor data as the prediction result data obtained by predicting the process state. However, the prediction result data output by the process state predictor 204 is not limited to the presence or absence of an abnormality or the sensor data and may be, for example, a level indicating the state of the process, or presence or absence of a failure of the apparatus executing the manufacturing process.

While the above embodiment illustrates the apparatus executing the manufacturing process as the apparatus to which the process state prediction system is applied, the apparatus to which the process state prediction system is applied is not limited to the apparatus executing the manufacturing process. As long as the apparatus executes a predetermined process, a process other than the manufacturing process may be performed.

The present invention is not limited to the configurations described in connection with the embodiments that have been described heretofore, or to the combinations of these configurations with other elements. Various variations and modifications may be made without departing from the scope of the present invention, and may be adopted according to applications.

1. A reservoir device comprising an input weight multiplier and a connection weight multiplier,
wherein the reservoir device is configured to output, in response to time series sensor data measured in a predetermined process being input, a reservoir feature value based on a result of processing using the input weight multiplier and the connection weight multiplier,
the input weight multiplier weights the input sensor data, using a value determined by a periodic function as an input weight, and
the connection weight multiplier performs weighted addition of data indicating states of nodes, using a value determined by a periodic function as a connection weight between two nodes among the nodes.

2. The reservoir device according to claim 1,
wherein the reservoir device outputs, in response to the time series sensor data measured in the predetermined process and prediction data predicted based on a reservoir feature value obtained one timing ago being input, the reservoir feature value based on a result of processing using the input weight multiplier, the connection weight multiplier, and a feedback weight multiplier, and
the feedback weight multiplier weights the prediction data predicted based on the reservoir feature value using a value determined by a periodic function as a feedback weight.

3. The reservoir device according to claim 1,
wherein the connection weight multiplier performs weighted addition of the reservoir feature value obtained one timing ago as the data indicating the states of the nodes.

4. The reservoir device according to claim 1,
wherein the connection weight is determined by the periodic function and a right shift amount obtained by logarithmically quantizing a spectral radius calculated in advance.

5. The reservoir device according to claim 1,
wherein the input weight multiplier includes a first multiplier configured to weight the input sensor data, using a value output by a first periodic function circuit and bit-shifted as an input weight.

6. The reservoir device according to claim 1,
wherein the input weight multiplier includes an input weight bit shift multiplier configured to weight the input sensor data, using a power of two corresponding to a value output by a first periodic function circuit or a negative value of the power of two as an input weight.

7. The reservoir device according to claim 3,
wherein the connection weight multiplier includes a second multiplier configured to weight the data indicating the states of the nodes, using a value output by a second periodic function circuit and bit-shifted as a connection weight between two nodes among the nodes, and an accumulator configured to add the weighted data indicating the states of the nodes.

8. The reservoir device according to claim 3,
wherein the connection weight multiplier includes a connection weight bit shift multiplier configured to weight the data indicating the states of the nodes, using a power of two corresponding to a value output by a second periodic function circuit or a negative value of the power of two as a connection weight, and an accumulator configured to add the weighted data indicating the states of the nodes.

9. The reservoir device according to claim 2,
wherein the feedback weight multiplier includes a third multiplier configured to weight the prediction data predicted based on the reservoir feature value obtained one timing ago using a value output by a third periodic function circuit and bit-shifted as a feedback weight.

10. The reservoir device according to claim 2,
wherein the feedback weight multiplier includes a feedback weight bit shift multiplier configured to weight the prediction data predicted based on the reservoir feature value obtained one timing ago using a power of two corresponding to a value output by a third periodic function circuit or a negative value of the power of two as a feedback weight.

11. The reservoir device according to claim 1,
wherein the connection weight multiplier includes
a second multiplier configured to weight the data indicating the states of the nodes, using the connection weight, by multiplying a value output by a second periodic function circuit by a value obtained by adjusting the states of the nodes using a spectral radius, and
an accumulator configured to add the weighted data indicating the states of the nodes.

12. The reservoir device according to claim 7,
wherein the connection weight multiplier includes an address control circuit configured to read data indicating states of target nodes from a memory storing the reservoir feature value obtained one timing ago as the data indicating the states of the nodes, a number of the target nodes being less than a number of the nodes, and
the second multiplier weights the data indicating the states of the target nodes read by the address control circuit.

13. A reservoir device comprising an input weight multiplier and a connection weight multiplier,
wherein the reservoir device is configured to output, in response to time series sensor data measured in a predetermined process being input, a reservoir feature value based on a result of processing using the input weight multiplier and the connection weight multiplier,
the input weight multiplier weights the input sensor data, using a value determined by a periodic function as an input weight,
the connection weight multiplier includes multipliers configured to weight data indicating states of nodes, using a value determined by a periodic function as a connection weight between two nodes among the nodes, and correspond in number to a processing speed or prediction accuracy of the reservoir device, and
the multipliers of the connection weight multiplier parallelly weight common data between the multipliers in weighting the data indicating the states of the nodes, using the value determined by the periodic function as the connection weight.

14. A reservoir device comprising an input weight multiplier and a connection weight multiplier,
wherein the reservoir device is configured to output, in response to time series sensor data measured in a predetermined process being input, a reservoir feature value based on a result of processing using the input weight multiplier and the connection weight multiplier,
the input weight multiplier weights the input sensor data, using a value determined by a periodic function as an input weight,
the connection weight multiplier includes
a spectral radius multiplier configured to weight data indicating states of nodes, using a connection weight between two nodes among the nodes by adjusting a reservoir feature value obtained one timing ago using a spectral radius and output a spectral radius weighting result, and
multipliers that correspond in number to a processing speed or prediction accuracy of the reservoir device, the spectral radius weighting result being input into the multipliers,
the multipliers are connected in series in a stage subsequent to the input weight multiplier,
a first multiplier among the multipliers includes an adder configured to add an input weighting result output by the input weight multiplier to a connection weighting result obtained by weighting data indicating a state of a corresponding node, and
a multiplier that is a second multiplier or later among the multipliers includes an adder configured to add an addition result output by a multiplier in a previous stage to the connection weighting result obtained by weighting data indicating a state of a corresponding node.

15. The reservoir device according to claim 13,
wherein the reservoir device outputs, in response to the time series sensor data measured in the predetermined process and prediction data predicted based on a reservoir feature value obtained one timing ago being input, the reservoir feature value based on a result of processing using the input weight multiplier, the connection weight multiplier, and a feedback weight multiplier, and
the feedback weight multiplier weights the prediction data predicted based on the reservoir feature value, using a value determined by a periodic function as a feedback weight.

16. The reservoir device according to claim 13,
wherein each of the multipliers weights the reservoir feature value obtained one timing ago as the data indicating the states of the nodes.

17. The reservoir device according to claim 13,
wherein the multipliers are connected in series in a stage subsequent to the input weight multiplier,
a first multiplier among the multipliers includes an adder configured to add an input weighting result output by the input weight multiplier to a connection weighting result obtained by weighting data indicating a state of a corresponding node, and
a multiplier that is a second multiplier or later among the multipliers includes an adder configured to add an addition result output by a multiplier in a previous stage to a connection weighting result obtained by weighting data indicating a state of a corresponding node.

18. The reservoir device according to claim 13,
wherein the connection weight is determined by the periodic function and by a spectral radius calculated in advance or a right shift amount obtained by logarithmically quantizing the spectral radius.

19. The reservoir device according to claim 13,
wherein the input weight multiplier includes an input weight bit shift multiplier configured to weight the input sensor data, using a power of two corresponding to a value output by a first periodic function circuit, a negative value of the power of two, or 0 as an input weight.

20. The reservoir device according to claim 17,
wherein each of the multipliers further includes a connection weight bit shift multiplier configured to weight the data indicating the states of the nodes, using a power of two corresponding to a value output by a second periodic function circuit, a negative value of the power of two, or 0 as a connection weight.

21. The reservoir device according to claim 15,
wherein the feedback weight multiplier includes a feedback weight bit shift multiplier configured to weight the prediction data predicted based on the reservoir feature value obtained one timing ago using a power of two corresponding to a value output by a third periodic function circuit, a negative value of the power of two, or 0 as a feedback weight.

22. The reservoir device according to claim 13,
wherein the connection weight multiplier reads data indicating states of target nodes among the nodes from a memory storing a reservoir feature value obtained one timing ago as the data indicating the states of the target nodes, the target nodes corresponding in number to the processing speed or the prediction accuracy of the reservoir device, and the multipliers weight the read data indicating the states of the nodes.

23. The reservoir device according to claim 13,
wherein the connection weight multiplier reads data indicating states of target nodes among the nodes, the target nodes being specified in advance to be weighted using a non-zero element based on regularity in arrangement of elements of zero of the connection weight and corresponding in number to the processing speed or the prediction accuracy of the reservoir device.

24. The reservoir device according to claim 17, further comprising:
an operation circuit configured to output the reservoir feature value by performing fixed-point or floating-point polynomial calculation of an addition result output by a multiplier in a last stage among the multipliers.

25. The reservoir device according to claim 15, further comprising:
an operation circuit configured to output the reservoir feature value by performing fixed-point or floating-point polynomial calculation of a result obtained by adding an addition result output by a multiplier in a last stage among the multipliers to a feedback weighting result output by the feedback weight multiplier.

26. The reservoir device according to claim 24,
wherein the operation circuit
includes a holder configured to hold a coefficient after adjustment that is adjusted in advance in accordance with a characteristic of the sensor data as a coefficient to be used for the fixed-point or floating-point polynomial calculation, and
performs the fixed-point or floating-point polynomial calculation by reading the coefficient held in the holder.

27. The reservoir device according to claim 24,
wherein the operation circuit outputs the reservoir feature value, using a piecewise linear function or using a lookup table, instead of performing the fixed-point or floating-point polynomial calculation.

28. A process state prediction system comprising:
the reservoir device according to claim 1; and
a prediction device configured to predict a state of the predetermined process based on the reservoir feature value and weight parameters, and output prediction data.

29. The process state prediction system according to claim 28,
wherein the prediction device learns the weight parameters by performing First-Order Reduced and Controlled Error (FORCE) Learning processing based on recursive least squares.

30. The process state prediction system according to claim 29,
wherein the prediction device includes a plurality of field-programmable gate arrays (FPGAs), each of the plurality of FPGAs executes a part of matrix operations of a plurality of rows and a plurality of columns executed for the FORCE learning processing based on the recursive least squares, and the prediction device learns the weight parameters by aggregating execution results of the plurality of FPGAs.

31. The process state prediction system according to claim 30,
wherein, in the prediction device, each of the plurality of FPGAs substitutes a partial operation of the FORCE learning processing based on the recursive least squares by transposing an already calculated vector using symmetry of a matrix used for the partial operation.

32. The process state prediction system according to claim 29,
wherein, in response to determining that relearning is necessary during a prediction period after the learning, the prediction device relearns the weight parameters by performing the FORCE learning processing based on the recursive least squares.

33. The process state prediction system according to claim 32,
wherein, in relearning the weight parameters through the FORCE learning processing based on the recursive least squares, the prediction device calculates, by executing the FORCE learning processing a number of times corresponding to a number of learning parameters, the weight parameters corresponding in number to the number of the learning parameters, and sets a weight parameter corresponding to a prediction result having prediction accuracy that falls within a predetermined allowable range and that is highest among the calculated weight parameters as a weight parameter to be used for prediction after the relearning.

34. The process state prediction system according to claim 33,
wherein a fixed value or a value based ort a prediction result calculated by accumulating the reservoir feature value to reach a predetermined data amount and performing batch learning is set as the predetermined allowable range.

35. The process state prediction system according to claim 33,
wherein, when a new learning parameter is generated in response to determining that the prediction accuracy of any prediction result does not fall within the predetermined allowable range is made, the prediction device sets a weight parameter calculated by executing the FORCE learning processing based on the new learning parameter as the weight parameter to be used for prediction after the relearning.

36. The process state prediction system according to claim 32,
wherein it is determined that relearning is necessary in a case where accuracy of a prediction result output by the prediction device is decreased to a predetermined threshold or lower, in a case where a type of the input time series sensor data is changed, or in a case where a value of the input time series sensor data changes by a predetermined threshold or more.
